(19) United States
(12) Patent Application Publication
(10) Pub. No.: US 2007/0241665 A1
(43) Pub. Date: Oct. 18, 2007

(54) ORGANIC ELECTROLUMINESCENT ELEMENT, AND MANUFACTURING METHOD THEREOF, AS WELL AS DISPLAY DEVICE AND EXPOSURE APPARATUS USING THE SAME

(75) Inventors: Kei SAKANOUE, Fukuoka (JP); Takafumi HAMANO, Fukuoka (JP); Shinya YAMAMOTO, Fukuoka (JP); Naoto MATSUO, Fukuoka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/733,923

(22) Filed: Apr. 11, 2007

(30) Foreign Application Priority Data
Apr. 12, 2006 (JP) 2006-110117
Apr. 19, 2006 (JP) 2006-115856
Apr. 19, 2006 (JP) 2006-116183
Apr. 19, 2006 (JP) 2006-116184
Apr. 19, 2006 (JP) 2006-116193
Apr. 19, 2006 (JP) 2006-116194

(51) Int. Cl. H05B 33/26; H01L 51/50

(52) U.S. Cl. 313/503; 313/504

(57) ABSTRACT

To provide an organic electroluminescent element having uniform luminescence properties stable in operation and excellent in life property, an organic electroluminescent element in which a luminescent layer is provided between a positive electrode and a negative electrode, wherein a buffer layer constituted with a transition metal oxide (for example, molybdenum oxide) is provided between the negative electrode and the luminescent layer.

### BACKGROUND OF THE INVENTION

1. Field of the Invention

The present invention relates to an organic electroluminescent element and the method thereof, and furthermore, to a display device such as a display screen of a cellular phone and an exposure apparatus for an image forming device in which the organic electroluminescent element is used.

2. Description of the Related Art

An organic electroluminescent element is a light emitting device which utilizes an electroluminescence phenomenon of solid fluorescent materials and commercially available as a small-sized display screen in some cases.

In particular, a so-called polymer organic electroluminescent element in which a polymer material is used as a luminescent material is available as a film according to wet coating methods such as a spin coating method, an ink jet method, a flood printing method, a gap coating method, a spray method, an LB method, and a printing method by using a solution in which a material constituting a so-called functional layer such as a luminescent layer or a charge-injection layer is used, and the manufacturing method is now gaining attention as a technology for using the film in a larger area or manufacturing it at a lower cost, due to the simple process.

A typical polymer organic electroluminescent element is created by laminating a plurality of functional layers such as a charge-injection layer and a luminescent layer between a positive electrode and a negative electrode.

FIG. 25 is a sectional view showing a constitution of a conventional organic electroluminescent element.

As illustrated in FIG. 25, first, PEDOT:PSS (mixture of polythiophene with polystyrene sulfonate, hereinafter, referred to as PEDT) thin film is formed as a charge-injection layer 126 on a glass substrate 100 on which ITO (indium tin oxide) is formed as a positive electrode 111 by a spin coating method or the like. PEDT is a material which is a practical standard of a charge-injection layer, functioning as a hole injection layer when arranged on the positive electrode 111. Reference numeral 127 denotes an electron blocking layer.

Polyphenylene vinylene (hereinafter, abbreviated as PPV) and its derivatives, or polyfluorene and its derivatives are formed as a luminescent layer 112 on the PEDT layer by a spin coating method or the like. Then, a metal electrode 113 as a negative electrode is formed as a film on the luminescent layer by a vacuum deposition method, a sputtering method or a wet coating method, thereby completing the formation of an element.

As described above, a polymer organic electroluminescent element can be prepared by a simple process and is expected to find applications in various fields. However, the element is unable to provide a sufficiently great luminescence intensity or is not adequate in durability for prolonged use, which is a problem to be improved.

Although estimation is made for possible causes of decreased luminescence intensity, the deterioration of PEDT is considered to be one of the major causes. As described previously, PEDT is a mixture of two polymer substances, that is, polystyrene sulfonate and polythiophene. The former has ionicity, whereas the latter has a local polarity in polymer chains. These two substances are loosely bound due to the Coulomb interaction resulting from such an anisotropic charge, thereby exhibiting excellent charge injection characteristics.

In order for PEDT to exhibit excellent characteristics, the two substances must be closely interacted. In general, a mixture of polymer substances will easily cause a phase separation due to a subtle difference in solubility to a solvent. With regard to PEDT, this is not an exception. To cause a phase separation means that where two polymer substances are loosely bound, they may be decomposed relatively easily, in other words, suggesting that when PEDT is driven in an organic electroluminescent element, it may be unstable, or as a result of the phase separation, compositions not contributing to the bonding, in particular, an ionic composition, may diffuse due to an electric field associated with electrification, thereby affecting other functional layers. As described above, although provided with excellent charge injection characteristics, PEDT is not a stable substance at all.

Based on the results of various experiments, the present inventor and others have made a proposal as a solution for the above problem related to PEDT for forming a transition metal oxide, for example, molybdenum oxide, between a positive electrode 111 and a luminescent layer 112 in place of PEDT, thereby obtaining desirable injection characteristics (Patent Document 1).

Patent Document 1: Japanese Published Unexamined Patent Application No. 2005-203340

According to the above-described structure, a molybdenum oxide film having a thickness of approximately 20 nm is formed on the positive electrode 111, and functional layers such as the luminescent layer 112 are formed on the upper layer thereof. Then, on a negative electrode 113 mainly used is a metal laminated structure which is constituted with an intermediate layer 113a in contact with an organic compound layer composed of metals such as Ba, Ca, Mg, Li and Cs or a fluoride and an oxide of these metals such as LiF and CaO and an electrode layer 113b formed thereon and composed of metal materials such as Ag, Al, Mg and In.

As described above, since a highly reactive material is used as the intermediate layer 113a, there is an idea that a barrier layer is interposed at a space with the luminescent layer 112, thereby preventing the inflow of reactive substances, which may sometimes result in a voltage drop. It is, therefore, difficult to adjust a carrier balance and also emit light at the center of the luminescent layer 112.

Furthermore, in a conventional organic electroluminescent element, where there is found a portion thinner in thickness, electric field concentration may occur. If light is continuously emitted under such a circumstance, the electric field is concentrated on the portion thinner in thickness, and also where light is emitted not at the center of a luminescent layer but at a deviated position in the laminated direction of each layer, there is found a problem that deterioration proceeds rapidly.

### SUMMARY OF THE INVENTION

The present invention has been made in view of the above circumstance, an object of which is to provide an organic electroluminescent element which is uniform in luminescence properties, stable in operation and excellent in life property.

The organic electroluminescent element of the present invention is an organic electroluminescent element having a luminescent layer between a positive electrode and a negative electrode, in which a transition metal oxide layer is formed between the negative electrode and the luminescent layer, thereby providing an organic electroluminescent element excellent in life property.

### BRIEF DESCRIPTION OF THE DRAWINGS

FIG. 1 is a block diagram illustrating an organic electroluminescent element according to the first embodiment of the present invention;

FIG. 2 is a drawing showing the luminescence properties of an organic electroluminescent element according to the first embodiment of the present invention;

FIG. 3 is a block diagram illustrating an organic electroluminescent element according to a modification of the first embodiment of the present invention;

FIG. 4 is a drawing showing the luminescence properties of the organic electroluminescent element according to the first embodiment of the present invention;

FIG. 5 is a block diagram illustrating a constitution where the electroluminescent element of the first embodiment of the present invention is applied to an exposure apparatus;

FIG. 6 is a plan view showing a constitution in the vicinity of a photo-detecting element of an exposure apparatus in which the organic electroluminescent element of the first embodiment of the present invention is used;

FIG. 7 is a sectional view showing a modification of an exposure apparatus in which the organic electroluminescent element of the first embodiment of the present invention is used;

FIG. 8 is a sectional view where the organic electroluminescent element used in the exposure apparatus according to the first embodiment of the present invention is constituted in a top-emission structure;

FIG. 9 is a block diagram illustrating a modification of the first embodiment of the present invention;

FIG. 10 is a block diagram illustrating a constitution of an image forming device having the exposure apparatus in which the organic electroluminescent element according to the first embodiment of the present invention is used;

FIG. 11 is a block diagram illustrating the vicinity of a developing station in an image forming device of the first embodiment of the present invention;

FIG. 12 is a circuit diagram illustrating a display device according to the first embodiment of the present invention;

FIG. 13 is a drawing for explaining a pixel of the display device according to the first embodiment of the present invention;

FIG. 14 is a drawing for explaining the upper part of the display device according to the first embodiment of the present invention;

FIG. 15 is a sectional view showing a constitution of an organic electroluminescent element used in an exposure apparatus of an image forming device of the second embodiment of the present invention;

FIG. 16 is a sectional view of an organic electroluminescent element according to the third embodiment of the present invention;

FIG. 17 is a drawing for explaining a manufacturing process of the organic electroluminescent element according to the third embodiment of the present invention;

FIG. 18 is a sectional view of the organic electroluminescent element according to a modification of the third embodiment of the present invention;

FIG. 19 is a drawing for explaining a manufacturing process of the organic electroluminescent element according to the modification of the third embodiment of the present invention;

FIG. 20 is a drawing for explaining the relationship between the ionization potential of an organic electroluminescent element according to the fifth embodiment of the present invention and that of a conventional organic electroluminescent element;

FIG. 21 is a photo showing physical properties on the surface of a pixel restricting layer 114 of the electroluminescent element according to the fifth embodiment of the present invention;

FIG. 22 is a photo showing physical properties on the surface of the pixel restricting layer 114 according to the conventional electroluminescent element;

FIG. 23 is a photo showing a light emitting state of the electroluminescent element used in the exposure apparatus according to the fifth embodiment of the present invention;

FIG. 24 is a photo showing a light emitting state of an electroluminescent element used in a conventional exposure apparatus; and

FIG. 25 is a sectional view showing a constitution of the conventional organic electroluminescent element.

### DETAILED DESCRIPTION OF THE PREFERRED EMBODIMENTS

Hereinafter, a description will be given of embodiments of the present invention with reference to the drawings.

### First Embodiment

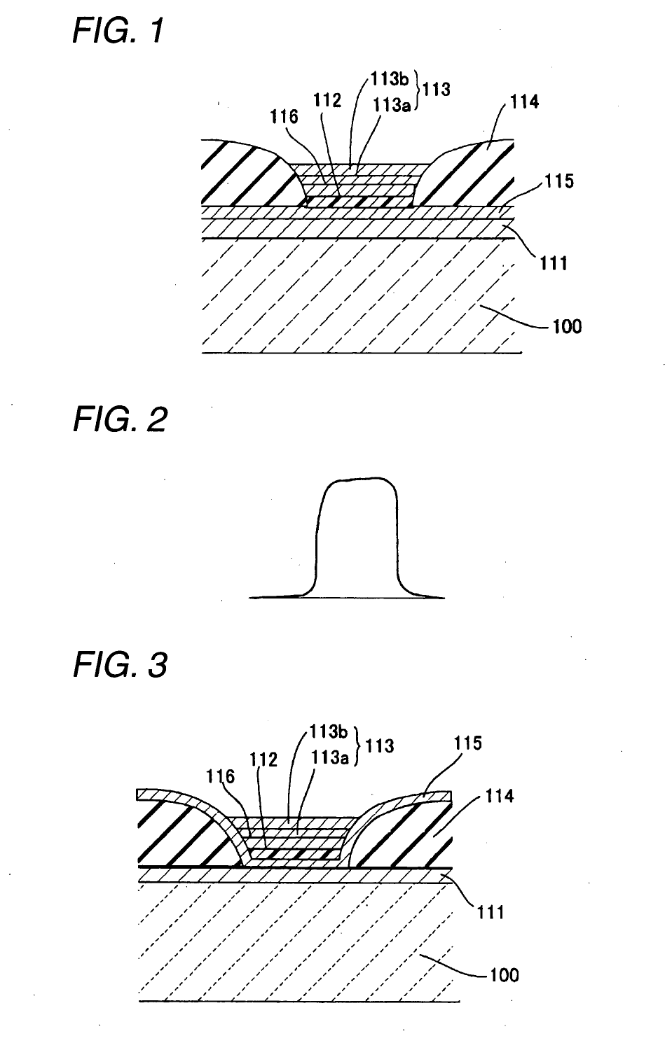

FIG. 1 is a block diagram illustrating an organic electroluminescent element of a first embodiment of the present invention.

As illustrated in FIG. 1, the organic electroluminescent element of the first embodiment is constituted with a substrate 100 based on a translucent glass, ITO (indium tin oxide) as a positive electrode 111 formed on the substrate 100, a transition metal oxide thin film (molybdenum oxide layer) as a charge-injection layer 115 additionally formed on the upper layer thereof, a luminescent layer 112 composed of a polymer material, a transition metal oxide thin film (molybdenum oxide layer) as a buffer layer 116, an intermediate layer 113a composed of Ba, Ca and the like, and an electrode layer 113b formed with a metal material such as Ag, Al, Mg or In (the intermediate layer 113a and the electrode layer 113b are collectively referred to as a negative electrode 113).

As described above, the organic electroluminescent element of the first embodiment has a feature that a molybdenum oxide layer which is a transition metal oxide is interposed between the luminescent layer 112 and the negative electrode 113 as a buffer layer.

Furthermore, the first embodiment may be described as that which is constituted with a layer having the luminescence function (luminescent layer 112) composed of at least one type of organic semiconductors, an electrode (negative electrode 113) for injecting electrons into the layer having the luminescence function, and at least one type of a transition metal oxide layer arranged between the electrode and the layer having the luminescence function.

It is noted that in this instance, the luminescent layer 112 is used by meaning a layer having the luminescence function and shall not be limited to a single luminescent layer but may include layers having other functions such as a charge transport function. From here, a description will be made for a luminescent layer 112 in a simplified manner (the same applies to all the subsequent embodiments).

Where direct-current voltage or direct current is applied, with the positive electrode 111 of the organic electroluminescent element given as a plus electrode and the negative electrode 113 given as a minus electrode, holes are injected into the luminescent layer 112 from the positive electrode 111 via the charge-injection layer 115, and also electrons are injected from the negative electrode 113 via buffer layer 116. In the luminescent layer 112, thus injected holes and electrons are bound again, and a light emitting phenomenon will occur when an exciter formed in association thereof is shifted from an excited state to a normal state. It is noted that upon application of an electric field, an electric field resulting from an external magnetic field or the like may be used.

The organic electroluminescent element of the first embodiment can adjust a carrier balance by using a molybdenum oxide layer formed as the buffer layer 116 and emit light at the center of the luminescent layer in the laminated direction of each layer. Furthermore, the buffer layer 116 can inhibit the breakage of boundary faces and the thermal inactivation of an exciter due to the barrier effect and is also able to prevent the intrusion of impurities from the negative electrode into the luminescent layer in association with the driving, thus making it possible to provide an organic electroluminescent element stable in operation and excellent in life property.

Next, a description will be given of a manufacturing process of an organic electroluminescent element of the present invention.

First, an ITO thin film having a thickness of 20 nm is formed as a positive electrode 111 on the surface of a translucent substrate 100 by a sputtering method.

Then, a molybdenum oxide layer having a thickness of 40 nm is formed as a charge-injection layer 115 by a vacuum deposition method. These layers are together subjected to patterning by photolithography. It is noted that the work function of the molybdenum oxide layer as the charge-injection layer 115 is 5.4 eV, and the transmittance is 80%.

This process may proceed as follows; the ITO thin film is formed on the substrate 100 by a sputtering method, the resultant is subjected to patterning by photolithography, a metal oxide thin film is then formed by a vacuum deposition method, these films are subjected to patterning either by photolithography or masking, thereby producing the positive electrode 111 and the charge-injection layer 115.

It is noted that in the first embodiment, a glass substrate specified as Corning 7029# with a thickness of 1 mm is used as the substrate 100.

Then, a silicon nitride film is formed by a CVD method in which a high-density plasma is used, and an aperture is provided by photolithography, thereby forming a pixel restricting layer 114.

Then, a luminescent layer 112 is formed on the charge-injection layer 115 by a screen printing method. Examples of a luminescent material to be used in the luminescent layer 112 of the first embodiment include 7-diyl)-alt-co-(N,N′-diphenyl)-N,N′di(p-butyl-oxyphenyl)-1,4-diaminobenzene)] and polyfluorene-based compounds having a thickness of 80 nm such as poly[9,9-dioctyl fluorenyl-2,7-diyl]-co-1,4-benxo-{2,1′-3}-thiadiazole]poly[9,9-dioctylfluorenyl-2,7-diyl]-co-1,4-benzo-{2,1′-3}-thiadiazole]]poly[(9,9-dioctylfluorenyl-2,7-diyl)-co-(1,4-benzo-{2,1′-3}-thiadiazole)]Poly[(9,9-dioctylfluorenyl-2,7-diyl)-co-(1,4-benzo-{2,1′-3}-thiadiazole)]. These luminescent materials are available from, for example, Nihon SiberHegner K.K.

Thereafter, a buffer layer 116 composed of molybdenum oxide which is a transition metal oxide is formed to be 40 nm in thickness by a vacuum deposition method.

Then, a negative electrode 113 is finally formed.

The negative electrode 113 is constituted with an intermediate layer 113a composed of a 20 nm-thick calcium (Ca) layer and an electrode layer 113b composed of a 100 nm-thick aluminum (Al) layer (they are to constitute a negative electrode 113).

The negative electrode 113 may be formed as a film, for example, by a sputtering method. A sputtering method can provide an elaborately formed film in a simple manner but known to impart a large amount of damage to an underlying substrate. However, since the buffer layer 116 contains a transition metal oxide on the upper layer of the luminescent layer 112 in the first embodiment, it is possible to greatly reduce the damage of the luminescent layer 112 due to the sputtering.

Furthermore, the negative electrode 113 may be formed on the buffer layer 116 by a CVD method. A CVD method can form a film excellent in step coverage, thus making it possible to form a reliable organic electroluminescent element.

Barium, lithium, cesium or their oxides and halogenides may also be preferably used as the intermediate layer 113a constituting the negative electrode 113, in addition to calcium.

According to the above-described manufacturing method, since the luminescent layer 112 is formed on a molybdenum oxide layer as the charge-injection layer 115 by a screen printing, it can be manufactured easily and also subjected to micro processing and high integration. In the first embodiment, prior to the formation of the molybdenum oxide layer as the buffer layer 116, the luminescent layer 112 is to be formed.

It is noted that the molybdenum oxide layer as the buffer layer 116 also acts as an electron injection layer.

Furthermore, it is possible to interpose other functional layers therebetween. However, in any case, it is desirable to provide such a structure that the luminescent layer 112 is printed on the upper layer of transition metal oxide such as a molybdenum oxide layer by a screen printing method.

The molybdenum oxide layer as the charge-injection layer 115 and the buffer layer 116 in the first embodiment is a non-crystalline thin film prepared by vacuum deposition. In the first embodiment, the molybdenum oxide is mainly made with a stable molybdenum trioxide (MoO₃) among molybdenum oxides. However, an environment in which vacuum deposition is conducted is a reducing atmosphere and molybdenum oxides are subjected to reduction in the course of the vacuum deposition on a substrate after sublimation therein by heating. The thus reduced molybdenum oxides yield some oxides having a smaller oxidation number in addition to hexa-valent MoO₃. They are, for example, tetravalent MoO₂ or trivalent Mo₂O₃. In other words, in the first embodiment (and in all subsequent embodiments), molybdenum oxides are mainly made with MoO₃ but, as a matter of course, they effectively include MoO₂ and Mo₂O₃. To be subjected to reduction is equal to receiving electrons, and oxides which are reduced and made smaller in valence are in a state that they release electrons more easily than an oxide having a larger valence, that is, a state that they are more likely to receive holes. This is equivalent to a fact that they have a higher energy level.

In other words, the buffer layer 116 of the first embodiment is also considered to be constituted with such a transition metal oxide that is different in valence. Although a pure form of MoO₃ is known as a material having an extremely high resistance, the buffer layer 116 is measured for the specific resistance to find 12 MΩcm. According to this constitution, the buffer layer 116 composed of molybdenum oxide is able to have a lower voltage drop, if it is interposed between the luminescent layer 112 and the negative electrode 113.

The buffer layer 116 is preferably from 1 MΩcm (=10⁶ Ωcm) to 1 GΩcm (=10⁹ Ωcm) in specific resistance and more preferably from 10 MΩcm to 100 MΩcm. The buffer layer 116, the specific resistance of which is in this range, can prevent a drastic voltage drop of the buffer layer 116, as described above.

Furthermore, since the buffer layer 116 is excellent in electron injection potency and provided with an electron transport property and also a hole blocking property, light can be emitted at the center of the luminescent layer 112 (indicating the central portion in the laminated direction of each layer) by adjusting, for example, the thickness and the specific resistance. It is, therefore, possible to provide an organic electroluminescent element high in brightness and long in life.

Furthermore, in the first embodiment, as described above, a molybdenum oxide layer as the charge-injection layer 115 is arranged also on the lower layer of the luminescent layer 112.

Then, the pixel restricting layer 114 for restricting the light emitting region of an organic electroluminescent element is provided on the charge-injection layer 115.

According to this constitution, since an underlying layer on which the pixel restricting layer 114 is placed is sufficiently smoothened by the charge-injection layer 115, the pixel restricting layer 114 can retain a sufficient insulation property, even if the pixel restricting layer 114 is made thin. Thereby, a step resulting from the pixel restricting layer 114 can be decreased and the luminescent layer 112 is made more uniform in thickness distribution. As a result, a short circuit between the positive electrode 111 and the negative electrode 113 can be decreased to a great extent.

In this instance, the pixel restricting layer 114 may be constituted with a light blocking material, not with an insulating material. Furthermore, even if a material is used which has both a light blocking effect and an insulation property, it can effectively restrict a light outgoing region.

In the first embodiment, the buffer layer 116 composed of molybdenum oxide is interposed between the luminescent layer 112 and the negative electrode 113, the charge-injection layer 115 composed of thick molybdenum oxide is used to planarize and smooth the surface of the substrate 100, and the luminescent layer 112 is thereafter formed by a screen printing method.

More specifically, in the first embodiment, an underlying layer (molybdenum oxide layer as the charge-injection layer 115) is smoothened so as to make the surface mean roughness (Ra) to be 20 nm or lower in formation of the luminescent layer 112, and subjected to screen printing. It is, therefore, possible to provide a luminescent layer pattern with great accuracy. Planarization of the underlying layer allows the pixel restricting layer 114 to be available as a thin film, with a sufficient insulation property retained, thereby decreasing a step difference at an edge portion on the pixel restricting layer 114. As a result, the luminescent layer 112 is made more uniform in thickness distribution. FIG. 2 shows the results obtained on measurement of the luminescence properties.

FIG. 2 is a drawing showing the luminescence properties of an organic electroluminescent element of the first embodiment of the present invention.

In this instance, the abscissa indicates a position, and the ordinate indicates a luminescence intensity. As apparent from FIG. 2, the luminescence intensity is formed in a rectangular profile, exhibiting the favorable luminescence properties (in-plane distribution).

FIG. 3 is a block diagram illustrating an organic electroluminescent element of a modification of the first embodiment of the present invention. In this electroluminescent element, the surface of the pixel restricting layer 114 is entirely covered with a molybdenum oxide layer as a charge-injection layer 115.

The molybdenum oxide layer as the charge-injection layer 115 is different from that described in the first embodiment in that it is subjected to surface plasma processing so that the surface mean roughness is given Ra: 15 nm, and a luminescent layer 112 is formed thereafter on the upper layer thereof by screening printing. All the others are formed in a similar manner as those of the first embodiment.

In the modification of the first embodiment as well, a molybdenum oxide layer as a buffer layer 116 is formed on the luminescent layer 112. Furthermore, since the molybdenum oxide layer covers from a region which is given as a light outgoing region to the pixel restricting layer 114, there is found a decreased influence resulting from a step difference at a boundary portion between a light emitting region and a non-light emitting region, whereby the luminescent layer 112 is formed on a smoother surface. Thereby, the luminescent layer 112 is made uniform in thickness distribution, resulting in a prolonged life of an organic electroluminescent element.

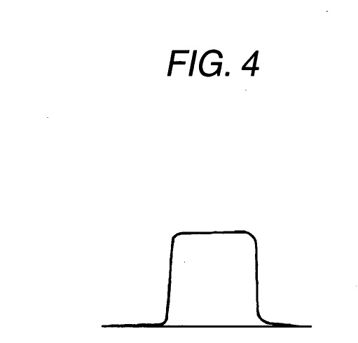

FIG. 4 shows the result obtained on measurement of the luminescence properties in this instance.

FIG. 4 is a drawing showing the luminescence properties of an organic electroluminescent element of the first embodiment of the present invention.

Here, the abscissa indicates a position, and the ordinate indicates a luminescence intensity. As apparent from FIG. 4, the organic electroluminescent element of the modification of the first embodiment has a rectangular luminescent profile, exhibiting the favorable luminescence properties. The light emitting profile is slightly steep, as compared with that of the first embodiment shown in FIG. 2.

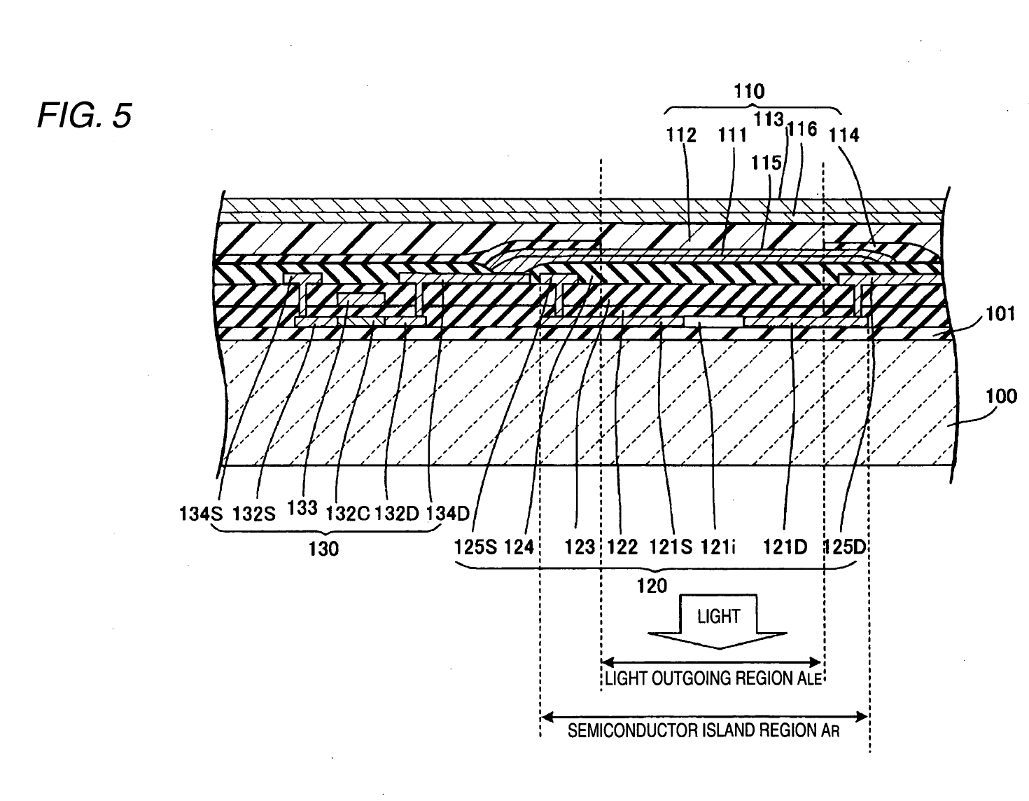

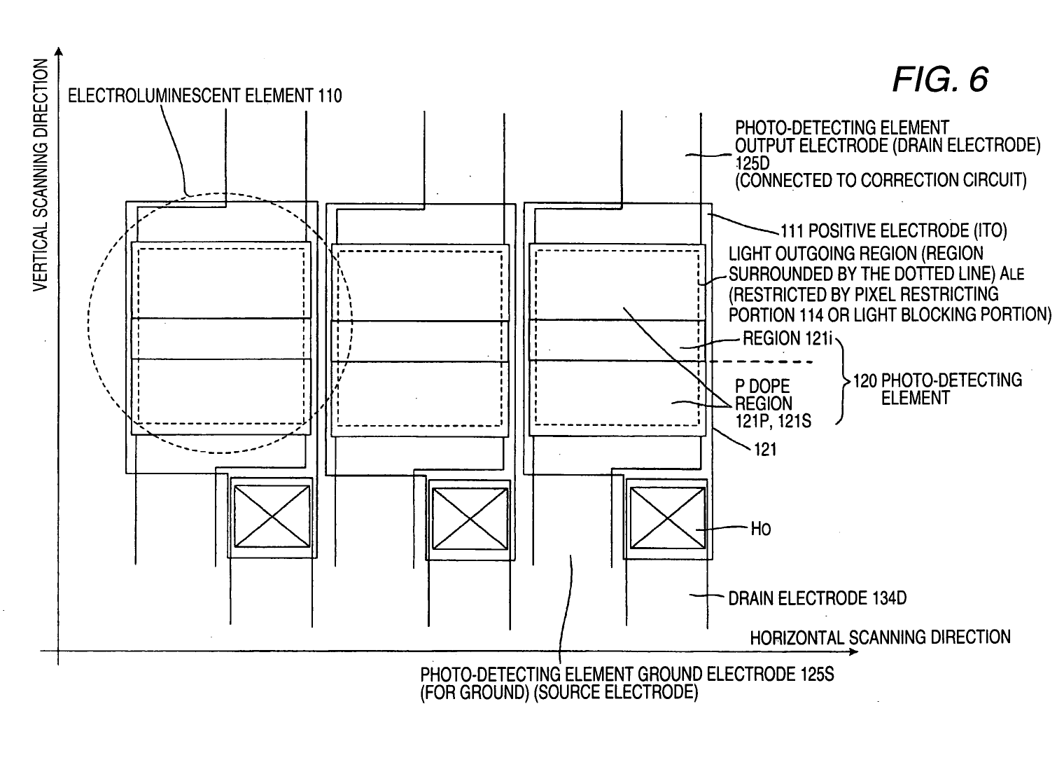

FIG. 5 is a block diagram illustrating a constitution where the electroluminescent element of the first embodiment of the present invention is applied to an exposure apparatus. FIG. 6 is a plan view showing a constitution in the vicinity of a photo-detecting element of the exposure apparatus in which the organic electroluminescent element of the first embodiment of the present invention is used.

The exposure apparatus of the first embodiment is provided with an integrated structure in which a photo-detecting element 120 is formed on the lower layer of an electroluminescent element 110. FIG. 5 illustrates the electroluminescent element 110 as a light source and the vicinity thereof, showing a vertically arranged relationship of respective layers constituting the photo-detecting element 120.

In the first embodiment, the photo-detecting element 120 and the electroluminescent element 110 as a light source are laminated on a substrate 100, and they are formed in an integrated form one-dimensionally as a plurality of luminescence units and constituted as a monolithic device. Then, a luminescent layer 112 of the electroluminescent element 110 is formed by a screen printing method.

The electroluminescent element 110 is provided with a first electrode as a positive electrode 111, a second electrode as a negative electrode 113, and a luminescent layer 112, that is, a layer having a luminescence function composed of at least one type of organic semiconductor formed between these electrodes, and further provided with a 40 nm-thick charge-injection layer 115 constituted with a transition metal oxide (molybdenum oxide) between the positive electrode 111 and the luminescent layer 112, a pixel restricting layer 114 composed of a 50 nm-thick silicon nitride film on the upper layer thereof, a buffer layer 116 composed of molybdenum oxide and a negative electrode 113 on the upper layer thereof. As described above, a buffer layer 116 is provided with a structure sandwiched between the luminescent layer 112 and the negative electrode 113.

A molybdenum oxide layer as the charge-injection layer 115 is formed in a thickness of 40 nm which is not realized conventionally, and the surface mean roughness is made so as to be Ra=20 nm or lower. Thereby, the surface is sufficiently planarized and smoothened to form the luminescent layer 112 by a screen printing method. It is, therefore, possible to give a favorable pattern to the luminescent layer 112 and also accurately restrict the area of a light emitting region.

In this instance, a silicon nitride film as the pixel restricting layer 114 is formed by a low temperature CVD method in which high-density plasma is used so as to give a thickness of approximately 50 nm. Then, a resist pattern is formed by photolithography and etching is conducted to provide an aperture. First, anisotropic etching is conducted and isotropic etching is then conducted to form a smoothly edged pattern. In this instance, an angle with respect to an underlying layer on pattering the edge is to range from 3 to 10 degrees.

As illustrated in FIG. 5, the exposure apparatus is formed in such a way that the electroluminescent element 110 is laminated on the upper layer of a thin film transistor (TFT) constituting the photo-detecting element 120 formed on the substrate 100 and the positive electrode 111 as a first electrode positioned on the photo-detecting element 120 of the electroluminescent element 110 covers a whole part of a photoelectric conversion portion of the photo-detecting element 120 (photo-detecting element 120 shown in FIG. 6, more strictly, channel region 121i), therefore, the first electrode of the electroluminescent element 110 is opposed to a whole part of the photoelectric conversion portion of the photo-detecting element 120. According to this constitution, the first electrode effectively acts as a gate electrode of the photo-detecting element 120 to securely control the channel characteristics of the photo-detecting element 120 by the potential of the first electrode, which is a stable potential, thereby making it possible to accurately detect a light emitting quantity of the electroluminescent element 110. It is, therefore, possible to provide an exposure apparatus having stable luminescence properties.

Furthermore, in the exposure apparatus, the outer boundary of an island region 121 of polycrystalline silicon constituting an element region of the photo-detecting element 120 is formed so as to be outside a light outgoing region A_{LE} of the electroluminescent element 110. As described above, the island region 121 of the photo-detecting element 120 which results in a step formation, or in this instance, the outer boundary of the element region A_{R} is formed so as to be outside the light outgoing region A_{EL} of the electroluminescent element 110. Therefore, no step is found resulting from the photo-detecting element 120 at a region corresponding to a light outgoing region of the electroluminescent element 110, and a flat surface is constituted by the underlying layer of the luminescent layer 112, whereby an exposure apparatus has a uniform luminescent layer at the light outgoing region which is an effective region of the exposure apparatus.

Furthermore, the molybdenum oxide layer of the charge-injection layer 115 can be given a desired surface state by adjusting film-forming conditions, for example, formation of the layer at a low temperature. Still furthermore, the desired surface state can be easily obtained in such a way that the pixel restricting layer 114 is formed, and the surface processing such as plasma patterning is conducted after or concurrently with patterning to adjust the surface roughness.

The exposure apparatus having the organic electroluminescent element of the first embodiment is, as illustrated in FIG. 5, provided with a photo-detecting element 120 and an electroluminescent element 110, that is, luminescent element, which are sequentially laminated on the substrate 100 having a base coat layer 101 for planarization on the surface thereof, a driving transistor 130 which is constituted with a thin film transistor for driving the electroluminescent element 110, with the driving current or the driving time being corrected, depending on the output of the photo-detecting element 120, and a driving circuit (not illustrated) as a chip IC connected to the driving transistor 130.

Then, the photo-detecting element 120 is constituted with a source region 121S and a drain region 121D formed by doping a semiconductor island region A_{R} composed of a polycrystalline silicon layer formed on the surface of the base coat layer 101 to a desired concentration apart from channel region 121i composed of a band-form i layer, and a source electrode 125S and a drain electrode 125D formed via a through hole so as to penetrate through a first insulative film 122 and a second insulative film 123 composed of an oxide silicon film formed on the upper layer thereof. Furthermore, the electroluminescent element 110 is formed on the upper layer thereof via a silicon nitride film as a protective film 124. And, ITO (indium tin oxide) which gives a positive electrode 111 as a first electrode, a pixel restricting layer 114 which is an insulative film covering a part of the positive electrode to specify an aperture, a luminescent layer 112, and a negative electrode 113 as a second electrode are laminated individually in the order so described. In this instance, the light outgoing region A_{LE} is restricted by the pixel restricting layer 114 which is an insulative film.

As apparent from the drawing, the photo-detecting element 120 is formed at a semiconductor region (that is, semiconductor island region A_{R}) formed in an island form on the substrate 100. The light outgoing region A_{LE} of the electroluminescent element 110 is arranged inside the semiconductor island region A_{R}, and an electrode (positive electrode 111) located on the lower layer of the electroluminescent element 110 is formed so as to cover the semiconductor island region A_{R}.

Furthermore, the light outgoing region A_{LE} in this instance is to be specified by an aperture provided on an insulative film (pixel restricting layer 114) interposed between the first electrode (positive electrode 111) and the luminescent layer 112. It is noted that the pixel restricting layer 114 may be formed between the second electrode (negative electrode 113) and the luminescent layer 112, thereby specifying the aperture.

On the other hand, each of the layers constituting the photo-detecting element 120 is formed on the same layer in the same manufacturing process as that of the driving transistor 130 constituted with a thin film transistor. More specifically, a source region 132S and a drain region 132D are formed in the same process as the semiconductor island region A_{R} of the photo-detecting element 120 by interposing a channel region 132C in the driving transistor 130 therebetween, constituting the driving transistor 130, together with the source electrode 134S, the drain electrode 134D and the gate electrode 133 which are in contact with the source region 132S and the drain region 132D.

These layers are formed through ordinary semiconductor manufacturing processes such as formation of a semiconductor thin film prepared by a CVD method, a sputtering method or a vacuum deposition method; poly crystallization by annealing; patterning by photolithography; etching; injection of impurity ions; and formation of an insulative film and a metal film.

In this instance, the substrate 100 is one sheet of colorless transparent glass. Examples of the substrate 100 include inorganic oxide glass such as transparent or semi-transparent soda lime glass, barium/strontium containing glass, lead glass, alumino-silicate glass, borosilicate glass, barium/borosilicate glass and quartz glass, or inorganic glass such as inorganic fluoride glass. In general, where a thin film transistor is formed on the surface, often used is borosilicate glass represented by #1737 made by Corning Inc.

Other materials may be used in place of the substrate 100, and examples include, polymer films prepared by using polymers such as transparent and semi-transparent polyethylene terephthalate, polycarbonate, polymethyl methacrylate, polyether sulfone, polyvinyl fluoride, polypropylene, polyethylene, polyacrylate, non-crystalline polyolefin, fluorine-based resins such as polysiloxane and polysilane, or chalcogenoide glass such as transparent and semi-transparent As₂S₃, As₄₀S₁₀, S₄₀Ge₁₀, or materials like metal oxides and nitrides, such as ZnO, Nb₂O, Ta₂O₅, SiO, Si₃N₄, HfO₂, TiO₂, or semiconductor materials such as opaque silicon, germanium, carbonized silicon, gallium arsenide and gallium nitride where light emitted from a light emitting region is taken not via a substrate, or the above-described transparent substrate materials containing pigments and the like, or metal materials, the surface of which is subjected to insulation. They may be selected appropriately according to necessity. A laminated substrate may be used on which a plurality of substrate materials are laminated. Alternatively, such a substrate may be used that the surface is insulated by forming an insulative film based on an inorganic insulating material such as SiO₂ and SiN or an organic insulating material such as resin coated on the surface of an electric conductive substrate composed of metal such as Fe, Al, Cu, Ni, Cr or their alloy.

As will be described later, a circuit for driving the electroluminescent element 110 which is composed of a resistor, a capacitor, an inductor, a diode, a transistor and the like may be formed in an integrated manner on the substrate 100 or inside the substrate.

Furthermore, a material which will permeate only a specific wavelength or a material having the function of light-to-light conversion, thereby converting light to that having a specific wavelength may be used, depending on an application. Still furthermore, the substrate is preferably of an insulation property but not restricted thereto in particular and may be electrically conductive to such an extent that will not prevent the electroluminescent element 110 from being driven or dependent on an application.

A base coat layer 101 may be constituted with two layers, for example, a first layer composed of SiN and a second layer composed of SiO₂. Each of the SiN and the SiO₂ layers may be formed by a vacuum deposition method or the like. However, it is preferable to form the layers by a sputtering method or a CVD method.

A driving transistor 130 of the electroluminescent element 110 and a photo-detecting element 120 are formed on the base coat layer 101 by using a polycrystalline silicon layer formed in the same process. A circuit for driving the electroluminescent element 110 is constituted with a circuit element composed of a resistor, a capacitor, an inductor, a diode, a transistor and the like, a wiring which connects them electrically and a contact hole (through hole). It is preferable to use a thin film transistor when the miniaturization of an exposure apparatus is taken into account. As apparent in FIG. 5, in the first embodiment, the photo-detecting element 120 is located halfway between the electroluminescent element 110 containing a luminescent layer 112 and the substrate 100 which acts as a light output face, and also the semiconductor island region A_{R} of the photo-detecting element 120 is larger in area than the light outgoing region A_{LE}.

As illustrated in FIG. 6, when the electroluminescent element 110 is viewed from above, the light outgoing region A_{LE} is inside the photo-detecting element 120, thereby, making it impossible to use a light impermeable material in the photo-detecting element 120. Therefore, in order that light emitted from the luminescent layer 112 is not prevented from being radiated outside the substrate 100, a transparent material must be used in the photo-detecting element 120. For example, polycrystalline silicon is preferably selected as a transparent material for the photo-detecting element 120.

In the first embodiment, after a uniform semiconductor layer is formed on the base coat layer 101, the semiconductor is subjected to etching, thereby forming a driving transistor 130 and a photo-detecting element 120 from the same layer. Processing by which the driving transistor 130 and the photo-detecting element 120 are formed together in an independent island shape from the same semiconductor layer is advantageous in reducing the manufacture-related man-hours and costs. Furthermore, in the photo-detecting element 120, a semiconductor island region A_{R} for receiving light output at a light outgoing region A_{LE} is the surface of polycrystalline silicon or non-crystalline silicon which is constituted in an island shape to give the photo-detecting element 120.

A first insulative film 122 composed of, for example, an oxide silicon film, a second insulative film 123 and a protective film 124 are provided on the driving transistor 130 for applying an electric field to the luminescent layer 112 of the electroluminescent element 110 and the photo-detecting element 120. The insulative film and the protective film 124 act on the photo-detecting element 120 as a gate insulative film when the positive electrode 111 is regarded as a gate electrode, and an extent dropped from a potential of the positive electrode 111 is determined by a voltage drop resulting from the film thickness thereof. The first insulative film 122, the second insulative film 123 and the protective film 124 constituting the gate insulative film are formed by a deposition method, a sputtering method, a CVD method or the like.

Furthermore, a gate electrode 133 is formed on the surface of the first insulative film 122 as a gate insulative film immediately above the driving transistor 130. The gate electrode 133 is made with a metal material, for example, Cr and Al. Where the electrode 133 must be made transparent, it is made with ITO or a laminated structure of a thin film metal and ITO. The gate electrode 133 is formed by a deposition method, a sputtering method, a CVD method or the like.

The second insulative film 123 is formed on the surface of a substrate on which the gate electrode 133 is formed. The second insulative film 123 is formed all over the surface of a laminated body so far formed. The second insulative film 123 is composed of SiN or others and formed by a deposition method, a sputtering method, a CVD method or the like.

On the second insulative film 123 formed are a drain electrode 125D as a photo-detecting element output electrode, a source electrode 125S as a photo-detecting element ground electrode, a source electrode 134S of the driving transistor 130, and a drain electrode 134D. The drain electrode 125D as a photo-detecting element output electrode and the source electrode 125S as a photo-detecting element ground electrode are respectively connected to the source region 121S and the drain region 121D of the photo-detecting element 120, transmitting an electric signal output from the photo-detecting element 120 and grounding the photo-detecting element 120. On the other hand, the source electrode 134S and the drain electrode 134D are respectively connected to the source region 132S and the drain region 132D of the driving transistor 130, imparting a predetermined potential to the above-described gate electrode 133, with a predetermined potential difference kept between the source electrode 134S and the drain electrode 134D, whereby an electric field is applied to the channel region 132C, and the driving transistor 130 is given a function of a switching element, acting as a circuit for driving the electroluminescent element 110 as a luminescent element.

The drain electrode 125D as a photo-detecting element output electrode, the source electrode 125S as a photo-detecting element ground electrode, and the source electrode 134S and the drain electrode 134D of the driving transistor 130 are made with a metal such as Cr or Al. Where transparency is needed they are made with ITO or a laminated structure of a thin film metal and ITO.

As illustrated in FIG. 5, the drain electrode 125D as a photo-detecting element output electrode and the photo-detecting element ground electrode are allowed to pass through a first insulative film 122 and a second insulative film 123, and electrically connected to the photo-detecting element 120. On the other hand, the source electrode 134S and the drain electrode 134D are also allowed to pass through the first insulative film 122 and the second insulative film 123, and electrically connected to the driving transistor 130. Therefore, before the drain electrode 125D as a photo-detecting element output electrode, the source electrode 125S as a photo-detecting element ground electrode, the source electrode 134S of the driving transistor 130 and the drain electrode 134D are formed, it is necessary to provide through holes for connecting the drain electrode 125D as a photo-detecting element output electrode and the source electrode 125S as a photo-detecting element ground electrode with the photo-detecting element 120 and also through holes for connecting a source electrode 134S and a drain electrode 134D with the driving transistor 130, with respect to the first insulative film 122 and the second insulative film 123.

These through holes have a depth leading to a point where the surface of the photo-detecting element 120 and that of the driving transistor 130 are exposed, that is, a face on which the photo-detecting element 120 is in contact with the drain electrode 125D and the source electrode 125S and a face on which the driving transistor 130 is in contact with the source electrode 134S and the drain electrode 134D are exposed, and formed by etching or the like immediately above the photo-detecting element 120 and the edge of the driving transistor 130, respectively. Etching is conducted by using a halogen-based etching gas. In a state that a resist pattern on which an aperture is provided by photolithography is used to cover the surface, the etching gas is introduced to effect patterning, whereby through holes formed on a first insulative film 122 and a second insulative film 123. In this instance, the etching gas should be selected from a gas which will not chemically react with materials constituting the photo-detecting element 120 and the driving transistor 130.

After completion of such processing that exposes a face on which the drain electrode 125D as a photo-detecting element output electrode and the source electrode 125S as a photo-detecting element ground electrode are in contact with the photo-detecting element 120 and a face on which the source electrode 134S and the drain electrode 134D are in contact with the driving transistor 130, there are formed the drain electrode 125D as a photo-detecting element output electrode, the source electrode 125S as a photo-detecting element ground electrode, the source electrode 134S of the driving transistor 130, and the drain electrode 134D. The source electrode 134S and the drain electrode 134D are provided according to the procedure in which a metal layer acting as a sensor electrode is uniformly formed on the surface of the second insulative film 123, the surface of the above-described through hole, both sensor electrodes, the surface of the photo-detecting element 120 and a contact surface of the driving transistor 130, the metal layer is, thereafter, subjected to etching, and the thus uniformly prepared metal layer is divided into the drain electrode 125D as a photo-detecting element output electrode, the source electrode 125S as a photo-detecting element ground electrode, the source electrode 134S and the drain electrode 134D.

A protective film 124 is formed after formation of the drain electrode 125D as a photo-detecting element output electrode, the source electrode 125S as a photo-detecting element ground electrode, the source electrode 134S and the drain electrode 134D. The protective film 124 is made from SiN or the like and formed by a deposition method, a sputtering method, a CVD method or the like.

A positive electrode 111 is formed on the protective film 124. The positive electrode 111 is made with ITO (indium tin oxide), for example. The positive electrode 111 may be constituted with IZO (zinc-doped indium oxide), ATO (Sb-doped SnO₂), AZO (Al-doped ZnO), ZnO, SnO₂ or In₂O₃, in addition to ITO. As shown in FIG. 5, the positive electrode 111 is formed on the surface of the protective film 124, which is located immediately above the photo-detecting element 120.

As clearly illustrated in FIG. 5 and FIG. 6, the positive electrode 111 is formed above a photo-detecting element 120 constituted with a semiconductor island region A_{R} formed on the substrate 100 via the first insulative film 122 and the second insulative film 123. The positive electrode 111 is set to be larger than the photo-detecting element 120, and the photo-detecting element 120 is constituted so as to be at the inner side than the outer boundary of the positive electrode 111.

As shown in FIG. 5, the positive electrode 111 is allowed to pass through the protective film 124 and electrically connected to the drain electrode 134D of the driving transistor 130. It is, therefore, necessary to provide a through hole for connecting the positive electrode 111 with the drain electrode 134D on the protective film 124 before the positive electrode 111 is formed. The through hole has a depth leading to a point where the surface of the drain electrode 134D is exposed, that is, a face on which the drain electrode 134D is in contact with the positive electrode 111 is exposed, and provided immediately above the edge of the drain electrode 134D by etching or the like. After the etching is conducted, the positive electrode 111 is formed as a layer. The positive electrode 111 can be formed by a deposition method. However, a sputtering method or a CVD method is preferable in obtaining the elaborately constituted positive electrode 111 excellent in resistance and transmittance.

After the positive electrode 111 is formed, inorganic insulating materials such as silicon nitride film, oxide silicon film, silicon oxynitride, titanium oxide, aluminum nitride and aluminum oxide or organic insulating materials such as polyimide and polyethylene are used to form a pixel restricting layer 114. The pixel restricting layer 114 is desirably made with a material high in insulation property, highly resistant to insulation breakdown, excellent in film formability and great in patterning property, as described previously. The pixel restricting layer 114 is a member for restricting a light outgoing region, specifying by using an aperture provided on an insulative film interposed between the first electrode or the second electrode and the luminescent layer.

In the first embodiment, silicon nitride or aluminum nitride is used as a material for constituting a silicon nitride film as the pixel restricting layer 114. The pixel restricting layer 114 is provided between a luminescent layer 112 which will be described later and the positive electrode 111, insulating the luminescent layer 112 in a region which is outside the light outgoing region A_{LE} from the positive electrode 111 and restricting a site at which the luminescent layer 112 emits light. Therefore, a region of the luminescent layer 112 superimposed on the pixel restricting layer 114 is a non-light emitting region, whereas a region not superimposed on the pixel restricting layer 114 is a light outgoing region A_{LE}. The pixel restricting layer 114 is constituted in such a way that the light outgoing region A_{LE} of the luminescent layer 112 is restricted to be made smaller in area than the semiconductor island region A_{R} of the photo-detecting element 120 and the light outgoing region A_{LE} is arranged inside the semiconductor island region A_{R} of the photo-detecting element 120.

After a silicon nitride film is formed as the pixel restricting layer 114, a luminescent layer 112 is formed by a screen printing method.

The luminescent layer 112 is made with inorganic luminescent materials, or polymer and small-molecular organic luminescent materials which will be described in detail later. Examples of inorganic luminescent materials for forming the luminescent layer 112 include potassium titanyl phosphate, barium boron oxide and lithium boron oxide.

Materials having the fluorescence or phosphorescence characteristics at a visible region and excellent in film formability are desirable as a polymer organic luminescent material which constitutes the luminescent layer 112, including, for example, polymer luminescent materials composed of polyparaphenylene vinylene (PPV), polyfluorene or their derivatives.

The polymer luminescent layer 112 may include, for example, an organic compound having a dendritic multi-branched structure such as dendrimer. Since this organic compound is provided with a dendritic multi-branched polymer structure or a dendritic multi-branched small-molecular structure in which a luminescent structural unit is surrounded three dimensionally by a plurality of external structural units, the luminescent structural unit is kept isolated three dimensionally, and the organic compound in itself assumes a fine-particle like configuration. Therefore, when formed in a thin film shape, adjacent luminescent structural units are prevented from coming close to each other to result in a uniform distribution of the luminescent structural units in the thin film due to the presence of external structural units. It is, therefore, possible to emit light at a greater intensity and with longer life.

Small-molecular organic luminescent materials which constitute the luminescent layer 112 include, in addition to Alq₃ and Be-benzoquinolinol (BeBq₂), benzoxazole-based fluorescent brightening agents such as 2,5-bis(5,7-di-t-pentyl-2-benzoxazolyl)-1,3,4-thiadiazole, 4,4′-bis(5,7-bentyl-2-benzoxazolyl) stilbene, 4,4′-bis[5,7-di-(2-methyl-2-butyl)-2-benzoxazolyl]stilbene, 2,5-bis(5,7-di-t-bentyl-2-benzoxazolyl)thiophine, 2,5-bis([5-α,α-dimethylbenzyl]-2-benzoxazolyl)thiophene, 2,5-bis[5,7-di-(2-methyl-2-butyl)-2-benzoxazolyl]-3,4-diphenyl thiophene, 2,5-bis(5-methyl-2-benzoxazolyl)thiophene, 4,4′-bis(2-benzoxazolyl)biphenyl, 5-methyl-2-[2-[4-(5-methyl-2-benzoxazolyl)phenyl]vinyl]benzoxazolyl, 2-[2-(4-chlorophenyl)vinyl]naphtho[1,2-d]oxazole; benzothiazole-based fluorescent brightening agents such as 2,2′-(p-phenylene divinylene)-bisbenzothiazole; benzoimidazole-based fluorescent brightening agents such as 2-[2-[4-(2-benzoimidazolyl)phenyl]vinyl]benzoimidazole, 2-[2-(4-carboxyphenyl)vinyl]benzoimidazole; 8-hydroxyquinoline-based metal complexes such as tris (8-quinolinol)aluminum bis(8-quinolinol) magnesium, bis(benzo[f]-8-quinolinol)zinc, bis(2-methyl-8-quinolinolate)aluminum oxide, tris(8-quinolinol)indium, tris(5-methyl-8-quinolinol)aluminum, 8-quinolinol lithium, tris(5-chloro-8-quinolinol)potassium, bis(5-chloro-8-quinolinol)calcium, poly [zinc-bis(8-hydroxy-5-quinolinonyl)methane]; metal chelating oxinoide compounds such as dilithium epindorlydion; stylylbenzene-based compounds such as 1,4-bis(2-methylstylyl)benzene, 1,4-(3-methylstylyl)benzene, 1,4-bis(4-methylstylyl)benzene, distylyl benzene, 1,4-bis(2-ethylstylyl)benzene, 1,4-bis(3-ethylstylyl)benzene, 1,4-bis(2-methylstyl)2-methyl benzene; distylpyrazine derivatives such as 2,5-bis(4-methylstyl)pyrazine, 2,5-bis(4-ethylstylyl)pyrazine, 2,5-bis[2-(1-naphytyl)vinyl]pyrazine, 2,5-bis(4-methoxystylyl)pyrazine, 2,5-bis[2-(4-viphenyl)vinyl]pyrazine, 2,5-bis[2-(1-pirenyl)vinyl]pyrazine; naphthal imide derivatives; perilene derivatives; oxadiazole derivatives; aldazine derivatives; cyclopentadiene derivatives; styrylamine derivatives; coumarin derivatives and aromatic dimetylidyne derivatives. Furthermore, anthracene, salicylate, pyrene, coronene, and others are also used. Still furthermore, phosphorescence luminescent materials such as fac-tris (2-phenylpyridine)iridium and the like are also usable.

The luminescent layer 112 composed of a polymer material and a small-molecular material is obtained by procedures in which a material is dissolved in a solvent such as toluene or xylene, the resultant is formed in a layer by a wet-type film forming method such as a spin coating method, an ink jet method, a gap coating method or a printing method, by which the dissolved solvent is volatilized. The luminescent layer 112 composed of a small-molecular material is in general obtained by procedures in which the material is laminated by a vacuum deposition method, a deposition polymerization method or a CVD method and formed by any one of these methods, with characteristics of a luminescent material taken into account.

Furthermore, in the first embodiment, the luminescent layer 112 is described as a single layer for the sake of convenience. However, the luminescent layer 112 may be formed in a three-layered structure consisting of hole transport layer/electron blocking layer/above-described organic luminescent material layer (any of them not illustrated) in the order from the side of the positive electrode 111. Alternatively, the luminescent layer 112 may be formed in a two-layered structure consisting of electron transport layer/organic luminescent material layer (either of them not illustrated) in the order from the side of the negative electrode 113, or in a two-layered structure consisting of hole transport layer/organic luminescent material layer (either of them not illustrated) in the order from the side of the positive electrode 111, or in a seven-layered structure consisting of hole injection layer/hole transport layer/electron blocking layer/organic luminescent material layer/hole blocking layer/electron transport layer/electron injection layer (any of them not illustrated) in the order from the side of the negative electrode 113. Furthermore, the luminescent layer 112 may be simply formed in a single layered structure made by the above organic luminescent material alone. It may also be formed in a structure in which a mixed layer made up of materials having the individual functions is used or the mixed layer is laminated.

Where in the first embodiment, the luminescent layer 112 is referred to as a functional layer, such reference includes a sole constitution of the luminescent layer 112 and a multi-layered structure in which functional layers such as the luminescent layer 112, the hole transport layer, the electron blocking layer, the electron transport layer and others are used, as described above. This is also applicable similarly to other embodiments that will be described later.

The above-described hole transport layer is preferably high in hole mobility, transparent and high in film formability, including, in addition to TPD, organic materials, that is, porphyrin compounds such as porphin, tetraphenyl porphin copper, phthalocyanine, copper phthalocyanine, titanium phthalocyanine oxide; aromatic tertiary amines such as 1,1-bis{4-(di-p-tolylamino)phenyl}cyclohexane, 4,4′,4-trimethyl triphenylamine, N,N,N′,N′-tetrakis(p-tolyl)-p-phenylene diamine, 1-(N,N-di-p-tolylamino)naphthalene, 4,4′-bis(dimethyl amino)-2-2′-dimethyl triphenyl methane, N,N,N′,N′-tetraphenyl-4,4′-diamino biphenyl, N,N′-diphenyl-N,N′-di-m-tolyl-4,4′-diamino biphenyl, N-phenyl carbazole; stilbene compounds such as 4-di-p-tolylamino stilbene, 4-(di-p-tolylamino)-4′-[4-(di-p-tolylamino)stylyl]stilbene; triazole derivatives; oxadizazole derivatives; imidazole derivatives; polyaryl alkane derivatives; pyrazoline derivatives; pyrazolone derivatives; phenylene diamine derivatives; anneal amine derivatives; amino-substituted chalcone derivatives; oxazole derivatives; stylyl anthracene derivatives; fluorenone derivatives; hydrazone derivatives; silazane derivatives; polysilane-based and aniline-based co-polymers; polymer oligomers; stylylamine compounds; aromatic dimethylidyne compounds; or polythiophene derivatives such as poly-3,4ethylene dioxythiophene (PEDT), tetradihexyl fluorenyl biphenyl (TFB) and polly 3-methylthiophene (PMeT). Furthermore, a polymer dispersion hole transport layer in which an organic material for a small-molecular hole transport layer is dispersed in a polymer substance such as polycarbonate is also usable.

Still furthermore, inorganic oxides such as MoO₃, V₂O₅, WO₃, TiO₂, SiO and MgO may be used. In particular, the use of transition metal oxides such as MoO₃ and V₂O₅ as a hole transport layer can provide an organic electroluminescent element excellent in efficiency and long in life. These hole transport materials may also be used as electron blocking materials.

Examples of the above-described electron transport layer include polymer materials such as oxadiazole derivatives such as 1,3-bis(4-tert-butylphenyl-1,3,4-oxadiazie)phenylene (OXD-7), anthraquinodimethane derivatives; diphenyl quinone derivatives and syrol derivatives, or bis(2-methyl-8-quinolynolate)-(para phenylphenolate), aluminum (BAlq) and vasofuploin (BCP). Materials which can constitute these electron transport layers may be used as a hole blocking material.

After a luminescent layer 112 is formed, and then after a 40 nm-thick buffer layer 116 (molybdenum oxide layer) is formed by a vacuum deposition method, a negative electrode 113 is formed.

The negative electrode 113 is provided by forming, for example, a metal such as Al into a layer according to a vacuum deposition method. A metal or an alloy low in work function, for example, metals such as Ag, Al, In, Mg, Ti, or Mg-based alloys such as Mg—Ag alloy, Mg—In alloy, and Al-based alloys such as Al—Li alloy, Al—Sr alloy, Al—Ba alloy are usable as the negative electrode 113 of the electroluminescent element 110. A metal laminated structure may also be used, which is composed of a first electrode layer in contact with an organic compound layer made up of metals such as Ba, Ca, Mg, Li and Cs or fluorides and oxides of metals such as LiF and CaO and a second electrode made up of metal materials such as Ag, Al, Mg and In formed thereon.

Furthermore, in this instance, the buffer layer 116 is 80% in transmittance at 650 nm which is a peak luminous wavelength of the organic electroluminescent element 110. The buffer layer 116 whose transmittance is increased up to 70% or greater may be applied to a top emission-type luminescent element. In future, when the organic electroluminescent element 110 is made to be short in luminous wavelength, for example, similar to that of a currently available laser diode (780 nm), the buffer layer 116 may be, for example, adjusted for thickness so that 70% or greater transmittance can be obtained with respect to the peak luminous wavelength.

The exposure apparatus of the first embodiment as illustrated in FIG. 5 is constituted so as to emit light from the driving transistor 130 side of the electroluminescent element 110, and the thus structured electroluminescent element 110 is called a bottom emission type. Since light is emitted from the substrate 100 side in the bottom emission structure, a photo-detecting element 120 is preferably constituted with a material high in transparency, as described previously, for example, with polycrystalline silicon (poly-silicon). The photo-detecting element 120 constituted with polycrystalline silicon is lower in capacity of causing photocurrent than that constituted with non-crystalline silicon (amorphous silicon), which is a problem. However, this problem can be solved, for example, by providing a capacitor (not illustrated) in the vicinity of the electroluminescent element 110 to accumulate an electric charge based on a current output from a photo-detecting element 120 for a predetermined period of time in the capacitor or by providing a processing circuit in which a predetermined electric charge is accumulated and the charge is discharged to effect a voltage conversion thereafter. The bottom emission structure is advantageous in that an electrode (positive electrode) for taking out light can be easily formed by using a transparent material, thereby resulting in a simple manufacture.

As illustrated in FIG. 6, the exposure apparatus of the first embodiment is constituted by arranging a plurality of electroluminescent elements 110 in a horizontal scanning direction (direction at which the elements are arrayed), with one photo-detecting element 120 being arranged so as to correspond to one light emitting region (light outgoing region ALE). This structure makes it possible to independently measure the light emitting quantity of each of the electroluminescent elements 110 by using the photo-detecting element 120. Furthermore, since the photo-detecting element 120 is kept apart from the electroluminescent element 110 by thin films (first insulative film 122, a second insulative film 123 and a protective film 124), there is quite a small leakage of emitted light in a planar direction, thereby, optical cross-talk effects can be made substantially negligible. It is, therefore, possible to measure the light quantity of a plurality of electroluminescent elements 110 at the same time and greatly decrease the measurement time.

FIG. 6 illustrates the interrelation among the photo-detecting element 120, the drain electrode 125D as a photo-detecting element output electrode, the source electrode 125S as a photo-detecting element ground electrode, the light outgoing region A_{LE}, the semiconductor island region A_{R} as an element region of the photo-detecting element 120, ITO (indium tin oxide) which will act as the positive electrode 111 of the luminescent layer 112, a through hole HD and a drain electrode 134D. The photo-detecting element 120 is connected with the drain electrode 125D as a photo-detecting element output electrode and the source electrode 125S as a photo-detecting element ground electrode. The drain electrode 125D as a photo-detecting element output electrode is an electrode for transmitting an electric signal output from the photo-detecting element 120 to an exterior of the photo-detecting element 120. On the basis of the electric signal, a feedback signal generated by a light quantity correcting portion (not illustrated) is determined, and processing necessary for light correction is carried out on the basis of the feedback signal.

In the first embodiment, the light emitting quantity of each of the electroluminescent elements 110 is to be corrected on the basis of the feedback signal, and a driver circuit (not illustrated) is used to control a current value for driving each of the electroluminescent elements 110. As described above, in the first embodiment, the light emitting quantity of the electroluminescent element 110 is controlled on the basis of an output of the photo-detecting element 120. However, such a constitution may also be available that so-called PWM control is gained, that is, the driving time of each of the electroluminescent elements 110 is controlled on the basis of a feedback signal. Where the PWM control is adopted, there is provided an advantage that the control can be gained by a circuit composition in a full digital mode.

The source electrode 125S as a photo-detecting element ground electrode is an electrode for grounding the photo-detecting element 120. ITO (indium tin oxide) which is a positive electrode 111 of the electroluminescent element 110 as a luminescent element is connected to a drain electrode 134D of the driving transistor 130, and the electroluminescent element 110 is controlled by the driving transistor 130 via the drain electrode 134D.

As shown in FIG. 5 and FIG. 6, the exposure apparatus of the first embodiment is constituted in such a way that a photo-detecting element 120 constituted with polycrystalline silicon (poly-silicon) formed in an island shape is arranged in a horizontal scanning direction in a row, and each of the electroluminescent elements 110 is constituted in such a way that the photo-detecting element 120 having a larger semiconductor island region A_{R} than a light outgoing region A_{LE} is arranged at the lower part of the luminescent layer 112 at which the light outgoing region A_{LE} is restricted by a silicon nitride film as a pixel restricting layer 114. The semiconductor island region A_{R} (an island proton of the polycrystalline silicon formed in an island shape) of the photo-detecting element 120 is made larger than the light outgoing region A_{LE}, by which a step-containing structure such as the source electrode 125S or the drain electrode 125D is removed from a site at which the light outgoing region A_{LE} is formed. Therefore, at least, the light outgoing region A_{LE} is to be formed on a flat portion of the photo-detecting element 120. Thereby, even where the luminescent layer 112, in particular, is formed by the above-described wet coating method, it is possible to inhibit a local variation in thickness in the luminescent layer 112 and also inhibit a deviation of the current flowing through the luminescent layer 112. It is, thus, possible to manufacture an exposure apparatus having a uniform distribution of light emission and an improved life.

Furthermore, since the semiconductor island region A_{R} of the photo-detecting element 120 formed in an island shape, which is loaded on the exposure apparatus of the first embodiment, is larger in light emitting region than the light outgoing region A_{LE}, light output from the luminescent layer 120 can be effectively converted to an electric signal used in correcting the light emitting quantity or the light emitting time.

Then, the exposure apparatus described in the first embodiment is constituted with an electrode (positive electrode 111) on the lower side of the electroluminescent element 110, which is a luminescent element, a semiconductor region (semiconductor island region A_{R}) constituting the photo-detecting element 120 and a light outgoing region A_{LE} so as to make the area smaller in the order described above, each of which is preferably formed so as to be made small by 1 μm or more accordingly. In an ordinary semiconductor manufacturing process, when each layer is subjected to film formation and patterning, it is difficult to form a film exactly as instructed in a drawing. Where a large area is subjected to patterning without using a special apparatus, errors are made of 1 μm or less respectively in the positioning accuracy of a photo mask or expansion/contraction of the photo mask on photolithography and in the in-plane distribution of the etching rate on etching. An error of approximately 1 μm will occur in general, with these matters taken into account.

Therefore, a allowance of 1 μm or greater is made, by which a highly reliable exposure apparatus can be provided effectively, even where there are developed an uneven distribution of film thickness, a positional deviation and a size deviation of films resulting from an element manufacturing process. In particular, where a possible longer size of the exposure apparatus is taken into account, there may be developed a greater deviation of films resulting from the element manufacturing process. Therefore, where consideration is given to a manufacturing process of thin film transistors on a glass substrate 100 now commonly available, for example, an allowance of 1 μm or greater is made, by which the exposure apparatus can be formed easily.

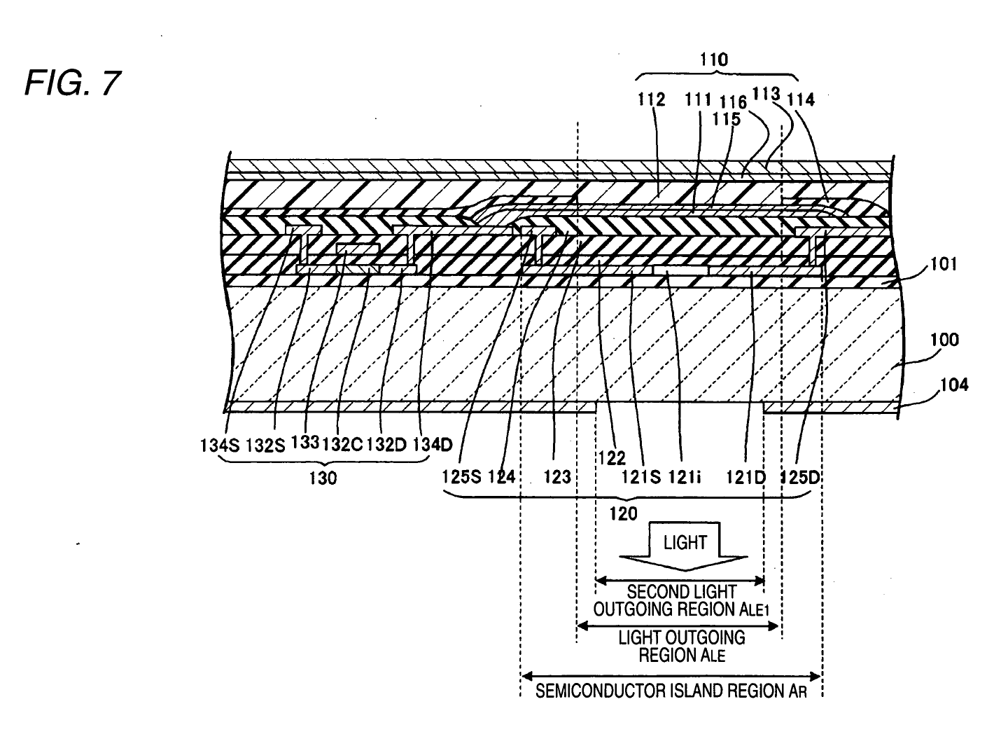

FIG. 7 is a sectional view showing a modification of an exposure apparatus in which the organic electroluminescent element of the first embodiment of the present invention is used.

As illustrated in FIG. 7, a light protection film 104 composed of a chrome thin film is formed on the back face of a substrate 100, and the aperture thereof is used to specify a second light outgoing region A_{LEI}. The second light outgoing region A_{LEI} is formed smaller than the aperture of silicon nitride film as a pixel restricting layer 114 described in the first embodiment, by which a step portion of a luminescent layer 112 resulting from the pixel restricting layer 114 can be removed from the light outgoing region A_{LEI}, by which it is possible to make more uniform the luminescent layer 112 in the light outgoing region A_{LEI}. Other constitutions are similar to those given in the first embodiment.

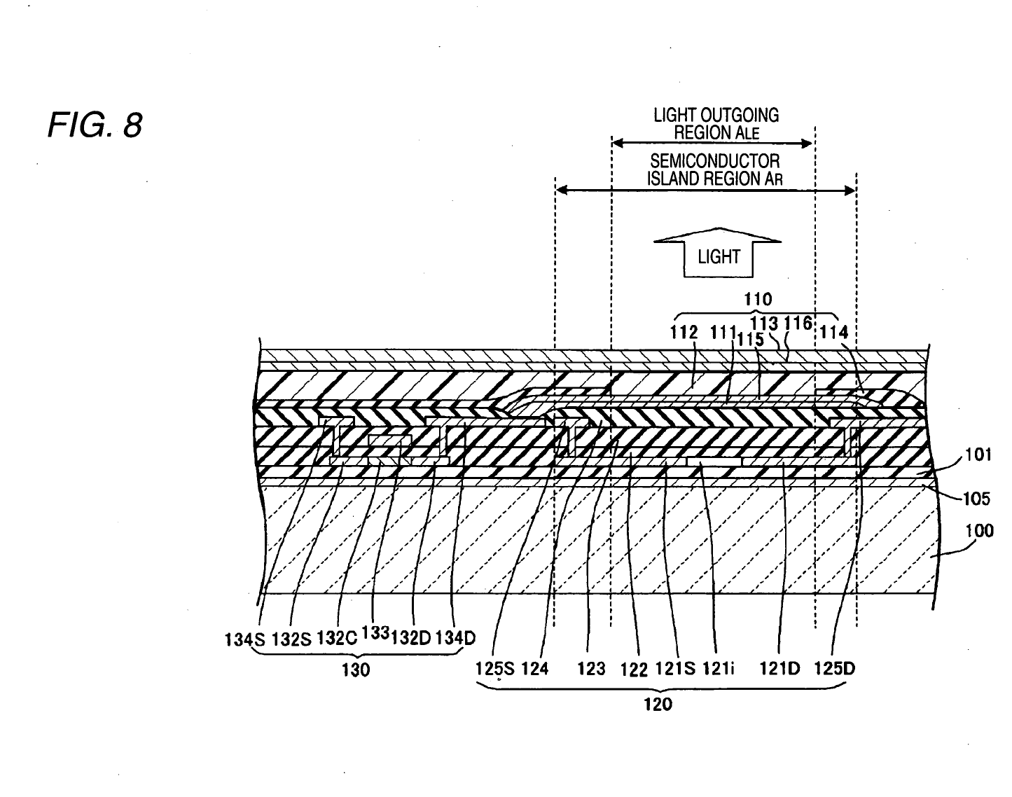

FIG. 8 is a sectional view showing a case where the organic electroluminescent element used in the exposure apparatus of the first embodiment of the present invention is constituted by a top emission structure.

The top emission structure is a structure in which in reverse to a bottom emission structure, light output from a luminescent layer 112 is output to the negative electrode 113 side which is above the luminescent layer 112. According to the structure shown in FIG. 8, a metal reflecting layer 105 is provided on the substrate 100 to output light on the negative electrode 113 side.

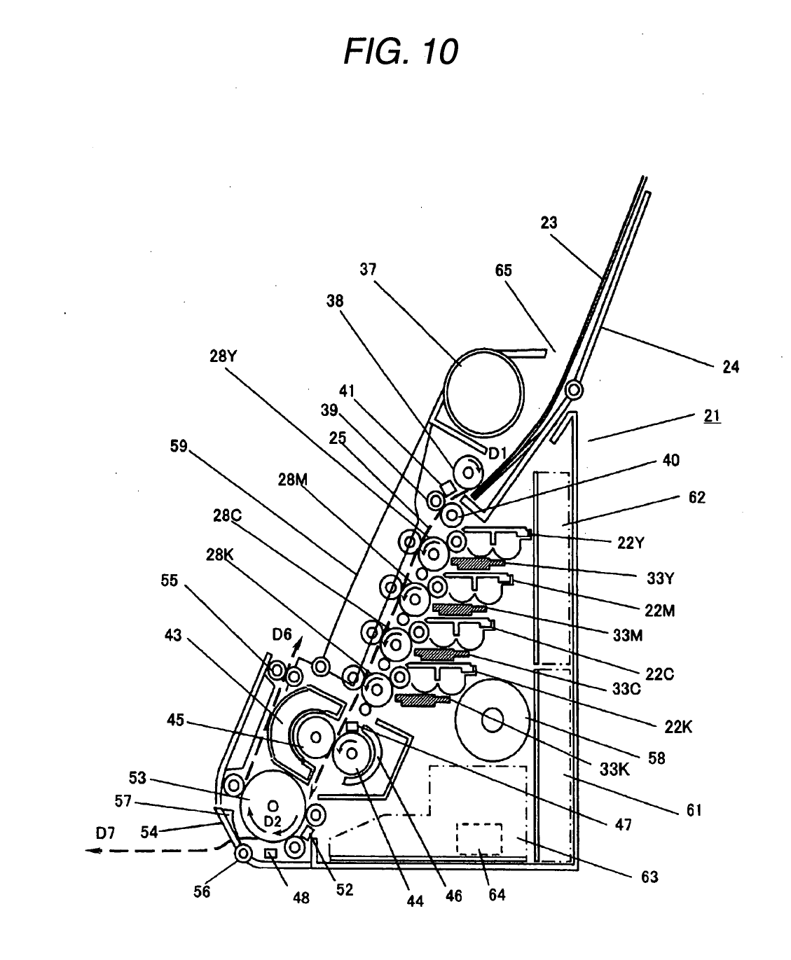

In this instance, since light is structurally taken out on the negative electrode 113 side, the transmittance of a molybdenum oxide layer as a buffer layer 116 interposed between the luminescent layer 112 and the negative electrode 113 is preferably constituted so as to give 70% or more at a luminous wavelength of light at which the organic electroluminescent element 110 radiates.

Where this structure is adopted, as illustrated, of light caused by the luminescent layer 112 of the organic electroluminescent element 110, light radiated in a direction opposite the photo-detecting element 120 is used to expose photosensitive bodies which are not illustrated (refer to 28Y to 28K shown in FIG. 10, which will be described later). On the other hand, the light generated by the luminescent layer 112 is radiated to a direction opposite that for exposure, that is, on the side of photo-detecting element 120 as well, and the light is received by the photo-detecting element 120.

Where a top-emission structure is adopted, the light used for exposure is not required to permeate through the photo-detecting element 120, and polycrystalline silicon high in transparency is not necessarily used in the photo-detecting element 120. Therefore, non-crystalline silicon (amorphous silicon) highly capable of causing photocurrent may be used to constitute the photo-detecting element 120.

Then, in order to put the top-emission structure into operation, the negative electrode 113 must be constituted with a transparent metal material, which is, however, technically difficult. Thereafter, an extremely thin metal layer (thin-film negative electrode) made with A, Ag or the like and a transparent electrode such as that made with ITO (either of them not illustrated) are laminated to give the negative electrode 113 for a subsequent use. Since the metal layer (thin-film negative electrode) is extremely made thin, it is possible to obtain the negative electrode 113 in which translucency is secured. The top emission structure can constitute an exposure apparatus excellent in luminous efficiency, although it needs a larger number of manufacture-related man-hours than the bottom emission structure to result in an increased manufacturing cost.

A detailed description has been so far made for the constitutions and the actions of the electroluminescent element 110 and the photo-detecting element 120 which constitute the exposure apparatus. In the first embodiment, an array of electroluminescent elements used in the exposure apparatus is described as one array. However, these electroluminescent elements may be provided in a plurality of arrays to practically increase the light emitting quantity.

Furthermore, regarding the structure of the electroluminescent element 110 and that of the photo-detecting element 120, they may be arranged two-dimensionally to constitute a display device.

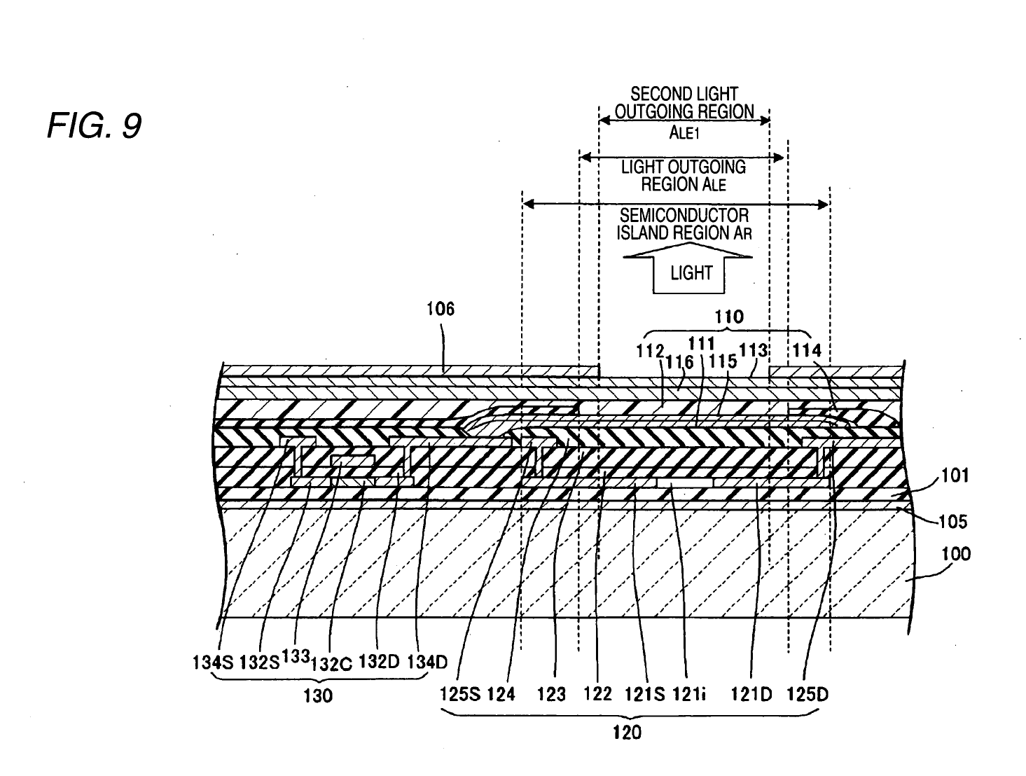

FIG. 9 is a block diagram illustrating a modification of the first embodiment of the present invention.

As illustrated in FIG. 9, a light protection film 106 composed of a chrome thin film is formed on the back face of the substrate, the aperture thereof is used to specify a second light outgoing region A_{LEI}. The second light outgoing region A_{LEI} is formed smaller than the aperture of silicon nitride film as the pixel restricting layer 114 described in the first embodiment, by which a step portion of a luminescent layer 112 resulting from a pixel restricting layer 114 can be removed from the light outgoing region to form the luminescent layer 112 higher in uniformity. Other constitutions are similar to those given in the first embodiment.

FIG. 10 is a block diagram illustrating a constitution of an image forming device 21 equipped with an exposure apparatus in which the organic electroluminescent element of the first embodiment of the present invention is used.

In FIG. 10, the image forming device 21 has therein four-color developing stations, that is, yellow developing station 22Y, magenta developing station 22M, cyan developing station 22C and black developing station 22K arranged vertically in a step-wise manner, wherein a sheet feeding tray 24 for accommodating recording sheet 23 is disposed thereabove, and a recording-sheet conveying path 25 acting as a conveying path of the recording sheet 23 supplied from the sheet feeding tray 24 is arranged at a site corresponding to each of the developing stations 22Y to 22K from above to downward in a vertical direction.

The developing stations 22Y to 22K are to form toner images which are yellow, magenta, cyan and black in the ascending order upstream from the recording-sheet conveying path 25. The yellow developing station 22Y, the magenta developing station 22M, the cyan developing station 22C and the black developing station 22K respectively contain a photoreceptor 28Y, a photoreceptor 28M, a photoreceptor 28C and a photoreceptor 28K. Furthermore, each of these developing stations 22Y to 22K includes a member necessary for providing a series of developing processes based on electro photography such as a development sleeve and a charger (not illustrated).

Furthermore, exposure apparatuses 33Y, 33M, 33C, 33K for exposing the surfaces of the photosensitive bodies 28Y to 28K to form an electrostatic latent image are arranged below the developing stations 22Y to 22K. It is noted that the exposure apparatus shown in the first embodiment is mounted on the exposure apparatuses 33Y, 33M, 33C, 33K.

The developing stations 22Y to 22K are different in color of a developer filled therein but identical in constitution, irrespective of the development color. Therefore, for the sake of a simple explanation in a subsequent process, a description will be made without specifying the color concerned, but simply referring to a developing station 22, a photoreceptor 28 or an exposure apparatus, unless otherwise needed in particular.

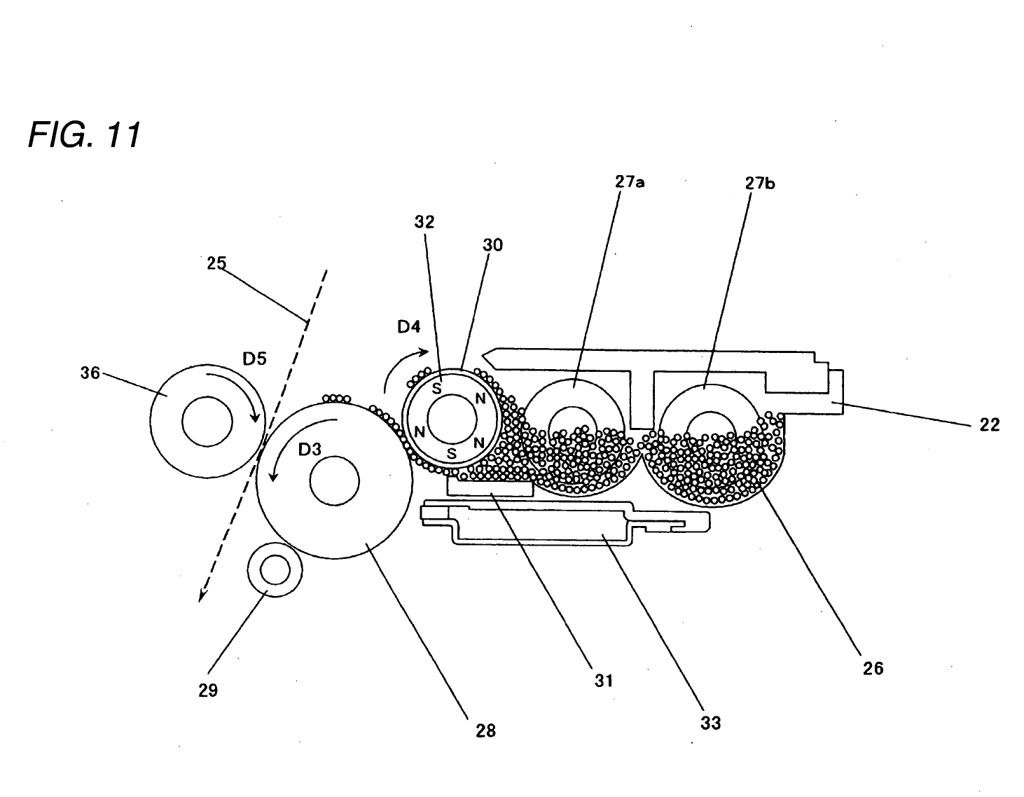

FIG. 11 is a block diagram illustrating the vicinity of a developing station 22 in the image forming device 21 of the first embodiment of the present invention. In FIG. 11, a developer 26, a mixture of carrier and toner, is filled inside the developing station 22. Reference numerals 27a, 27b denote agitation paddles for agitating the developer 26. The toner in the developer 26 is charged to a predetermined potential due to a friction with the carrier and circulated inside the developing station 22 by the rotation of these agitation paddles 27a, 27b, by which the toner and the carrier are sufficiently agitated and mixed. The photoreceptor 28 is rotated to the direction of D3 by a driving source (not illustrated). Reference numeral 29 denotes a charger which charges the surface of the photoreceptor 28 to a predetermined potential. Reference numeral 30 denotes a development sleeve, and reference numeral 31 denotes a thin-layered blade. The development sleeve 30 is provided with a magnet roll 32 in which a plurality of magnetic poles are formed. The developer 26 supplied to the surface of the development sleeve 30 is restricted for the layer thickness by a thin-layered blade 31, and the development sleeve 30 is rotated by a driving source (not illustrated) to the direction D4. This rotation and the magnetic poles inside the magnet roll 32 act to supply the developer 26 to the surface of the development sleeve 30, and an exposure apparatus which will be described later develops an electrostatic latent image formed on the photoreceptor 28, and the developer 26 which is not transferred to the photoreceptor 28 is recovered into the developing station 22.

Reference numeral 33 denotes the exposure apparatus which has been already described. The image forming device 21 in which the exposure apparatus 33 using organic electroluminescent elements of the first embodiment is put into practical use is long in life due to the ability of the exposure apparatus 33 to stably form a latent image for a prolonged period of time. Furthermore, the exposure apparatus 33 of the first embodiment can provide an electrostatic latent image having a desired configuration for a prolonged period of time, whereby a high-quality image can be constantly formed.

Then, the exposure apparatus 33 of the first embodiment has organic electroluminescent elements with a resolution of 600 dpi (dot/inch) arranged in a linear manner, selectively switching the organic electroluminescent elements on or off, depending on image data, with respect to the photoreceptor 28 charged to a predetermined potential by the charger 29, thereby an electrostatic latent image up to A4 size is formed. Of the developer 26 supplied to the surface of the development sleeve 30, only toner will attach to a portion of the electrostatic latent image, thereby the electrostatic latent image is manifested.

A transfer roller 36 is provided at a position opposite a recording-sheet conveying path 25 with respect to the photoreceptor 28, and rotated by a driving source (not illustrated) to the direction of D5. A predetermined transfer bias is applied to the transfer roller 36, by which a toner image formed on the photoreceptor 28 is transferred to recording sheet conveyed through the recording-sheet conveying path 25.

In reverting to FIG. 10, the following description will be made.

As described above, the image forming device 21 of the first embodiment is a tandem-type color image forming device in which a plurality of developing stations 22Y to 22K are arranged vertically in a step-wise manner, and intended to be available in a size similar to that of a color ink-jet printer. The developing stations 22Y to 22K are provided with a plurality of units. In order to miniaturize the image forming device 21, the developing stations 22Y to 22K must be made small and members related to an image-forming process which are arranged around the developing stations 22Y to 22K must also be made small to decrease an arrangement pitch of the developing stations 22Y to 22K as much as possible.

Where consideration is given to an easy operation of the image forming device 21 on a desk by a user in an office or, in particular, the convenience of feeding or discharging the recording sheet 23, it is desirable to make 250 mm or lower the height from the bottom of the image forming device 21 to a sheet feeding port 65. For the purpose of attaining this height, an overall height of the developing stations 22Y to 22K must be kept to approximately 100 mm in a whole constitution of the image forming device 21.

However, for example, an existing LED head has the thickness of approximately 15 mm, which makes it difficult to attain the above purpose, if it is arranged between the developing stations 22Y to 22K. According to the results evaluated by the present inventor and others, where the exposure apparatus 33 is made to be 7 mm or lower in thickness dimension, the exposure apparatuses 33Y to 33K are arranged at a space between the developing stations 22Y to 22K, thereby it becomes possible to keep an overall height of the developing stations to 100 mm or lower.

Reference numeral 37 denotes a toner bottle, at which yellow, magenta, cyan and black toners are accommodated. Toner conveying pipes (not illustrated) are disposed at each of the developing stations 22Y to 22K from the side of the toner bottle 37, thereby toner is supplied to each of the developing stations 22Y to 22K.

Reference numeral 38 is a sheet feeding roller and rotated by controlling an electromagnetic clutch (not illustrated) to the direction of DI, thereby the recording sheet 23 placed into the sheet feeding tray 24 is fed out to the recording-sheet conveying path 25.

A pair of resist roller 39 and pinch roller 40 are provided as nip conveying means on an inlet side at the recording-sheet conveying path 25 positioned between the sheet feeding roller 38 and a transfer position of the upper-most stream yellow developing station 22Y. The pair of resist roller 39 and pinch roller 40 temporarily halt the recording sheet 23 conveyed from the sheet feeding roller 38, and convey it toward the yellow developing station 22Y at a predetermined timing. This temporary halt restricts the leading end of the recording sheet 23 parallel with the axial direction of the pair of resist roller 39 and pinch roller 40, thereby bias feeding of the recording sheet 23 is prevented.

Reference numeral 41 denotes a recording-sheet passage detecting sensor. The recording sheet passage detecting sensor 41 is constituted with reflective-type sensors (photo reflectors), and detects the leading end and the trailing end of the recording sheet 23 by referring to whether reflected light is found.

Then, when the resist roller 39 is started for rotation (an electromagnetic clutch (not illustrated) is used to control a transmitted driving force to switch the rotation on or off), the recording sheet 23 is conveyed along the recording-sheet conveying path 25 toward the yellow developing station 22Y. On the basis of a timing of starting the rotation of the resist roller 39, an electrostatic latent image is independently controlled for the writing timing by exposure apparatuses 33Y to 33K arranged in the vicinity of each of the developing stations 22Y to 22K.

A fuser 43 is provided as nip conveying means on the outlet at the recording-sheet conveying path 25 positioned further downstream from the black developing station 22K which is at the last end. The fuser 43 is constituted with a heating roller 44 and a pressure roller 45. The heating roller 44 is a multi-layered roller constituted with a heating belt, a rubber roller and a core material (any of them not illustrated) in the order from the surface. Of these constituents, the heating belt is a three-layered belt and constituted with a releasing layer, a silicon rubber layer and a substrate layer (any of them not illustrated) in the order from the surface. The releasing layer is composed of fluorine resin having the thickness from 20 to 30 micrometers, and gives a mold releasing property to the heating roller 44. The silicon rubber layer is constituted with approximately 170-micrometer-thick silicon rubber, and gives an appropriate elasticity to the pressure roller 45. The substrate layer is constituted with a magnetic material which is an alloy of iron, nickel, chrome or the like.

Reference numeral 26 denotes a back face core in which an exciting coil is included. An exciting coil which bundles a predetermined number of copper wires (not illustrated), with the surface thereof being insulated, is formed inside the back face core 46 so as to be extended toward an axial direction at which the heating roller 44 is rotated and also turned around toward the circumference of the heating roller 44 at both ends of the heating roller 44. When an alternating current of approximately 30 kHz is applied to the exciting coil from an exciting circuit (not illustrated) which is a semi-vibration type inverter, flux is generated on a magnetic path constituted with the back face core 46 and a substrate layer of the heating roller 44. The flux produces an eddy current on the substrate layer of the heating belt of the heating roller 44, thereby the substrate layer generates heat. The heat generated on the substrate layer is transmitted via the silicon rubber layer to the releasing layer, thereby the surface of the heating roller 44 generates heat.

Reference numeral 47 denotes a temperature sensor for detecting the temperature of the heating roller 44. The temperature sensor 47 is a ceramic semiconductor made by sintering mainly metal oxides at a high temperature and able to measure temperatures of an object which is in contact by utilizing a change in load resistance depending on temperatures. The output of the temperature sensor 47 is input into a controlling device (not illustrated). The controlling device controls electricity which is output to an exciting coil inside the back face core 46 on the basis of the output of the temperature sensor 47 in such a way that a temperature on the surface of the heating roller 44 is set to be approximately 170° C.

When recording sheet 23 on which a toner image is formed is supplied to a nip portion formed by the thus temperature controlled heating roller 44 and the pressure roller 45, the toner on the recording sheet 23 is subjected to heating and pressure by the heating roller 44 and the pressure roller 45, by which the toner image is fixed on the recording sheet 23.

Reference numeral 48 denotes a recording sheet trailing end detecting sensor, and the recording sheet trailing end detecting sensor monitors how the recording sheet 23 is discharged. Reference numeral 52 denotes a toner image detecting sensor. The toner image detecting sensor 52 is a reflective sensor unit in which used are electroluminescent elements as a plurality of luminescent elements different in emission spectrum (all visible light) and a single light receiving element (photo-detecting element). This sensor is to detect image concentrations by utilizing a fact that the background foundation of the recording sheet 23 and an image forming part are different in absorption spectrum, depending on an image color. Furthermore, the toner image detecting sensor 52 can detect not only the image concentration but also an image forming position. Therefore, in the image forming device 21 of the first embodiment, two units of the toner image detecting sensor 52 are provided in a width direction of the image forming device 21 to control an image forming timing based on a position of detecting an image position deviation detecting pattern formed on the recording sheet 23.

Reference numeral 53 denotes a recording-sheet conveying drum. The recording-sheet conveying drum 53 is a metal roller, the surface of which is coated with rubber having a thickness of approximately 200 micrometers, and recording sheet 23 after being fixed is conveyed along the recording-sheet conveying drum 53 toward the direction of D2. In this instance, the recording sheet 23 is cooled by the recording-sheet conveying drum 53 and conveyed after being bent to a direction opposite an image forming face. Thereby, it becomes possible to greatly reduce a curl which occurs when a highly-concentrated image is formed all over the recording sheet. Thereafter, the recording sheet 23 is conveyed to the direction of D6 by a kick-out roller 55 and discharged to a sheet discharging tray 59.

Reference numeral 54 denotes a face-down sheet discharging portion. The face-down sheet discharging portion 54 is constituted so as to rotationally move at the center of a supporting member 56. When the face-down sheet discharging portion 54 is kept open, the recording sheet 23 is discharged to the direction of D7. The face-down sheet discharging portion 54 is provided with ribs 57 along the conveyance path on the back thereof so as to guide the conveyance of the recording sheet 23, together with the recording sheet conveying drum 53, when it is closed.

Reference numeral 58 denotes a driving source, and a stepping mode is used as the driving source in the first embodiment. The driving source 58 is to drive a sheet feeding roller 38, a resist roller 39, a pinch roller 40, photosensitive bodies (28Y-28K), vicinity of each of the developing stations 22Y to 22K including transfer rollers (36Y to 36K), a fuser 43, a recording-sheet conveying drum 53, and a kick-out roller 55.

Reference numeral 61 denotes a controller, and the controller receives image data from a computer or the like via an external network, thereby printable image data are developed and generated.

Reference numeral 62 denotes an engine control portion. The engine control portion 62 controls the hardware and mechanism of the image forming device 21, thereby a color image is formed on recording sheet 23 based on image data transmitted from the controller 61 and also in general the image forming device 21 is controlled.

Reference numeral 63 denotes a power supply portion. The power supply portion 63 supplies electricity to the exposure apparatuses 33Y to 33K, the driving source 58, the controller 61, and the engine control portion 62 at a predetermined voltage, and also supplies electricity to the heating roller 44 of the fuser 43. Furthermore, so-called high-voltage power supply systems such as those dealing with charge on the surface of the photoreceptor 28, development bias applied to the development sleeve (refer to reference numeral 30 in FIG. 11) and transfer bias applied to the transfer roller 36 are also included in the power supply portion.

Furthermore, a power-supply monitoring portion 64 is also included in the power supply portion 63 and designed to monitor at least the power supply voltage supplied to the engine control portion 62. The monitor signal thereof is detected at the engine control portion 62, that is, a decrease in power supply voltage is detected, which occurs when a power supply switch is turned off or power supply is interrupted.

A description has been made so far for a case where the present invention is applied to a color image forming device. The present invention is also applicable to a single-color image forming device in which, for example, black is used. Furthermore, where the present invention is applied to a color image forming device, developed colors are not limited to four colors, that is, yellow, magenta, cyan and black.

Since the image forming device 21 of the first embodiment is equipped with exposure apparatuses 33Y to 33K uniform in distribution of light emission and great in resistance, it can provide an image high in quality and excellent in resistance.

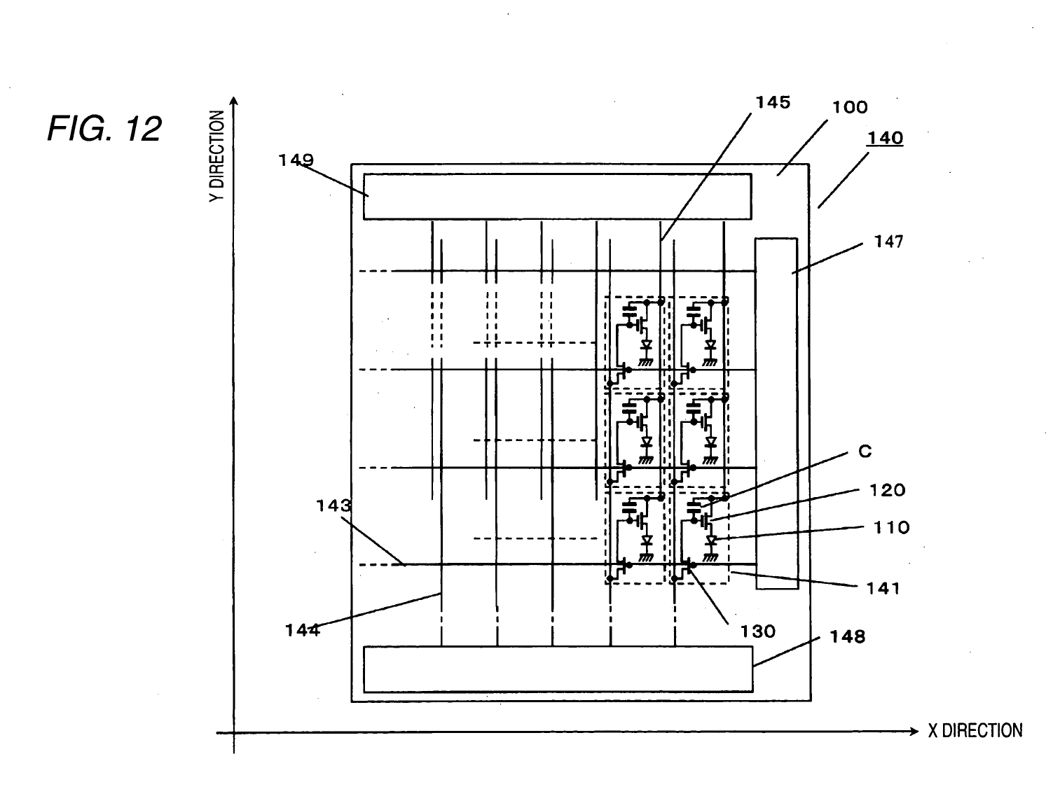

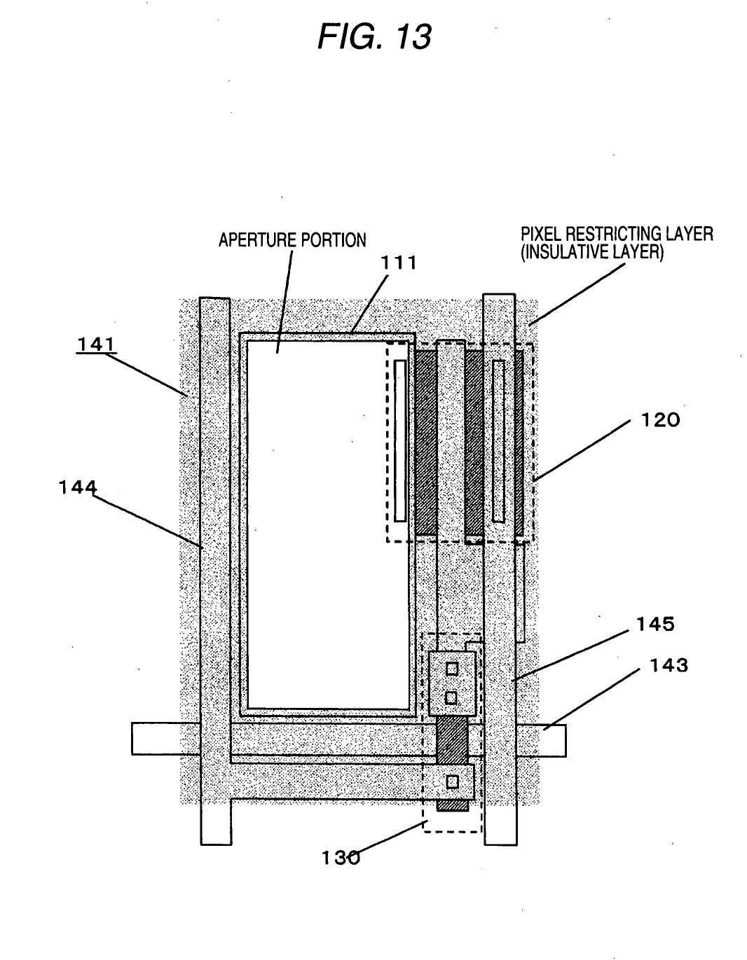

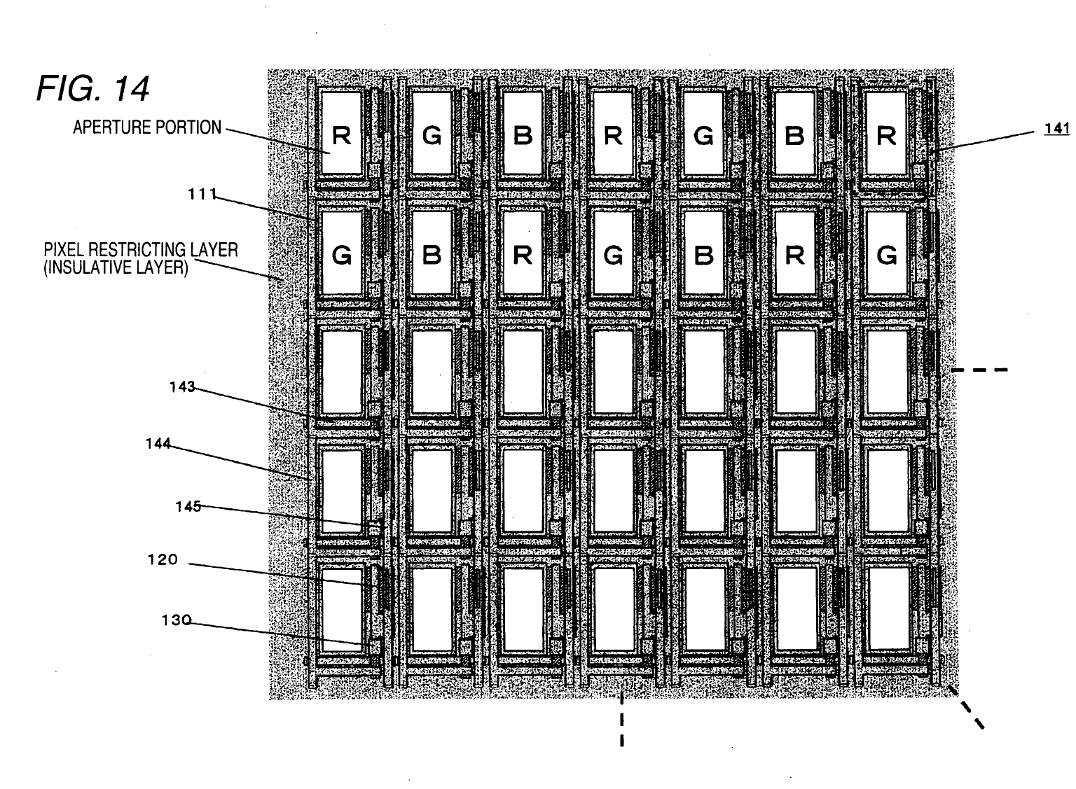

FIG. 12 is a circuit diagram of a display device 140 of the first embodiment of the present invention. FIG. 13 is a drawing for explaining a pixel of the display device 140 of the first embodiment of the present invention. FIG. 14 is a drawing for explaining the upper face of the display device 140 of the first embodiment of the present invention.

Hereinafter, a description will be given of the display device of the first embodiment also with reference to FIG. 1.

Electroluminescent elements 110 which constitute the display device of the first embodiment are fundamentally provided with the structure described in detail in the first embodiment, in which a transition metal oxide layer is formed as the charge-injection layer 115 having an ionization potential of approximately 5.6 eV on the positive electrode 111, and the luminescent layer 112 is formed additionally thereon via TFB as a buffer layer (not illustrated) by an ink jet method.

Furthermore, the display device of the first embodiment is an active matrix-type display device and provided at each pixel with a driving circuit constituted with TFT, for example, as shown in FIG. 12.

The display device 140 is constituted in such a way that organic electroluminescent elements 110 constituting pixels and a plurality of driving circuits composed of a driving transistor 130, a capacitor C and others are arranged vertically and laterally, a first TFT gate electrode of each of the driving circuits arranged in a lateral direction is connected to a scanning line 143 to give a scanning signal, and a first TFT drain electrode of each of the driving circuits arranged in a vertical direction is connected to a signal line 144 to supply a light emitting signal. A driving power supply (not illustrated) is connected to one end of the electroluminescent element. Reference numeral 143 denotes a scanning line; 144, a signal line; 145, a common power supply cable; 147, a scanning line driver; 148, a signal line driver; 149, a common power supply cable driver.

As illustrated in FIG. 12, in the display device of the first embodiment, the positive electrode 111 described in detail with reference to FIG. 1 and others, a transition metal oxide layer as the charge-injection layer 115 having an ionization potential of 5.6 eV, the luminescent layer 112, a transition metal oxide layer as the buffer layer 116 and the negative electrode 113 are formed on a substrate 100 where a driving thin film transistor (not illustrated) is formed, thereby the organic electroluminescent element 110 is constituted.

In terms of the structure, the positive electrode 111 and the charge-injection layer 115 are individually formed, and the luminescent layer 112, the buffer layer 116 and the negative electrode 113 are actually restricted for patterning by the pixel restricting layer 114, and they are formed in a stripe manner.

The driving thin film transistor is, for example, that in which an organic semiconductor layer (polymer layer) is formed on a substrate 100, the resultant is covered with a gate insulative film, a gate electrode is formed thereon, and source/drain electrodes are formed via a through hole formed on the gate insulative film. Furthermore, it is structured in such a way that a polyimide film and others are coated thereon to form an insulative layer (flat layer), on top of which organic semiconductor layers such as the positive electrode (ITO) 111, the charge-injection layer 115 (molybdenum oxide layer), the electron blocking layer, luminescent layer 112, as well as the buffer layer 116 (molybdenum oxide layer) and the negative electrode 113 are formed, thereby the organic electroluminescent element 110 is given. The manufacturing process has been already described in detail with reference to FIG. 1 and others, the description of which will be omitted here.

Although omitted in FIG. 14, the capacitor and the wiring are formed on the same substrate 100. As illustrated in FIG. 12, a plurality of display pixels 141 composed of the above-described TFT and organic electroluminescent elements 110 are formed on the same substrate 100 in a matrix shape to constitute an active matrix-type display device 140.

In terms of the manufacture, as illustrated in FIG. 13, an ink jet method is used to form a luminescent layer at an aperture portion provided by the pixel restricting layer 114.

More specifically, in the manufacture, the aperture portion is provided, after the pixel restricting layer 114 is formed on the driving transistor 130 constituted with the scanning line 143, the signal line 144 and the switching TFT formed on the substrate 100, the positive electrode 111 and others.

Then, a transition metal oxide layer as the charge-injection layer 115 is formed by vacuum deposition all over the upper layer.

Thereafter, TFB (electron blocking layer) is coated by an ink jet method, depending on the necessity. The TFB layer may be coated all over as with the charge-injection layer 115 or may be coated only at a portion corresponding to an aperture portion.

Then, after a drying process, a polymer organic electroluminescent material corresponding to a desired color (any one of R, G, or B colors) is coated on a position corresponding to the aperture portion by an ink jet method.

Finally, a transition metal oxide layer as the buffer layer 116 is formed at a region at which the display pixel 141 is arranged, and the negative electrode 113 is then formed.

This constitution can provide a display device which is high in reliability and can be driven at a high speed.

Next, a description will be made with reference to FIG. 14, for an example, of the lighting device in which a plurality of electroluminescent elements 1 are arranged two dimensionally. Regarding the electroluminescent elements 110 arranged two dimensionally, for example, such a constitution can be quite easily realized that all the electroluminescent elements 1 are at the same time lit on or off. It is, however, preferable that even in a structure to light the electroluminescent elements on or off at the same time, at least either of the electrodes (for example, a pixel electrode constituted with ITO (refer to the positive electrode 111 in FIG. 1)) is constituted so as to be separated to one unit composed of individual electroluminescent elements. This is because where a defect is found in a display pixel 141 due to some causes, the defect can be contained only in the display pixel 141 concerned, by which lighting devices can be manufactured at a higher yield as a whole. A lighting device having the above-described constitution is applicable to lighting appliances in general, for example. In this instance, since the lighting device can be constituted to be extremely thin, the light device can be installed easily not only to where it is hung from the ceiling but also where it is installed on a wall.

Furthermore, the electroluminescent elements 1 arranged two dimensionally are able to supply any given data to easily control the light emitting pattern, and the electroluminescent elements 110 of the present invention are also constituted so as to provide the light emitting region thereof in a size formed by an angle of approximately 40 μm, for example. Thereby, such an application can be found that data are supplied to the lighting device which is used as a panel-type display device as well. As a matter of course, in this instance, although the display pixel 141 must be painted in a different color, that is, red, green or blue, depending on the position concerned, a variety of colors can be used quite easily by an ink jet method.

Conventionally, where a lighting device is compared with a display device, the lighting device is higher in light emission brightness. However, since the electroluminescent element 110 of the present invention is extremely high in light emission brightness, it is usable as a lighting device and a display device as well. In this instance, a mechanism for adjusting the light emission brightness is needed due to a difference in function (that is, use mode) between the lighting device and the display device. This mechanism can be provided, for example, by controlling a driving current, depending on the use mode concerned, and adjusting the light emission brightness of each of the electroluminescent elements 110. More specifically, where it is used as a lighting device, all the electroluminescent elements 110 may be driven by a greater current, and where it is used as a display device, each of the electroluminescent elements 110 may be driven by a small current and also at a current value controlled according to the gradation (that is, depending on image data). In this application, the power supply of the electroluminescent element used as a lighting device and that of the electroluminescent element used as a display device may be provided from a single source. However, where a driving current is controlled, for example, a digital-to-analog converter is great in dynamic range to result in shortage of the number of gradations when it is used as a display device, it is preferable to provide a constitution in which a power supply (not illustrated) connected to a common power supply cable 145 shown in FIG. 12 and FIG. 13 is switched over, according to the use mode concerned. As a matter of course, where the electroluminescent element needs to be controlled for brightness even in the use mode as a lighting device (that is, a lighting-control function-equipped lighting device), the brightness can be easily controlled, for example, by controlling a current value. Furthermore, the electroluminescent element 110 of the present invention may be formed not only on a glass-made substrate 100 but also on a substrate made of a resin such as PET, thereby making it possible to find applications as lighting devices for various illuminations.

It is noted that a thin film transistor may be constituted with an organic transistor. Such a structure that an organic electroluminescent element is laminated on a thin film transistor or a thin film transistor is laminated on an organic electroluminescent element is also effective.

In addition, in order to obtain a high-image quality electroluminescent display device, an electroluminescent substrate on which organic electroluminescent elements are formed is pasted together with a TFT substrate on which TFT, a capacitor and a wiring are formed so that an electrode of the electroluminescent substrate is connected to an electrode of the TFT substrate by using a connection bank.

In the above description, the organic electroluminescent element is driven by a direct current but may also be driven by an alternating voltage, an alternating current or a pulse wave.

The first embodiment includes the following inventions.

The organic electroluminescent element of the first embodiment is an organic electroluminescent element provided with a luminescent layer between a positive electrode and a negative electrode, in which a transition metal oxide layer is formed between the negative electrode and the luminescent layer.

Furthermore, the organic electroluminescent element of the first embodiment is an organic electroluminescent element provided with a positive electrode, a negative electrode and a plurality of functional layers between the positive electrode and the negative electrode, in which the functional layer is provided with a luminescent layer containing at least one type of organic semiconductors, and a transition metal oxide layer is additionally provided between the negative electrode and the luminescent layer. According to this constitution, a negative electrode material, which is highly reactive, can act as a barrier layer, thereby causing no deterioration of the luminescent layer even when a reactive substance is flown from the negative electrode. Furthermore, a transition metal oxide such as molybdenum oxide is effective in injecting electric charge, when used as an organic electroluminescent element. Where the transition metal oxide layer is formed, for example, in a thickness of 30 nm or more, it will not cause an abrupt voltage drop but can obtain high luminance properties because an electric field applied between both the electrodes is applied to the luminescent layer substantially as it is. The transition metal oxide is also provided with various properties such as electron injection capacity, electron transport property and hole blocking property, thereby making it possible to exhibit a high functionality in a single-layer structure and also provide a thinly filmed element. It is, therefore, possible to inject electrons favorably and control a light emitting region. Thus, for example, the light emitting region can be controlled so as to be located at the center of the luminescent layer, which would be otherwise difficult, thereby the element is further improved in efficiency to result in a prolonged life.

Furthermore, in the first embodiment, an organic electroluminescent element is constituted so that a transition metal oxide layer is preferably from Inm to 1 μm in thickness. The thickness exceeding 1 μm will result in a decreased light transmittance, posing difficulty in securing the transmittance of 70%, which is a target level for practical use. The thickness is more preferably set to be 500 nm or lower, with the film-forming time also taken into account. Where the transition metal oxide layer is extremely thin, a sponge-form layer having a mean thickness of approximately 1 nm may provide a similar effect as that described above, even if actually not in a film form. The layer, the thickness of which is less than 1 nm, is unable to provide a sufficient effect as a metal oxide.

Furthermore, in the first embodiment, an organic electroluminescent element is constituted so that the transition metal oxide layer is preferably 70% or higher in light transmittance. This constitution can retain a sufficient light emitting quantity. Where the transmittance fails to reach 70%, a problem occurs that the light emitting quantity is decreased.

Furthermore, in the first embodiment, an organic electroluminescent element is constituted so that a luminescent layer may include a polymer compound.

Furthermore, in the first embodiment, an organic electroluminescent element is constituted so that a luminescent layer may include a polymer compound having a fluorene ring. In this instance, the polymer compound having a fluorene ring is such which constitutes a polymer in which a desired group is bound with the fluorene ring. Polymer compounds in which various groups are bound are commercially available.

Furthermore, in the first embodiment, an organic electroluminescent element is constituted so that a transition metal oxide layer is preferably from 4 to 6 eV in work function. According to this constitution, a favorable ohmic contact can be formed. The work function of less than 4 eV will tend to result in a higher reactivity, thus making it difficult to decrease the influence of a reactive substance, which is a feature of the first embodiment, resulting in a failure of obtaining a favorable light emission. Although a detailed mechanism still remains unknown, no favorable light emission can be obtained due to a great difference in work function with the negative electrode.

Furthermore, in the first embodiment, an organic electroluminescent element is constituted so that a transition metal oxide layer is preferably from 1 MΩcm to IGΩcm in specific resistance. This constitution can decrease a voltage drop resulting from the transition metal oxide layer in itself, thereby providing light emission with high brightness.

Furthermore, in the first embodiment, an organic electroluminescent element is constituted so that a transition metal oxide layer may be constituted with molybdenum oxide. Since the molybdenum oxide layer is small in specific resistance even though it is a metal oxide, a highly reliable light emission can be provided, with no voltage drop. Still furthermore, since a favorable contact property can be obtained without the use of a reactive substance in a negative electrode, the negative electrode may be structured in a single layer, by which the transition metal oxide layer is available in a thinner film. The thus prepared transition metal oxide layer is high in barrier property and also made smooth on the surface, thereby a luminescent layer can be made uniform. In this instance, molybdenum oxide (MoOₓ) is not restricted to MoO₃ but that different in valence may also be used effectively.

As described above, the first embodiment is provided with a buffer layer in which a transition metal oxide having a plurality of valences is contained between the negative electrode and the luminescent layer of the organic electroluminescent element, and the buffer layer is further constituted so as to be in contact with an intermediate layer containing oxides of earth metals such as Ba and Ca (earth metals constituting the intermediate layer 113a are oxidized to some extent during the manufacturing process).

Furthermore, in the first embodiment, an organic electroluminescent element is constituted so that a transition metal oxide layer may be constituted with vanadium oxide. In this instance, the vanadium oxide (VxOy) is not restricted to V₂O₅ but that different in valence may also be used effectively.

Furthermore, in the first embodiment, an organic electroluminescent element is constituted so that a transition metal oxide layer may be constituted with tungsten oxide. In this instance, the tungsten oxide (WOx) is not restricted to WO₃ but that different in valence may also be used effectively.

Furthermore, in the first embodiment, an organic electroluminescent element is constituted so that an intermediate layer is preferably formed between the transition metal oxide layer and the negative electrode.

Furthermore, in the first embodiment, an organic electroluminescent element is constituted so that an intermediate layer may be constituted with a polymer layer.

Furthermore, the organic electroluminescent element of the first embodiment includes a constitution in which a positive electrode is formed on a translucent substrate, a functional layer, which contains a hole injection layer and a luminescent layer, is formed on the positive electrode, and a transition metal oxide layer and a negative electrode are formed so as to oppose the hole injection layer via the luminescent layer.

Furthermore, the organic electroluminescent element of the first embodiment includes a constitution in which a positive electrode is formed on a substrate, a functional layer, which contains a hole injection layer and a luminescent layer, is formed on the positive electrode, a transition metal oxide layer and a negative electrode are formed so as to oppose the hole injection layer via the luminescent layer, and the negative electrode is constituted with a transparent material.

Furthermore, the first embodiment may also be provided with a transition metal oxide layer functioning as a charge-injection layer (hole injection layer) between the positive electrode and the luminescent layer. Then, the transition metal oxide layer is considered to contain a transition metal oxide different in valence as with the above-described buffer layer.

Furthermore, a method for manufacturing an organic electroluminescent element of the first embodiment includes a process in which a positive electrode is formed on a substrate, at least a luminescent layer is formed as the upper layer of the positive electrode, a transition metal oxide layer is formed as the upper layer of the luminescent layer, and a negative electrode is formed as the upper layer of the transition metal oxide layer.

Furthermore, a method for manufacturing an organic electroluminescent element of the first embodiment includes a process in which a negative electrode is formed as a film on a transition metal oxide layer by a sputtering method. The sputtering method can provide an elaborately formed film in a simple manner but may damage an underlying substrate to a greater extent. However, the use of a transition metal oxide can reduce the damage resulting from sputtering.

Furthermore, a method for manufacturing an organic electroluminescent element of the first embodiment includes a process in which a negative electrode is formed as a film on a transition metal oxide layer by a CVD method.

Since the CVD method can provide a film excellent in step coverage, it is possible to form a reliable organic electroluminescent element.

Still furthermore, the first embodiment includes a constitution in which the above-described organic electroluminescent elements are arranged two dimensionally to provide a display device.

In addition, the first embodiment includes a constitution in which the above-described organic electroluminescent elements are arranged in a row to provide an exposure apparatus.

### Second Embodiment

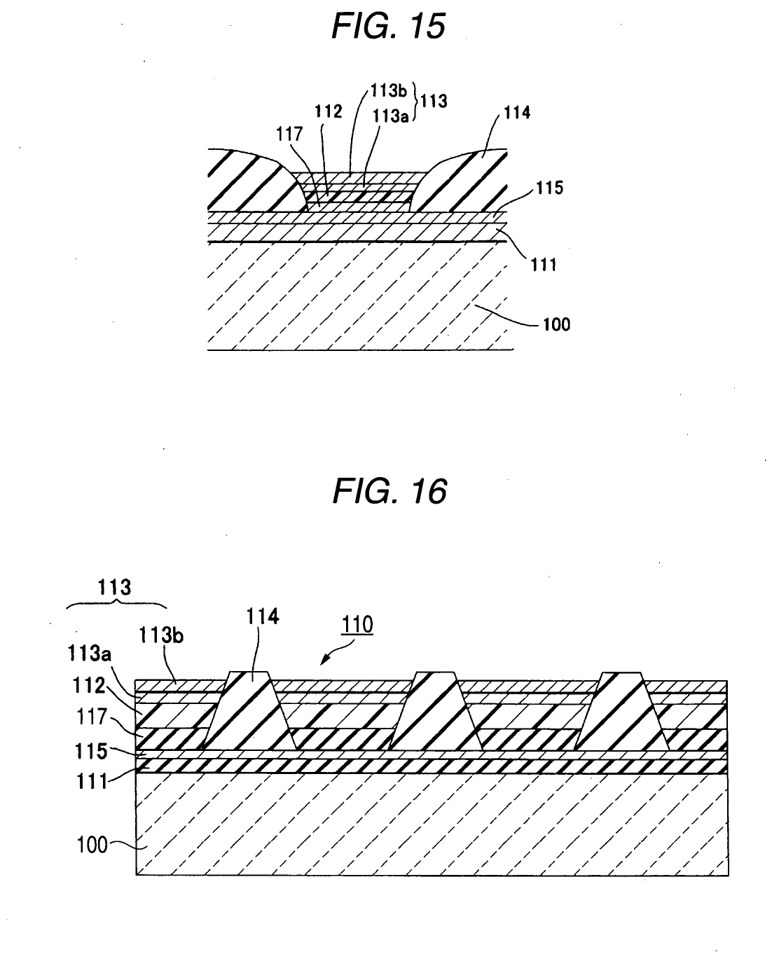

FIG. 15 is a sectional view showing a constitution of an organic electroluminescent element used in an exposure apparatus of an image forming device of a second embodiment of the present invention.

In the second embodiment, a detailed description will be made for the thickness of a transition metal oxide as the charge-injection layer 115 described in the first embodiment and a specific resistance value.

An electroluminescent element of the second embodiment is provided with a positive electrode 111 composed of ITO, a negative electrode 113 constituted, for example, with a metal and a functional layer formed between these electrodes on a translucent substrate 100. These functional layers are provided with a luminescent layer 112, that is, a luminescence function at least composed of an organic semiconductor polymer layer.

It is also provided with a transition metal oxide layer (specifically, 40 nm-thick molybdenum oxide layer) as the charge-injection layer 115 between the positive electrode 111 and the luminescent layer 112, and a pixel restricting layer 114 composed of a 50 nm-thick silicon nitride film on the upper layer, wherein the transition metal oxide layer as the charge-injection layer 115 is made to be 40 nm in thickness, which is not attainable conventionally, thereby a thick molybdenum oxide layer is used to planarize and smooth the surface, thus restricting an area of the light emitting region.

Furthermore, in forming as a film a transition metal oxide such as molybdenum oxide, the transition metal oxide layer thereof is formed as a film by a vacuum deposition method. On film formation, the composition ratio of a deposition source, the pressure and the temperature inside a chamber are controlled so as to give the specific resistance of 10 MΩcm or more. Under the presently available film-forming conditions, where molybdenum oxide (MoO₃) having a purity of 99.999% is used as a deposition source, the specific resistance is provided in 10 MΩcm or more.

This may be due to a fact that on film formation, the crystalline structure undergoes a change depending on film-forming conditions, thus resulting in a specific resistance of 10 MΩcm or more.

Furthermore, the specific resistance in a laminated direction can be made to be approximately one third of that in a planar direction by adjusting the film-forming conditions. This is considered due to a fact that on film formation, the crystal anisotropic structure occurs to result in a difference between the specific resistance in a laminated direction and the specific resistance in a planar direction. Although the mechanism still remains unknown, as described above, it is possible to obtain a transition metal oxide thin film in which the specific resistance in a laminated direction is approximately one third of that in a planar direction by selecting the conditions such as the purity of a deposition source.

The specific resistance should be made to be 1 GΩcm or lower, otherwise, there would be found an abrupt voltage drop in a charge-injection layer 115 to result in an excessive load to a driving circuit.

In the second embodiment, there is formed an electron blocking layer 117 composed of TFB between a thick molybdenum oxide layer as the charge-injection layer 115 (transition metal oxide layer) and a positive electrode 111. Furthermore, a negative electrode 113 is constituted with an intermediate layer 113a composed of barium having a film thickness of approximately 3 nm and an electrode layer 113b formed on the upper layer thereof and composed of aluminum having a film thickness of 150 nm.

According to this structure, the underlying layer of a pixel restricting layer 114 can be smoothened, and if the pixel restricting layer 114 is made thin by the thickness so smoothened, an insulation property can be retained sufficiently to decrease a step resulting from the pixel restricting layer 114, whereby a luminescent layer 112 can be made more uniform in thickness distribution. Furthermore, no short circuiting of pixels occurs. In this instance, the pixel restricting layer 114 may be formed by a light blocking material instead of an insulating material. A material provided with both light-blocking effect and the insulation property can also restrict a light outgoing region favorably, thus making it possible to specify a pixel.

Incidentally, the specific resistance can be changed by controlling impurities and oxygen vacancies contained in a transition metal oxide. For example, where MoO₃ is formed as a film by vacuum deposition, the specific resistance can be changed by adjusting the purity of MoO₃ powder used as a deposition source. For example, when MoO₃ having the purity of 99.999% is used as a deposition source, the specific resistance is made to be 10 MΩcm or more. However, when MoO₃ having the purity of 99.9% is used, the specific resistance is made to be 1 MΩcm.

Where a sputtering method is used to form a film, an MoO₃ target material is similarly influenced by the purity, or a higher purity will result in a greater resistance value. Furthermore, where a sputtering method is used, a metal molybdenum is used as a target agent, and the result will be greatly different depending on whether oxygen or nitrogen is used as a coexistence gas. Change in partial pressure of the respective gases will result in change in oxygen vacancy of film or ionization potential, thus making it possible to control the specific resistance as well. The above method is not restricted to MoO₃ but may be applicable to other elements such as tungsten and vanadium.

The specific resistance is preferably from IMΩcm to IGΩcm. Where the specific resistance is below 1 MΩcm, it is difficult to prevent an electrical cross-talk with an adjacent organic electroluminescent element (for example, refer to FIG. 6 as described in the first embodiment). In contrast, where it exceeds 1 GΩcm, there occurs a great voltage drop in a charge-injection layer 115, resulting in an increase in driving voltage.

### (Experiment by Spin Coating Method)

Then, in order to observe a change in characteristics due to the film thickness of a molybdenum oxide layer in the organic electroluminescent element, the film thickness is changed to prepare samples. It is noted that in this instance, the luminescent layer 112 is formed by a spin coating method.

These samples are prepared according to procedures in which an ITO film is formed on the surface of a translucent substrate 100 by a sputtering method, after a positive electrode 111 is formed, a molybdenum oxide layer as a charge-injection layer 115 is formed by a vacuum deposition method so as to provide a desired film thickness, a silicon nitride film is formed by a high-density plasma CVD method, and an aperture is provided by photolithography to form a pixel restricting layer 114. Then, an electron blocking layer 117 is formed, and a luminescent layer 112 is formed after patterning. As the luminescent layer 112, a polymer layer is formed by a spin coating method. Since a detailed process on film formation has been described in the first embodiment, the description of which will be omitted here.

As described above, the molybdenum oxide layer is changed in film thickness to prepare elements (pixels) by every 100, and the 100 elements are measured for the life under the condition that the brightness is kept constant at 10000 cd/m², thereby evaluating a variance of the life.

In this instance, the life is defined as time elapsed until a current value introduced into an element is made equal to 4 times an initial current value.

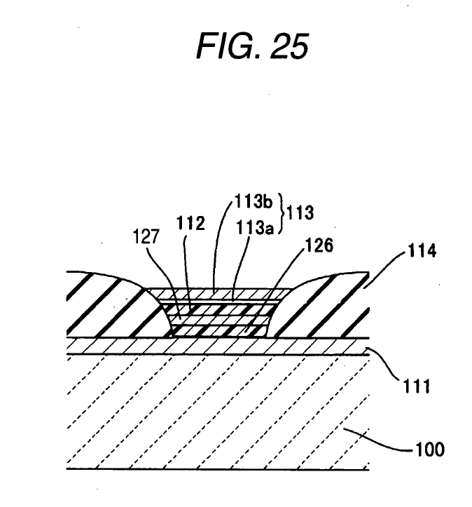

As a result, the sample RIOI in which PEDT is used as a charge-injection layer 126 on the positive electrode 111 shown in FIG. 25 as a conventional example is 11 hours for mean life, 0.5 hours for minimum value and 18 hours for maximum value. Samples RI06 and RII0 are respectively 9 hours and 6 hours for mean life, with the minimum and maximum values exhibiting a similar variance as with the sample RI0I.

On the other hand, the sample DI102 in which molybdenum oxide or a transition metal oxide is used as the charge-injection layer 115 has 110 hours for mean life, with the variance from 90 hours to 120 hours. Similar results are obtained for other samples D103 to 105.

Then, a search is made for the number of elements which have shown a short circuit in pixels corresponding to each of the 100 elements. Whether they have a short circuit is defined based on a fact that an element ceases to emit light within 10 minutes after evaluation of the life and an electric current flows to a great extent.

The number of pixels which have shown a short circuit is counted for the samples RI01 to DI15, the results of which are given in Table 1.

It is apparent that an element in which molybdenum oxide is used as a charge-injection layer is fewer in the number of short circuits than that in which PEDT is used, and also decreased in the number of short circuits in proportion to an increase in thickness. It is also apparent that an example of the conventional element shown in FIG. 25 is more likely to have. a short circuit in proportion to an increase in thickness of the pixel restricting layer 114, whereas an element in which molybdenum oxide is used shows an excellent result.

Regarding the thickness of a charge-injection layer 115, the number of short circuits is found to decrease greatly when molybdenum oxide-used samples are formed in a thickness of approximately 30 nm or more.

TABLE 1

| | | Thickness | The number of pixels |
|---|---|---|---|
| | Thickness of | of pixel | which have shown a short |
| Samples | MoO₃ | restricting layer | circuit in 100 pixels |
| R101 | PEDOT (60 nm) | 50 nm | 64 |
| R102 | 20 nm | 50 nm | 39 |
| R103 | 30 nm | 50 nm | 13 |
| R104 | 50 nm | 50 nm | 6 |
| R105 | 100 nm | 50 nm | 1 |
| R106 | PEDOT (60 nm) | 100 nm | 76 |
| R107 | 20 nm | 100 nm | 45 |
| R108 | 30 nm | 100 nm | 21 |
| R109 | 50 nm | 100 nm | 10 |
| R110 | 100 nm | 100 nm | 4 |
| R111 | PEDOT (60 nm) | 200 nm | 83 |
| R112 | 20 nm | 200 nm | 55 |
| R113 | 30 nm | 200 nm | 28 |
| R114 | 50 nm | 200 nm | 10 |
| R115 | 100 nm | 200 nm | 5 |

The second embodiment includes the following inventions.

The organic electroluminescent element of the second embodiment is provided with at least a pair of electrodes and a luminescent layer composed of at least one type of an organic semiconductor between these electrodes, in which a transition metal oxide layer having a film thickness of 30 nm or more is formed between at least either of the electrodes and the luminescent layer.

The present inventor and others have already proposed in the previously described Patent Document 1 that molybdenum oxide, one of transition metal oxides, is formed thin to provide injection characteristics more favorable than those of PEDT in a conventional procedure in which the thickness is at most 20 nm or lower. Under these circumstances, as the results of various experiments, the present inventor and others have found that the thickness of the transition metal oxide, in particular, the film thickness of molybdenum oxide, is quite insensitive to element properties and able to retain favorable hole injection characteristics even if it is formed thick. Thus, it is found that the number of short circuits that pixels have can be decreased by making the film thickness of the transition metal oxide to be 30 nm or more.

According to this constitution, a transition metal oxide layer having a film thickness of at least 30 nm is contained as the charge-injection layer 115. Therefore, even where a resist may remain at the time of patterning a translucent electrode such as ITO or particles may attach on the ITO, a transition metal oxide layer is formed in a thickness of 30 nm or more, and a layer having a luminescence function, which is formed thereafter on the upper layer thereof, is free of thickness distribution and formed in a uniform manner. Thus, a non-light emitting region is not formed or a pixel does not show a short circuit, thereby making it possible to form a layer having a uniform luminescence function and also obtain a favorable luminescent profile. Furthermore, since a transition metal oxide small in specific resistance such as molybdenum oxide is used, it is free of a great voltage drop when formed thick, and also able to impart an electric field to a layer having the luminescence function. In this instance, the transition metal oxide includes molybdenum oxide, vanadium oxide and tungsten oxide. However, molybdenum oxide (MoOₓ) is not restricted to MoO₃ and that different in valence is also effectively used (reasons for forming oxides different in valence are described in detail in the first embodiment). Vanadium oxide and tungsten oxide different in valence are also effectively used. An oxide containing a plurality of elements formed by a co-deposition method is also applicable.

Furthermore, an organic electroluminescent element of the second embodiment includes the above-described organic electroluminescent element in which a transition metal oxide layer is formed as a film in such a way that the specific resistance along a laminated direction is smaller than the specific resistance along a planar direction.

According to this constitution, since the specific resistance in a transverse direction, that is, a planar direction, is greater, it is possible to prevent an electrical cross-talk between adjacent organic electroluminescent elements. Therefore, where the charge-injection layer 115 is not subjected to an individual patterning corresponding to each of the organic electroluminescent elements but can be formed integrally, it is also possible to prevent a cross-talk and realize an easy manufacturing.

Furthermore, since the transition metal oxide layer entirely covers an underlying layer which is given at least as an organic electroluminescent element-forming region, it is possible to provide a stable and highly reliable structure. Still furthermore, the specific resistance along a vertical direction, that is, a laminated direction, is smaller to result in a decreased voltage drop. As described above, the present inventor and others have conducted various experiments, finding that the transition metal oxide layer is interposed between the luminescent layer and the electrode (positive electrode 111) to improve the characteristics.

### Third Embodiment

Hereinafter, a description will be given of a third embodiment with reference to drawings.

FIG. 16 is a sectional view showing an organic electroluminescent element of the third embodiment of the present invention. This electroluminescent element is provided with a positive electrode 111 composed of an ITO layer as a first electrode, a negative electrode 113 as a second electrode and a functional layer formed between these electrodes on a translucent substrate 100, in which the functional layer is provided with a luminescent layer 112, that is, a layer having the luminescence function composed of an organic semiconductor polymer layer, a 40 nm-thick transition metal oxide layer as the charge-injection layer 115 formed between the positive electrode 111 and the luminescent layer 112 (molybdenum oxide layer, hereinafter, referred to as transition metal oxide layer 115), a pixel restricting layer 114 composed of a 50 nm-thick silicon nitride film on the upper layer thereof, and an electron blocking layer 117, wherein the transition metal oxide layer 115 is formed at a recess formed by the pixel restricting layer 114, on which the electron blocking layer 117 and the luminescent layer 112 are formed in an ink jet method.

In this instance, an electron blocking layer 117 composed of tetradihexyl fluorenyl biphenyl (TFB) is formed between a thick molybdenum oxide layer as the transition metal oxide layer 115 and a first electrode composed of ITO (indium tin oxide) which is the positive electrode 111. Furthermore, a second electrode, that is, the negative electrode 113, is constituted with a barium electrode 113a having a thickness of approximately 3 nm and a 150 nm-thick aluminum electrode 113b formed on the upper layer thereof.

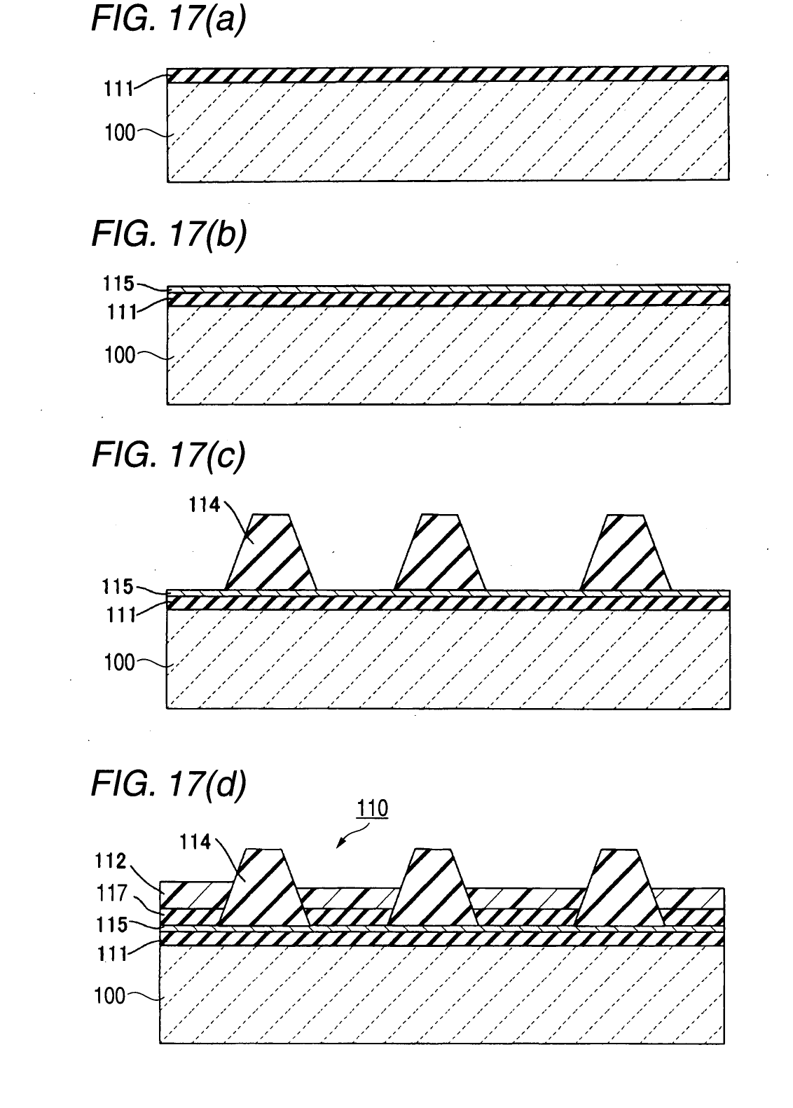

FIG. 17 is a view for illustrating a manufacturing process of the organic electroluminescent element according to the third embodiment of the present invention.

Hereinafter, a description will be given of a manufacturing method for the organic electroluminescent element of the third embodiment.

First, as illustrated in FIG. 17(a), a sputtering method is used to form an ITO film having a thickness of approximately 120 nm on the surface of a translucent substrate 100, thereby providing a first electrode 111.

Thereafter, as illustrated in FIG. 17(b), a vacuum deposition method is used to form a transition metal oxide layer 115 mainly made with molybdenum oxide so as to give the thickness of approximately 40 nm.

Then, as illustrated in FIG. 17(c), a silicon nitride film is formed by a high-density plasma CVD method, and an aperture is provided by photolithography to form a pixel restricting layer 114.

Thereafter, as illustrated in FIG. 17(d), a coating method is used to form an electron blocking layer 117 composed of TFB, thereby forming a luminescent layer 112. An ink jet method is used to form the luminescent layer 112 on the basis of a polymer luminescent material. In the third embodiment, the luminescent layer 112 is formed by using a polyfluorene-based luminescent material. Individual materials are dissolved into xylene and the resultant is filtered through a micro filter to prepare the electron blocking layer 117 and the luminescent layer 112. The materials are used at the concentration of 1%.

Thereafter, a vacuum deposition method is used to sequentially laminate an intermediate layer 113a composed of barium having a film thickness of approximately 3 nm and an electrode layer 113b composed of aluminum having a film thickness of 150 nm, thereby forming an organic electroluminescent element shown in FIG. 16.

In this instance, the ionization potential of a molybdenum oxide layer as a transition metal oxide layer 115 is constituted so as to be approximately equal to or greater than the ionization potential of a functional layer in contact with the transition metal oxide layer 115 side. Furthermore, the transition metal oxide layer 115, which is formed as a film by a CVD method, is laminated by controlling the composition ratio, pressure and temperature of a source gas on film formation. Furthermore, the transition metal oxide layer 115 is formed so that the specific resistance in a laminated direction is approximately one third of that in a planar direction. Still furthermore, the film thickness is made to be as thin as 40 nm, which would be unavailable conventionally, and the transition metal oxide layer 115, which is made thick, is used to planarize and smooth the surface, thereby regulating the area of a light emitting region favorably.

Polymer substances, oligomers, and small-molecular substances having a dendritic multi-branched structure may be used as the luminescent layer 112. A material design for preventing crystallization is needed when oligomers or small-molecular materials are used, and two or more materials are mixed to effectively prevent the crystallization. A substance having a dendritic multi-branched structure is a so-called dendrimer. It is well known that the use of heavy metals such as Ir and Pt at the center of dendron skeleton emits phosphorescence in a desired color such as green, red and blue. In this instance, a phosphorescent material can provide a triplet luminescence, thereby making it possible to increase the luminous efficiency and decrease the electric power consumption as compared with a fluorescent material. On the basis of these findings, a phosphorescent material is effective as the luminescent layer 112 of an organic electroluminescent element.

In the third embodiment, a polymer fluorescent material is used as the luminescent layer 112. Furthermore, a similar effect is also obtained for a iridium dendrimer complex given in (Chemical formula 1), which is a green phosphorescence-emitting dendrimer.

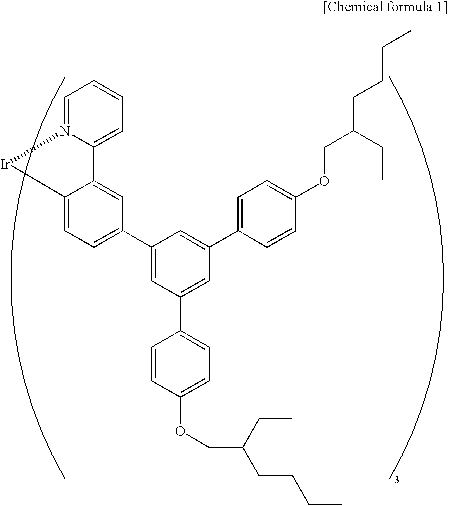

Furthermore, where a phosphorescent material is used in a color display device, in addition to the above-described green luminescent layer 112, red and blue dendrimers can be treated by an ink jet method and sequentially filled into a recess formed by the pixel restricting layer 114, thereby a color display device which will not easily undergo a color mixture is achieved.

An example of red-phosphorescence emitting dendrimers includes an iridium dendrimer complex given in Chemical formula 2.

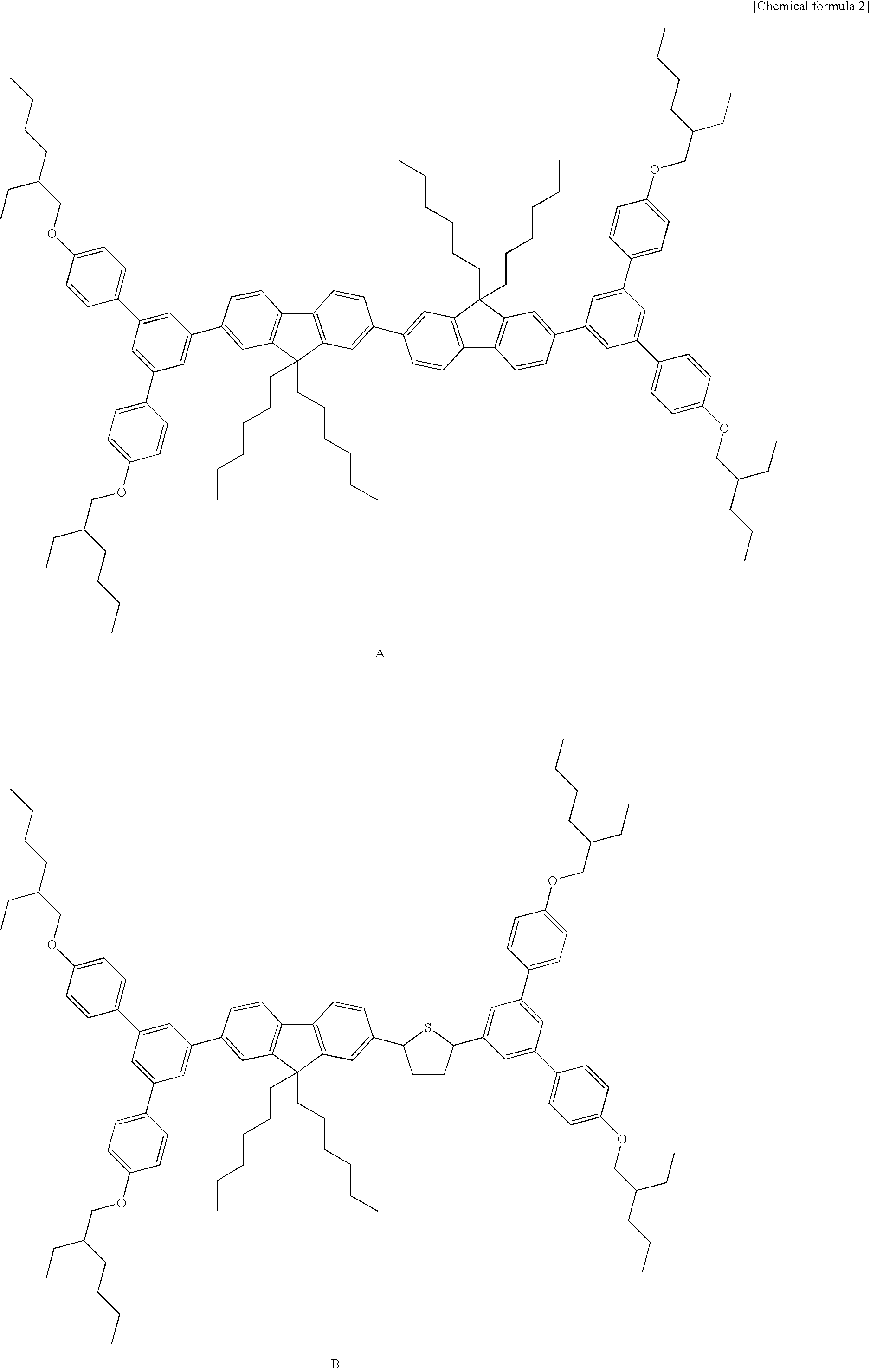

An example of blue-phosphorescence emitting dendrimers includes an iridium dendrimer complex given in Chemical formula 3. This dendrimer is a complex constituted with a mixture of deep-blue light emitting dendrimer A and blue-green light emitting dendrimer B.

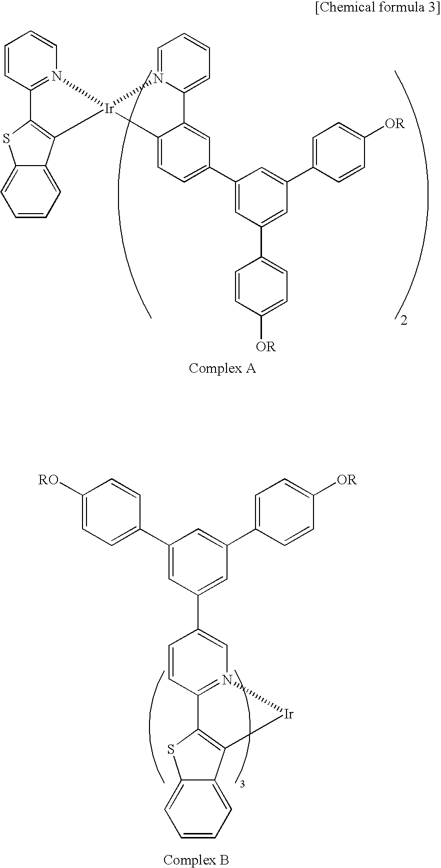

According to this constitution, the organic electroluminescent element can be formed by an ink jet method, which is excellent in injection efficiency and high in reliability. Since the luminescent layer 112 is formed by an ink jet method on the upper layer of the transition metal oxide layer 115, the luminescent layer 112 can be made smoothly according to this method. Furthermore, the transition metal oxide layer 115 is made to be 40 nm or more in thickness, a thick molybdenum oxide layer is used to planarize and smooth the surface, thereby making it possible to restrict the area of a light emitting region favorably. Furthermore, the underlying layer of a pixel restricting layer 114 can be smoothened. Therefore, if the pixel restricting layer 114 is made thin by the thickness so smoothened, a sufficient insulation property can be retained. Then, a step difference resulting from the pixel restricting layer 114 can be decreased to result in a more uniform distribution of the thickness of a layer having the luminescence function (luminescent layer 112). Furthermore, no short circuiting of pixels occurs.

The luminescence properties have been measured to find that the above constitution provides a rectangular luminescent profile exhibiting favorable luminescence properties. In this instance, the pixel restricting layer 114 may be made not with an insulating material but with a light blocking material. Furthermore, even those materials that have both a light blocking effect and an insulation property are able to restrict a light outgoing region favorably and also specify a pixel.

The ink jet method used in the third embodiment can be carried out by a known method. Selection of a head is particularly important, and a piezo element-equipped ink jet head is preferably used. A liquid drop quantity for one time ejection is not specified in particular, but preferably from 1 pl to 10 pl.

Next, in order to observe a change in properties of the transition metal oxide layer 115 in this organic electroluminescent element with respect to the thickness, samples different in thickness are prepared. In this instance, the luminescent layer 112 is formed in an ink jet method. The 40 nm-thick transition metal oxide layer 115 is used as an underlying layer, thereby making it possible to obtain a favorable luminescent profile for a prolonged period of time.

These samples are prepared according to procedures in which an ITO film is used to form a positive electrode 111 on the surface of a translucent substrate 100 by a sputtering method, the transition metal oxide layer 115 mainly made with molybdenum oxide is then formed so as to give a desired thickness by a vacuum deposition method, a silicon nitride film is formed by a high-density plasma CVD method, an aperture is made by photolithography and the pixel restricting layer 114 is formed. Then, an electron blocking layer 117 is formed by an ink jet method, and a luminescent layer 112 is formed by an ink jet method as well. The luminescent layer 112 is formed by an ink jet method, for example, with the above-described luminescent material.

As described above, the transition metal oxide layer 115 is changed in thickness to prepare elements (pixels) by every 100, and the 100 elements are measured for the life under the condition that the brightness is kept constant at 10000 cd/m² thereby a variance of the life is evaluated.

In this instance, the life is defined as the time elapsed until a current value introduced into an element is made equal to 4 times an initial current value.

As a result, a sample in which PEDT is used as a charge-injection layer on the positive electrode 111 is 11 hours for mean life, 0.5 hours for minimum value and 18 hours for maximum value.

In contrast, a sample 2 in which molybdenum oxide, or a transition metal oxide layer 115, is used as an underlying layer is 110 hours for mean life, with the variance falling in a range from 90 hours to 120 hours.

Then, a search is made for the number of elements which have shown a short circuit in pixels corresponding to each of the 100 elements. Whether they have a short circuit is defined based on a fact that an element ceases to emit light within 10 minutes after evaluation of the life and an electric current flows to a great extent.

An element in which molybdenum oxide is used as the transition metal oxide layer 115 functioning as a charge-injection layer is fewer in the number of short circuits than that in which PEDT is used, and also decreased in the number of short circuits with an increase in thickness. An element in which PEDT is used is more likely to have a short circuit with an increase in thickness of the pixel restricting layer 114, whereas an element in which molybdenum oxide is used hardly shows a short circuit.

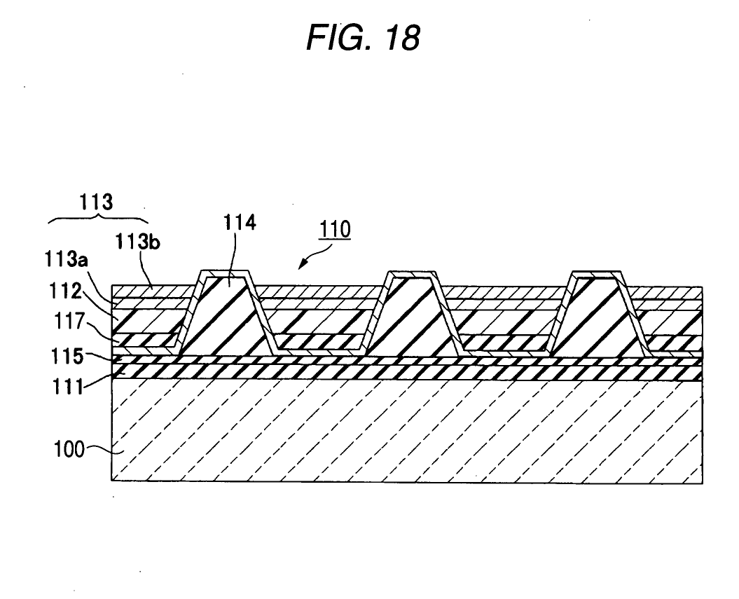

FIG. 18 is a sectional view showing an organic electroluminescent element of a modification of the third embodiment of the present invention. The electroluminescent element is, as with the third embodiment, provided with a luminescent layer 112 formed by an ink jet method but different from the third embodiment in that the surface of a pixel restricting layer 114 is entirely covered with a molybdenum oxide layer as a transition metal oxide layer 115 and the luminescent layer 112 is formed on the upper layer thereof. Others are similarly formed as those given in the third embodiment.

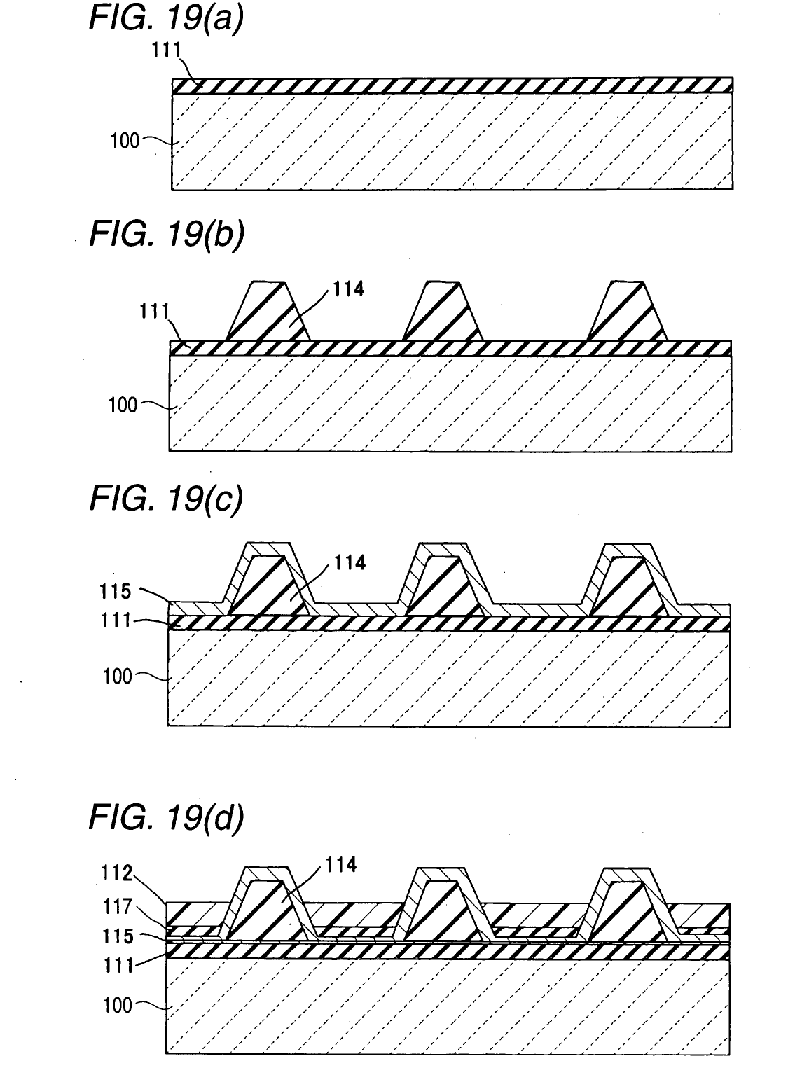

FIG. 19 is a view for describing a manufacturing process of the organic electroluminescent element of the modification of the third embodiment of the present invention.

Hereinafter, a description will be given of a method for manufacturing the organic electroluminescent element.

First, as illustrated in FIG. 19(a), an ITO film is formed on the surface of the translucent substrate 100 by a sputtering method to provide a positive electrode 111.

Next, as illustrated in FIG. 19(b), a photosensitive resin mainly made with polyimide is coated thereon, and an aperture is made by photolithography to form a pixel restricting layer 114, and as illustrated in FIG. 19(c), an MoO₃ layer 115 as a transition metal oxide is formed by a vacuum deposition method so as to entirely cover the pixel restricting layer 114 and give the thickness of approximately 50 nm.

Thereafter, as illustrated in FIG. 19(d), an ink jet method is used to form a 20 nm-thick TFB layer as an electron blocking layer 117, and thereafter an ink jet method is also used to form a 80 nm-thick luminescent layer 112. The luminescent layer 112 is formed, for example, with a polymer luminescent material by an ink jet method. In this instance, ink is in contact with the underlying layer of the electron blocking layer 117 at 30 degrees. Furthermore, the surface roughness is found to be approximately 2 nm. This is because a thin TFB layer is formed on the surface planarized by the transition metal oxide layer 115, and the surface roughness is similar to that of the underlying layer.

Thereafter, a vacuum deposition method is used to sequentially laminate an intermediate layer 113a composed of barium having a thickness of approximately 3 nm and an electrode layer 113b composed of aluminum having a thickness of 150 nm, thereby the organic electroluminescent element shown in FIG. 18 is formed.

In this instance as well, the ionization potential of the molybdenum oxide layer as a transition metal oxide layer 115 is constituted so as to be greater in absolute value than that of the functional layer in contact with the transition metal oxide layer 115 (for example, luminescent layer 112). Furthermore, the transition metal oxide layer 115 side is formed by a CVD method, and laminated by controlling the composition ratio, temperature and pressure of a source gas on film formation. Furthermore, the transition metal oxide layer 115 is formed so that the specific resistance in a laminated direction is approximately one third of that in a planar direction. Then, since the transition metal oxide layer 115 entirely covers the surface of the upper layer of the substrate 100 in an integrated manner, it will not react with the underlying layer and can retain the surface in a stable and highly reliable manner, thereby a high reliability as an underlying layer of the luminescent layer 112 is realized.

Next, an experiment is conducted to confirm the effect of the present invention by changing the thickness of the transition metal oxide layer 115, with the above-described structure.

First, polyimide is formed as a film on a substrate 100 or an ITO substrate on which a positive electrode 111 is formed, a photolithographic process is conducted by using a resist, and a pixel restricting layer 114 having one side of 35 μm as a bank is used at a pitch of 42 μm to provide 10 dots. The bank made with polyimide has the thickness of 2 μm.

PEDT is coated by an ink jet method on a positive electrode 111 composed of an ITO thin film having the thus obtained pixel restricting layer 114 so as to give a thickness of approximately 70 nm and baked, then, an electron blocking layer 117 is coated by an ink jet method to give a thickness of 20 nm and baked. Continuously, a polymer red-luminescent material is also coated by an ink jet method and baked. Furthermore, a negative electrode 113 composed of Ba and Al is deposited by a resistive heating deposition device so as to give a total thickness of 120 nm and used as a common electrode for all the dots, whereby comparative examples are prepared.

Next, samples are prepared by the procedures in which a similar substrate is used, or molybdenum oxide as the transition metal oxide layer 115 is subjected to vacuum deposition on the substrate by changing the thickness from 20 nm, 40 nm, 80 nm to 120 nm in place of a charge-injection layer 126 composed of PEDT, on which an electron blocking layer 117, a luminescent layer 112 and a negative electrode 113 are formed by using an ink jet method. A direct current voltage is applied to the thus obtained samples, and a high-resolution CCD camera is used to measure the distribution of light emission within one pixel.

As a result, the comparative examples exhibit a hanging-bell shaped luminescent profile, whereas the samples in which molybdenum oxide is used exhibit an approximately rectangular luminescent profile.

Comparative examples in which PEDT is used exhibit a hanging bell-shaped luminescent profile, possibly because a PEDT layer (that is, a charge-injection layer), an electron blocking layer 117 and a luminescent layer 112 are not uniform in thickness within a pixel, and this results in a change in luminous efficiency and a subsequent change in luminescent profile. On the other hand, the pixel in which molybdenum oxide is used exhibits a rectangular luminescent profile, possibly because there is an improved thickness uniformity. As described above, excellent life properties are found in the profile which is approximately rectangular.

Next, these samples are adjusted so as to give an initial brightness of 12000 cd/m² and subjected to a life test. As a result, the sample 201 was decreased half in life for 30 minutes, whereas the sample in which molybdenum oxide is used exhibits half life of 100 hours at a maximum and depends on the thickness to a lesser extent.

This is suggestive of a finding that there is a greater difference in forming the electron blocking layer 117 by an ink jet method depending on whether molybdenum oxide is used or PEDT is used. This finding is based on a fact that PEDT is a water dispersion solution, the surface of which is kept to be still hydrophilic after being dried, whereas the surface of ITO constituting a positive electrode 111 is hydrophilic but a bank material constituting the pixel restricting layer 114 has a lipophilic surface such as polyimide. As a result, it is considered that where PEDT is prepared by an ink jet method, a portion at which ink droplets are brought into contact with a bank is bounced and made thin.

Furthermore, an electron blocking layer 117 and a luminescent layer 112 dissolved in an organic solvent (for example, xylene and toluene) are ejected from an ink jet nozzle above a PEDT layer, they are dispersed on the PEDT to a lesser extent but easily dispersed at a portion which is in contact with the pixel restricting layer 114 (bank). Therefore, these layers are not uniformly dispersed. On the other hand, since the transition metal oxide layer 115 is not so hydrophilic on the surface as compared with the PEDT layer, an organic layer dissolved in an organic solvent is confirmed to attain a uniform dispersion even when an ink jet method is used. This is found to be very effective in making uniform the thickness inside a pixel, at least one side of which is surrounded by the pixel restricting layer 114 (bank).

After the results of the life test are evaluated, a maximum life value is approximately 100 hours. Where the transition metal oxide layer 115 is thin, many elements show a short circuit during the test, but where the transition metal oxide layer 115 is made thick from 40 nm, 80 nm to 120 nm, no elements show a short circuit.

The reason thereof is estimated due to a fact that where the transition metal oxide layer 115 is thin, there are effects of irregularities resulting from fine crystals on the surface of ITO, which is a positive electrode 111, and dust developed during the process, but where the transition metal oxide layer 115 is formed thick by using molybdenum oxide, projections and dust on the surface which may result in a short circuit are covered by the transition metal oxide layer 115, thereby a change in luminescence properties is prevented. However, true factors still remain unknown, and the experimental facts have thoroughly confirmed that samples in which the thick transition metal oxide layer 115 is used are highly reliable.

According to a method for manufacturing the organic electroluminescent element of the third embodiment, since an ink jet method is used to form a functional layer on a transition metal oxide layer, it is possible to provide an ink pattern excellent in wettability and high in accuracy and also to form a desired functional layer.

The thus produced organic electroluminescent element is high in injection efficiency of holes, stable in operation and also excellent in life property, thus making it possible to realize a stable injection of electric charge and maintain a luminous efficiency under various conditions, from mild driving conditions for a display application to severe driving conditions such as a strong electric field, a great electric current and a high brightness for an exposure apparatus and the like.

As described above, the method of the third embodiment is that in which a polymer layer is directly coated by an ink jet method on an inorganic oxide layer and able to favorably form a polymer layer. The inorganic oxide layer is to improve an electric charge injection effect. In order to add an electron blocking function, another functional layer such as tetradihexyl fluorenyl biphenyl (TFB) may be provided between the upper layer of the inorganic oxide layer and the luminescent layer. The functional layer having the electron blocking function is a layer provided for preventing electrons injected from a negative electrode from being flown to a positive electrode without rejoining with a luminescent layer, and those having a smaller LUMO energy than the LUMO level of a luminescent layer have a similar function. More specifically, the polymer layer includes functional layers such as a layer having the luminescence function, a charge-injection layer, a charge transport layer, and an electric charge blocking layer. An inorganic oxide layer has an intrinsic effect of smoothening the surface of an anode electrode (ITO and others), thereby, a substance, for example, TFB, which is coated on the inorganic oxide layer is made extremely uniform in thickness. Then, a luminescent layer formed on TFB by an ink jet method is also treated by using a common solvent such as xylene or toluene. Therefore, TFB and the luminescent layer are both quite excellent in wettability, and, as a result, TFB and the luminescent layer are both quite high in thickness uniformity even when they are formed by an ink jet method.

The third embodiment includes the following inventions.

The third embodiment is a method for manufacturing an organic electroluminescent element provided with a plurality of functional layers including a layer having a luminescence function composed of a pair of electrodes and at least one type of organic semiconductor formed between these electrodes, in which a functional-layer forming process includes a process for forming a transition metal oxide layer and a process for forming a functional layer by an ink jet method by supplying ink in which a functional material is dissolved in an organic solvent to the upper layer of the transition metal oxide layer. This constitution allows the functional layer to be formed by an ink jet method on the transition metal oxide layer having a favorable wettability with regard to ink containing an organic solvent, by which the ink can be supplied uniformly to provide the uniform functional layer.

In this instance, the function of the functional layer means various functions such as an electron blocking function, a hole injection function and a luminescence function, and the functional layer means an electron blocking layer, a hole injection layer and a luminescent layer. Furthermore, a region for supplying ink is specified so that the ink may be supplied therein, by which a luminescent layer can be formed quite easily in various colors without any color mixture. Still furthermore, since ink droplets are to be supplied, irregularities on the surface are more favorably covered. Therefore, it is also effective that an electron blocking layer or the like is formed in advance by an ink jet method and a luminescent layer is formed on the upper layer thereof. Furthermore, since the underlying layer is constituted with a transition metal oxide, there is no chance that the oxide is decomposed on injection of electrons to break the luminescent layer, as found in PEDT. Since the thus constituted underlying substrate is excellent in wettability with respect to an organic solvent, there is no chance either that ink jet droplets cause non-uniformity of the thus formed film. It is, therefore, possible to form a layer having a luminescence function which is more uniform in thickness distribution.

Furthermore, the third embodiment is a method for manufacturing an organic electroluminescent element in which a functional-layer forming process includes a process for forming an electron blocking layer on a transition metal oxide layer.

Furthermore, a film-forming process by an ink jet method in the third embodiment may be conducted in such a way that ink for forming a layer having a luminescence function is in contact with the transition metal oxide layer at an angle of 45 degrees or lower. According to this constitution, since the ink is to be in contact with the transition metal oxide layer at an angle of 45 degrees or lower, the ink is favorably coated to provide a desired pattern. When the angle exceeds 45 degrees, the ink is dispersed to result in a decreased accuracy of the pattern. An angle of 30 degrees or lower is more preferable.

Furthermore, the third embodiment is a method for manufacturing an organic electroluminescent element including a polymer compound in which a layer having a luminescence function contains a dendrimer. The dendrimer may include a phosphorescence-emitting type dendrimer.

Furthermore, the third embodiment is a method for manufacturing an organic electroluminescent element in which a process of forming a luminescent layer includes a process in which after a transition metal oxide layer is formed so that the arithmetic mean roughness of Ra is 5 nm or lower, an ink jet method is used to form a layer. Where an ink jet method is used to form a layer having a luminescence function, it has been made apparent from the experimental result that the surface roughness of an underlying layer has a great influence on film properties. Thus, an elaborately formed film having the arithmetic mean roughness Ra of 5 nm or less is used, by which the layer having a luminescence function formed on the upper layer thereof can be formed uniformly without the thickness distribution. Therefore, the layer having a uniform luminescence function can be formed to result in a favorable rectangular-shaped luminescent profile, without leakage of emitted light. Furthermore, no emergent projections on a film develop, by which the occurrence of a so-called dark spot, or a non-light emitting portion, can be prevented. Still furthermore, a short circuit or others resulting from a projected portion of the positive electrode can be prevented. Consequently, an electric current running through the organic electroluminescent element is uniformly distributed, thereby making it possible to provide a uniform light emission for a prolonged period of time. In addition, since no portion is needed at which an excessively bright light is emitted for obtaining a desired light quantity, it is possible to prolong the life of the organic electroluminescent element. Furthermore, where the surface roughness of Ra exceeds 5.0 nm, a dark spot will develop.

Furthermore, the third embodiment is a method for manufacturing an organic electroluminescent element including a process in which after a transition metal oxide layer is formed so as to give a thickness from 5 to 200 nm, an ink jet method is used to form a luminescent layer. This constitution makes it possible to provide a transition metal oxide layer excellent in surface smoothness, by which the luminescent layer is formed uniformly without thickness distribution. It is, therefore, possible to form a layer having a uniform luminescence function and also provide a favorable rectangular luminescent profile. Although a thin layer is effectively made uniform in thickness, a thickness exceeding 200 nm will result in a higher resistance and a higher driving voltage, which may be practically utilized depending on an application.

Furthermore, the third embodiment is a method for manufacturing an organic electroluminescent element including a process in which a transition metal oxide is molybdenum oxide (MoₓO_{y}).

Furthermore, the third embodiment is a method for manufacturing an organic electroluminescent element including a process in which a transition metal oxide is vanadium oxide (VₓO_{y}).

Furthermore, the third embodiment is a method for manufacturing an organic electroluminescent element including a process in which a transition metal oxide is tungsten oxide (WₓO_{y}).

Furthermore, the third embodiment is a method for manufacturing an organic electroluminescent element, in which the above-described ink contains an organic solvent whose boiling point is 110° C. or higher. Thereby, it is possible to remove the organic solvent at a relatively low temperature and form an underlying layer without a deterioration. Selection of a solvent is important for ink to be used in an ink jet method. Since an excessively high drying speed tends to develop irregularities on the surface, it is preferable to dissolve a functional material in an organic solvent having a boiling point of 100° C. or higher, which is then ejected from a nozzle. Preferably usable solvents include non-polar solvents such as toluene and xylene or their derivatives. High boiling-point polar organic solvents such as DMF (dimethyl formamide), N-methyl pyrrolidone and dimethyl sulfoxide, or mixtures with a halogen-based substance such as dichloro benzene may be used, depending on the solubility of a material. It is also possible to add low boiling-point solvents or alcohols for adjusting the drying speed. Where only low boiling-point organic solvents such as acetone, chloroform and ethyl alcohol are used, the drying speed is so high that the uniformity may be deteriorated. It is also preferable that the ejection from an ink jet head and the drying process are conducted in an atmosphere in which nitrogen or argon is filled.

Furthermore, the third embodiment is a method for manufacturing an organic electroluminescent element in which ink is 20 cp or lower in viscosity. Since the viscosity of ink influences the uniformity after film formation or during drying, the use of a solvent having the above-described boiling point makes it possible to form a film excellent in uniformity in a viscosity from 1 to 20 cp.

Still furthermore, the third embodiment is a method for manufacturing an organic electroluminescent element in which an ink jet process includes a process for forming luminescent layers different from each other at the respectively corresponding regions by using different types of ink.

In addition, the third embodiment is an organic electroluminescent element formed by the method for manufacturing an organic electroluminescent element.

The thus obtained organic electroluminescent element is provided with at least a pair of electrodes and a plurality of functional layers formed between these electrodes, in which a transition metal oxide layer (MₓO_{y}:M denotes a transition metal) interposed between a hole injecting electrode of a pair of the electrodes and a functional layer is included. The present inventor and others have already proposed in the above-described Patent Document 1 that molybdenum oxide, one of transition metal oxides, is formed thin to provide injection characteristics more favorable than those of PEDT in a conventional procedure in which the thickness is at most 20 nm or lower. Under these circumstances, various experiments have been conducted to find that when a transition metal oxide such as MoO₃ is adjusted for the film forming conditions and a functional layer material is selected by which the ionization potential of the transition metal oxide layer is made greater in absolute value than that of the functional layer on the transition metal oxide layer side, the thickness of the transition metal oxide, in particular, the thickness of MoO₃, is quite insensitive to element properties and able to retain favorable hole injection characteristics without depending on the thickness to a great extent.

According to this constitution, it is possible to provide an organic electroluminescent element uniform in luminescence properties and stable in operation. Since the operation is stable, a deposition method or the like is used to form a layer having a luminescence function on the upper layer thereof, by which the luminescent layer can also be constituted with a small-molecular layer.

Still furthermore, a transition metal oxide layer having a thickness of 30 nm or more is contained, by which even where a resist may remain at the time of patterning a translucent electrode such as ITO or particles may attach on the ITO, a transition metal oxide layer having a thickness of 30 nm or more is formed and also a layer having a luminescence function formed on the upper layer thereof is uniformly formed without thickness distribution.

Therefore, there is no chance of forming a non light-emitting region or having a short circuit of pixels, thus making it possible to form a layer having a uniform luminescence function and provide a favorable luminescent spectrum. Furthermore, upon forming a transition metal oxide such as MoO₃, the conditions can be appropriately selected to prepare a transition metal oxide small in specific resistance in a laminated direction. The thus prepared transition metal oxide will not cause a great voltage drop, even if being formed thick, thereby an electric field is imparted to a layer having a luminescence function. In this instance, the transition metal oxide may include molybdenum oxide, vanadium oxide and tungsten oxide. Molybdenum oxide (MoOₓ) is not restricted to MoO₃ but may include that different in valence. Vanadium oxide and tungsten oxide also include those different in valence. Furthermore, such an oxide that has a plurality of elements formed by a co-deposition method may also be applicable.

In addition to a case of co-deposition of molybdenum oxide, tungsten oxide and vanadium oxide described in the third embodiment, for example, SiO, In₂O₃ and TeO₂ are subjected to co-deposition, thereby making it possible to change the ionization potential or the conductivity and attain a more effective electrical-charge injection into an adjacent layer having a luminescence function. An element subjected to co-deposition is not restricted thereto. The thus formed transition metal oxide thin film is preferably non-crystalline.

The transition metal oxide layer used in the third embodiment is preferably from 5 nm to 500 nm in thickness, as long as it has fundamental electroluminescent characteristics. The transition metal oxide layer having a thickness of 30 nm or more is more preferable, because a rough surface of the underlying layer can be absorbed to improve the smoothness of the surface. Ink for ink jet printing in which an organic material is dissolved is filtered by a micro-filter so as to meet the specification. It is, however, quite difficult to inhibit the occurrence of particles widely different in size to zero. Therefore, it is very important to provide a manufacturing method for realizing stable characteristics even in the presence of particles.

Furthermore, the third embodiment includes a display device in which a plurality of organic electroluminescent elements formed by using the method for manufacturing the above-described organic electroluminescent element are arranged.

Furthermore, the third embodiment includes an exposure apparatus in which a plurality of organic electroluminescent elements formed by using the method for manufacturing the above-described organic electroluminescent element are arranged in a row to constitute a light emitting portion.

Furthermore, the third embodiment is a method for manufacturing the organic electroluminescent element which includes a manufacturing process of a pixel restricting layer after a process of forming the transition metal oxide layer and a process of forming a layer having a luminescence function on the transition metal oxide layer exposed from an aperture of the pixel restricting layer by an ink jet method.

According to this constitution, there is no chance that an oxide undergoes decomposition during driving, as found in PEDT, resulting in breakage of a luminescent layer due to resultant products such as oxygen atoms and the like or a film formed by ink containing an organic solvent by ink jet printing is made irregular. It is, thus, possible to form a layer uniform in thickness distribution and having a luminescence function. Furthermore, a step of the pixel restricting layer is moderated by a sufficiently thick transition metal oxide layer, and a layer having the luminescence function which is formed on the upper layer thereof can be made more uniform in thickness. This effect is made more prominent when the transition metal oxide layer is given a thickness of 30 nm or more, as described in the third embodiment, thereby a better luminescent profile per pixel is provided.

Transition metal oxides having the specific resistance from 1 MΩcm to 1 GΩcm are preferably used in the third embodiment. Of these oxides, those having the specific resistance from 10 MΩcm to 100 MΩcm are preferably used in particular. The specific resistance can be controlled for values on the basis of compositions of the thus obtained film or oxidation degree on the surface, defect status, crystallization degree, substrate temperature during thin-film formation and anneal temperature after the formation. Transition metal oxides tend to assume a non-crystalline state at temperatures close to an ordinary temperature and tend to assume a crystalline state at a higher temperature. Those in a non-crystalline state can be used as a transition metal oxide layer used in the third embodiment in the above-described range of the specific resistance.

Furthermore, the third embodiment is a method for manufacturing the organic electroluminescent element which includes a manufacturing process of the transition metal oxide layer all over the surface after a process of forming the pixel restricting layer and a process of forming a layer having the luminescence function on the transition metal oxide layer exposed from an aperture of the pixel restricting layer by an ink jet method.

According to this constitution, the surface exposed inside the pixel restricting layer is covered by the transition metal oxide layer, and there is provided a smaller contact angle, thus making it possible to form a stable and highly-reliable organic electroluminescent element on an underlying layer.

Furthermore, the third embodiment is a method for manufacturing the organic electroluminescent element which includes a process of forming an electrode on a substrate, a process of forming a transition metal oxide layer at a position opposite the electrode and a process of forming by an ink jet method a light emitting portion having at least the luminescence function at a position opposite the electrode at least across the transition metal oxide layer.

According to this constitution, the transition metal oxide layer entirely covers the surface of the pixel restricting layer to secure the protection of the underlying layer, thereby making it possible to form a stable and highly-reliable organic electroluminescent element.

Where the pixel restricting layer is used to effect a multi-color printing by an ink jet method, photo resist materials are used in general. A variety of photo resist materials are commercially available. In this instance, the pixel restricting layer is preferably formed so as to give the thickness from 1 μm to 10 μm and more preferably so as to give the thickness from 3 μm to 5 μm in view of the necessity for keeping ink used in ink jet printing inside a pixel so as not to overflow to an adjacent layer. Furthermore, where a single color printing is effected, ink overflown from a pixel to an adjacent layer will not pose any problem and the importance is to form a uniform layer. Thus, a thickness of approximately 0.05 μm may be acceptable and there should not pose any problem as long as the insulation property is secured. Other materials include an oxide silicon film and a silicon nitride film. In order to manufacture a full color display device, ink containing an organic functional layer which is dissolved in red, blue and green light emitting organic solvents is ejected into the pixel restricting layer by an ink jet method. In this instance, for the purpose of preventing a possible color mixture with an adjacent pixel, the pixel restricting layer is preferably high in thickness to some extent. On the other hand, in an application for single color printing, there is no necessity for keeping ink inside the pixel restricting layer, and ink overflown on or outside the pixel restricting layer will not pose any problem. In this meaning, no problem is found with the height of the pixel restricting layer from 1 μm to 50 nm, for example, as long as the insulation property can be secured. A pixel restricting layer prepared by high-quality silicon oxide or silicon nitride can be appropriately used in this application.

Where the transition metal oxide layer is made thick according to this constitution, the pixel restricting layer, regardless of whether it is on the upper layer or on the lower layer, can be planarized and smoothened to a greater extent as the surface of an underlying layer in forming a luminescent layer. Therefore, the pixel restricting layer can be selected at a greater extent of the thickness, with other factors taken into account.

Furthermore, in the case of a display device, a dimension of one pixel restricted by the pixel restricting layer is preferably in a rectangular shape usually from 5 μm to 200 μm, depending on the resolution and the size of a screen. However, in order to exhibit the effect of the third embodiment to a maximum extent, it is preferable that a corner is substantially in an arc shape in view of keeping the film uniform.

Still furthermore, an angle at which a portion of the pixel restricting layer in contact with a substrate forms with respect to the substrate is preferably small, that is, low, and an angle from 10 to 30 degrees is desirable in view of the uniformity. In the third embodiment, where a pixel restricting layer prepared by ordinary silicon nitride or silicon oxide is used, a dry etching process is conducted. In this instance, since the layer is from 0.05 to 1 μm in thickness, an angle in contact with the substrate is sufficient in the range from 60 to 80 degrees.

Ink droplets used in an ink jet method are usually in the range from 1 to 10 pl. It is preferable that many droplets are ejected into one pixel in the smallest possible ejected volume of droplets for averaging a variance in ejected quantity. Although depending on a required pixel size, where the pixel has a shorter side of approximately 40 μm, a preferable range is 2 pl or lower, and where the pixel has a shorter side of approximately 100 μm, a preferable range is 5 pl or lower.

Furthermore, the organic electroluminescent element of the third embodiment includes an MoO₃ layer with a thickness of 30 nm or more. According to this constitution, where a transition metal oxide layer such as the MoO₃ layer is used, the specific resistance in a vertical direction is sufficiently small, and there is no chance of a great voltage drop, even if the thickness is made to be as thick as 30 nm.

Furthermore, the organic electroluminescent element of the third embodiment includes a polymer compound in which a layer having a luminescence function contains a fluorene ring. In this instance, the polymer compound having a fluorene ring means that in which a desired group is bound with the fluorene ring to constitute a polymer. Furthermore, a polymer material having a spiro skeleton is preferably used. Polymer compounds which are bound with various groups are commercially available. However, they are not described here because the detailed information is not available.

A description has been so far made in detail of a method for manufacturing an electroluminescent element which forms a luminescent layer 112 on a charge-injection layer 115 by an ink jet method. In place of the ink jet method, a so-called printing method is also usable in manufacturing a high-performance electroluminescent element.

### Fourth Embodiment

Hereinafter, a description will be given of a fourth embodiment of the present invention with reference to the drawings.

The following description will be made with reference to FIG. 1 as well.

A method for manufacturing the electroluminescent element of the fourth embodiment is, as described in detail in the first embodiment and others, that in which a luminescent layer 112 is formed by a printing method on the upper layer of a charge-injection layer constituted with a transition metal oxide such as molybdenum oxide.

Experiments conducted by the present inventor and others have found that when a printing method is simply used in an attempt to form a layer having a luminescence function, an accurate pattern cannot be obtained without modification of the method.

Molybdenum oxide, one of the inorganic oxides, is formed thin, by which charge injection characteristics better than those obtained by PEDT are obtained, which has been already proposed in Patent Document 1 previously described by the present inventor and others. However, the idea that a printing method be used to form a luminescent layer thereon has not been proposed. This is because a region where a conventional functional organic film is formed thin and uniformly is sufficiently large and there is an allowance of pattern accuracy. However, in association with a miniaturized pattern, a region where a functional organic film is formed thin and uniformly is made small, whereby it becomes difficult to provide a sufficient uniformity. Then, the present inventor and others have conducted various experiments, finding that a reason for the failure of forming a highly accurate pattern by a printing method may be due to a large contact angle of 70 degrees in the case of PEDT, and an underlying layer is prepared under variously different conditions, with the above finding taken into account. As a result, where a luminescent layer is formed by a printing method on a charge-injection layer formed with an inorganic oxide such as molybdenum oxide, it is found that a highly accurate pattern can be formed. Therefore, with consideration given to the relationship with ink to be used, ink is allowed to be in contact with the underlying layer at approximately 10 degrees, thereby a printing pattern with high accuracy can be attained.

In an ink jet method, which needs to selectively give plasma processing to a necessary region, high plasma concentrations are found at the edge of the pattern in a concentrated manner on plasma processing. A large quantity of ink is placed thereon, and this results in a blurred pattern in some cases. It is now found that a pattern uniform in thickness can be formed where a functional organic layer is formed in a printing method on an inorganic oxide layer. Furthermore, since ink is adjusted so as to provide a higher wettability with respect to the surface of a substrate, the movement resulting from surface tension after the ink is coated is made small to form a film, by which the film can be formed with a low-boiling point material, if a positional restriction is sufficiently attained. Therefore, the film can be dried faster or formed at a lower temperature.

Furthermore, the fourth embodiment is a method in which a polymer layer (luminescent layer) is formed by a printing method on the upper layer of an inorganic oxide layer and not restricted to that in which, for example, a layer having a luminescence function is directly formed on an inorganic oxide layer.

For example, the inorganic oxide layer may be that having the effect of improving an electric charge injection effect. However, in order to add an electron blocking function, another layer such as TFB may be provided between the upper layer of the inorganic oxide layer and the luminescent layer.

The inorganic oxide layer has an intrinsic effect of smoothening the surface of an anode electrode (ITO and others), thereby, a substance, for example, TFB, which is coated on the inorganic oxide layer, is made extremely uniform in thickness. Then, a luminescent layer formed on TFB by a printing method is also treated by using a common solvent such as xylene or toluene. Therefore, TFB and the luminescent layer are both quite excellent in wettability, and, as a result, TFB and the luminescent layer are quite high in thickness uniformity even when they are formed by a printing method.

As a matter of course, the above-described inorganic oxide layer includes the transition metal oxide layer described in detail in the first embodiment and others.

Hereinafter, a description will be made in detail for a method for manufacturing the electroluminescent element of the fourth embodiment. A description will be made with reference to FIG. 1 used in the first embodiment.

According to a method for manufacturing the organic electroluminescent element of the fourth embodiment, since ink is adjusted so as to give a small contact angle on an inorganic oxide layer, and a printing method is used to form a layer having a luminescence function, it is possible to provide a luminescent layer pattern with high accuracy, which is stable in operation and excellent in life property. It is also possible to effect a multi-color printing or form a monolithic device by integration with other elements.

The fourth embodiment is that in which an underlying layer as the charge-injection layer 115 is constituted with molybdenum oxide or an inorganic oxide (transition metal oxide), processing is performed so that the surface roughness (Ra) is below 20 nm, and the luminescent layer 112 is thereafter formed by a printing method.

In other words, as shown in FIG. 1, the organic electroluminescent element of the fourth embodiment is constituted with a substrate 100 made with a translucent glass material, ITO (indium tin oxide) as a positive electrode 111 formed on the substrate 100, a transition metal oxide thin film (molybdenum oxide) layer as a charge-injection layer 115 formed on the upper layer thereof, a luminescent layer 112 composed of a polymer material, and a negative electrode 113 formed with a metal material. In this instance, as described in the first embodiment, a buffer layer 116 composed of a transition metal oxide may be provided between the luminescent layer 112 and the negative electrode 113.

According to the organic electroluminescent element of the fourth embodiment, where integration or miniaturization is intended, a printing method can be used to form a luminescent layer pattern high in accuracy, thus making it possible to provide a miniaturized pattern without using photolithography or causing any contamination. It is, therefore, possible to realize favorable luminescence properties in a light emitting device and a display device in which a plurality of organic electroluminescent elements are arranged two dimensionally and also provide a highly reliable element even at a high temperature.

Next, a description will be given of a process for manufacturing the organic electroluminescent element of the fourth embodiment.

First, an electrode layer made with an ITO thin film is formed by a sputtering method on a glass substrate 100, a charge-injection layer 115 constituted with molybdenum oxide, which is a transition metal oxide, is then formed by a vacuum deposition method so as to give a desired thickness, thereafter, a printing method is used to prepare a pixel restricting layer 114. Alternatively, an electrode composed of an ITO thin film and a pixel-restricting layer are formed by a sputtering method on the glass substrate 100, which are then subjected to patterning by photolithography, a charge-injection layer 115 is then formed by a vacuum deposition method so as to give a desired thickness, thereby a metal oxide thin film is formed. Then, a printing method is used to form a luminescent layer 112 on a buffer layer 115 composed of the metal oxide thin film.

Finally, a vacuum deposition method is used to form a negative electrode 113.

As described above, according a method of the fourth embodiment, the luminescent layer 112 is printed and formed on the charge-injection layer 115, thereby an easy manufacturing is realized and also miniaturization and high integration can be attained. Furthermore, in the fourth embodiment, a luminescent layer is formed on a charge-injection layer 115, and the charge-injection layer 115 also acts as a hole injection layer. Still furthermore, although another functional layer may be interposed, a structure in which the luminescent layer 112 is printed on the upper layer of a metal oxide layer such as the charge-injection layer 115 is provided, thereby making it possible to realize a highly reliable light emission.

Not only may a printing method be used to form a single-layered polymer layer on the charge-injection layer 115, but also a plurality of organic layers may be formed on another plate and then two or more layers may be transferred to the charge-injection layer 115 at the same time.

According to this constitution, the underlying layer of a pixel restricting layer 114 can be smoothened, and even if the pixel restricting layer 114 is made thin by the thickness so smoothened, an insulation property can be sufficiently kept to decrease a step resulting from the pixel restricting layer 114, whereby a luminescent layer 112 can be made more uniform in thickness distribution. Furthermore, no short circuiting of pixels occurs. According to the fourth embodiment, a thick charge-injection layer 115 is used to planarize and smooth the surface, thereby the luminescent layer 112 in a printing method is formed.

In the fourth embodiment, an underlying layer (that is, the surface of the charge-injection layer 115) at the time of forming the luminescent layer 112 is smoothened so as to give an arithmetic mean roughness of Ra equal to or lower than 20 nm, and printing is then conducted. As described above, the surface roughness is controlled, by which a highly accurate luminescent layer 112 can be patterned. Furthermore, even if the pixel restricting layer 114 is made thin, a sufficient insulation property can be retained, thereby making it possible to decrease a step resulting from the pixel restricting layer 114. The luminescent layer 112 is consequently made more uniform in thickness distribution.

Furthermore, the charge-injection layer 115 is to improve an electric charge injection effect. In order to add an electron blocking function and others, another layer such as TFB may be provided between the upper layer of the charge-injection layer 115 and the luminescent layer 112.

Thereby, the charge-injection layer 115 has an intrinsic effect of smoothening the surface of a positive electrode 111, and a substance, for example, TFB, which is coated on the charge-injection layer 115, is made extremely uniform in thickness. Then, the luminescent layer 112 formed on TFB by a printing method can be treated by using a common solvent such as xylene or toluene. Therefore, TFB and the luminescent layer 112 are both quite excellent in wettability, and, as a result, TFB and the luminescent layer 112 are quite high in thickness uniformity even when they are formed by a printing method.

The fourth embodiment includes the following inventions.

The fourth embodiment is a method for manufacturing an organic electroluminescent element including a process in which an angle of ink for forming a luminescent layer in contact with an inorganic oxide layer is given at 60 degrees or lower. According to this constitution, the contact angle with respect to the inorganic oxide layer is given at 60 degrees or lower, by which a wettability with the ink is improved and an ink pattern is formed on the inorganic oxide layer with high accuracy. The angle exceeding 60 degrees will result in poor wettability.

Furthermore, in a method for manufacturing an organic electroluminescent element of the fourth embodiment, a process of forming a luminescent layer includes a process in which after an inorganic oxide layer is formed so that an arithmetic mean roughness of Ra is 20 nm or lower, a printing method is used to form a luminescent layer. According to this constitution, a smooth surface can be formed, by which ink is provided with an improved wettability and a pattern formation can be made by a printing method with high accuracy. The inorganic oxide layer exceeding 20 nm in arithmetic mean roughness Ra will result in poor wettability.

Furthermore, a method for manufacturing an organic electroluminescent element of the fourth embodiment includes a process in which after an inorganic oxide layer is formed so as to give the film thickness from 10 to 200 nm, a printing method is used to form a layer having a luminescence function.

A step of underlying layer is moderated with an increase in thickness, thereby obtaining a smooth surface. According to this constitution, a smooth surface can be formed, by which ink is provided with an improved wettability and a pattern can be formed with high accuracy by a printing method. The thickness below 10 nm will deteriorate the surface planarization, whereas that exceeding 200 nm will cause a resistance to result in poor device characteristics.

Furthermore, in a method for manufacturing an organic electroluminescent element of the fourth embodiment, the printing method includes a reverse offset method, a relief printing method, a gravure printing method, a transfer method and a slit coater method.

Furthermore, in a method for manufacturing an organic electroluminescent element of the fourth embodiment, ink contains a solvent having a boiling point of 110° C. or more. According to this constitution, the drying speed can be easily controlled in a process in which a solvent is fixed by evaporation and drying after the ink is coated on the surface of a substrate, thereby forming a uniform film.

Furthermore, in a method for manufacturing an organic electroluminescent element of the fourth embodiment, ink has the viscosity of 20 cp or lower.

Furthermore, in a method for manufacturing an organic electroluminescent element of the fourth embodiment, a printing process includes a process in which a plurality of different types of ink are used to form luminescent layers different from each other at the corresponding regions.

Furthermore, the fourth embodiment includes an organic electroluminescent element which is formed by a method for manufacturing the above-described organic electroluminescent element.

### Fifth Embodiment

Hereinafter, a description will be given of a fifth embodiment of the present invention.

The following description will be made with reference to FIG. 15 used in explaining the second embodiment.

The electroluminescent element is provided with a positive electrode 111 composed of an ITO layer as a first electrode on a translucent substrate 100, a negative electrode 113 as a second electrode and a functional layer formed between these electrodes.

The functional layer is provided with a layer having a luminescence function at least composed of an organic semiconductor polymer layer, that is, a luminescent layer 112, and further provided with a 40 nm-thick molybdenum oxide layer as a charge-injection layer 115 (hereinafter, referred to as transition metal oxide layer 115) constituted with a transition metal oxide between the luminescent layer 112 and the positive electrode 111, a pixel restricting layer 114 composed of a 50 nm-thick silicon nitride film on the upper layer thereof and an electron blocking layer 117, in which the ionization potential of the transition metal oxide layer 115 is constituted so as to be greater in absolute value than that of the functional layer on the transition metal oxide layer 115 side. Furthermore, the transition metal oxide layer 115 is formed as a film by a CVD method. In this film formation, the transition metal oxide layer is laminated by controlling the composition ratio, the pressure and the temperature of a source gas. Still furthermore, the transition metal oxide layer 115 is formed in such a way that the specific resistance in a laminated direction is made to be one third of the specific resistance in a planar direction. In addition, the layer is made available in a thickness of 40 nm which would not be realized conventionally and constituted so as to favorably restrict the area of a light emitting region, with the surface being planarized and smoothened.

More specifically, the organic electroluminescent element of the fifth embodiment is provided with at least a pair of electrodes (a positive electrode 111 and a negative electrode 113) and a plurality of functional layers (the functional layer includes at least a luminescent layer 112) formed between the electrodes, and constituted in such a way that a transition metal oxide layer 115 (MxOy:M denotes a transition metal) disposed between a hole injecting electrode of the pair of electrodes and the functional layer is included and the ionization potential of the transition metal oxide layer 115 is made greater in absolute value than that of the functional layer on the transition metal oxide layer 115 side.

Furthermore, the fifth embodiment is an organic electroluminescent element provided with at least one hole injecting electrode and a plurality of functional layers formed on the electrode in which a transition metal oxide layer disposed between the electrode and the functional layer is included, and it is also constituted in such a way that the ionization potential of the transition metal oxide layer is made greater in absolute value than that of the functional layer on the transition metal oxide layer side. That is, injection of electric charge includes a case where an electric field is applied not from the electrode but externally.

The organic electroluminescent element of the fifth embodiment is thereby to remove an energy barrier and improve an injection efficiency.

Various experiments have been conducted to find that when a transition metal oxide such as molybdenum oxide is adjusted for film forming conditions and a functional layer is selected, by which the ionization potential of the transition metal oxide layer 115 is made greater in absolute value than that of the functional layer on the transition metal oxide layer side, favorable hole injection characteristics can be retained. This constitution can lower the energy barrier and improve the luminous efficiency, thereby providing an organic electroluminescent element high in brightness. Here, the film forming conditions are adjusted to change values of x and y in the above substance (MxOy: M denotes a transition metal), thereby making it possible to change a value of the ionization potential and increase the injection efficiency by adjusting the value.

More specifically, in the organic electroluminescent element of the fifth embodiment, the transition metal oxide layer 115 is constituted with a plurality of types of transition metal oxides different in oxidation number, and this constitution can give various energy levels to a transition metal compound layer and improve the injection efficiency.

In the fifth embodiment, an electron blocking layer 117 composed of TFB is additionally formed between a transition metal oxide layer 115 and a positive electrode 111. Furthermore, a negative electrode 113 is constituted with an intermediate layer 113a composed of barium having a film thickness of approximately 3 nm and a electrode layer 113b composed of aluminum having a film thickness of 150 nm on the upper layer thereof.

The electron blocking layer 117 is formed adjacent to the transition metal oxide layer 115, by which electrons supplied from the negative electrode 113 are prevented from escaping, thereby further improving the luminous efficiency.

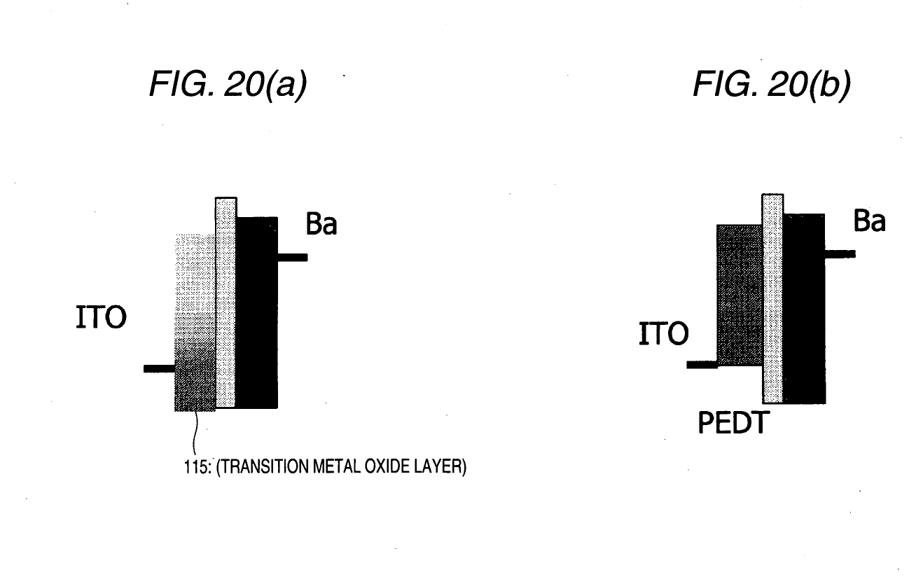

FIG. 20 is a drawing for explaining a relationship between the ionization potential of the organic electroluminescent element of the fifth embodiment of the present invention and that of a conventional organic electroluminescent element.

As apparent from FIG. 20(a), the ionization potential of ITO is 4.8 to 5.0 eV, that of molybdenum oxide is 5.6 eV and that of TFB constituting the electron blocking layer 117 is 5.4 to 5.6 eV.

It is noted that the ionization potential of each of these thin films was measured by using AC-2 made by Riken Keiki Co., Ltd.

FIG. 20(b) illustrates a relationship with the ionization potential of a conventional organic electroluminescent element in which PEDT is used in place of molybdenum oxide for comparison.

This constitution can form an organic electroluminescent element favorable in injection efficiency and high in reliability. In contrast, as shown in the comparative example in FIG. 20(b), where PEDT is used as a charge-injection layer 126 (refer to FIG. xx) in place of transition metal oxide layer 115, no sufficient injection efficiency is obtained. Furthermore, the transition metal oxide layer 115 is made to be 40 nm in film thickness, thereby making it possible to favorably restrict the area of a light emitting region, with the surface being planarized and smoothened by increasing film thickness. Furthermore, the underlying layer of the pixel restricting layer 114 can be smoothened, and even though the pixel restricting layer 114 is made thin by the thickness so smoothened, an insulation property can be kept sufficiently to decrease a step resulting from the pixel restricting layer 114, and consequently, a layer having the luminescence function can be made more uniform in thickness distribution. Furthermore, short circuiting of pixels can be effectively prevented.

The thickness of the transition metal oxide layer 115 is quite insensitive to element properties, thus making it possible to provide an organic electroluminescent element uniform in luminescence properties and stable in operation without depending on the thickness to a great extent. Furthermore, since the operation is stable, a deposition method or the like is used to form a luminescent layer 112 on the upper layer thereof, by which the luminescent layer 112 can be constituted with a small-molecular layer. Still furthermore, a transition metal oxide layer 115 having a film thickness of at least 30 nm or more is contained, by which even where a resist may remain at the time of patterning a translucent electrode such as ITO constituting a positive electrode 111 or particles may attach on the ITO, a transition metal oxide layer having a film thickness of 30 nm or more is formed, and also a luminescent layer 112 formed on the upper layer thereof is formed uniformly without thickness distribution. Therefore, there is no chance of forming a non light-emitting region or having a short circuit of pixels, thus making it possible to form a layer having a uniform luminescence function and provide a favorable luminescent profile.

Furthermore, when film-forming a transition metal oxide such as molybdenum oxide, by appropriately selecting the conditions a transition metal oxide layer 115 small in specific resistance in a laminated direction can be obtained. The thus obtained transition metal oxide layer will not cause a great voltage drop, if formed thick, thereby giving an electric field to a luminescent layer 112. Here, the transition metal oxide may include molybdenum oxide, vanadium oxide and tungsten oxide. Molybdenum oxide (MoOₓ) is not restricted to MoO₃ but may include that different in valence. Vanadium oxide and tungsten oxide may also include those different in valence. Furthermore, such an oxide that has a plurality of elements formed by a co-deposition method may also be applicable.

The organic electroluminescent element of the fifth embodiment is high in injection efficiency of holes, stable in operation and also excellent in life property, thus making it possible to realize a stable injection of electric charge and maintain a luminous efficiency under various conditions from mild driving conditions for a display application to severe driving conditions such as a strong electric field, a great electric current and a high brightness required by an exposure apparatus and the like.

Hereinafter, a detailed description will be made for a state of the pixel restricting layer 114 of the fifth embodiment.

As has been already described, a typical organic electroluminescent element is prepared by laminating a plurality of functional layers such as a charge-injection layer 115 (transition metal oxide layer) and a luminescent layer 112 between a positive electrode 111 and a negative electrode 113, for which there is employed a method for interposing an insulative film having an aperture as a pixel restricting layer 114 between either of a positive electrode 111 or a negative electrode 113 and a luminescent layer 112 in order to specify a pixel region. According to this constitution, it is necessary to form the luminescent layer 112 on the pixel restricting layer 114 having a step resulting from the aperture, by which a dimension of the step or a state of the surface of the pixel restricting layer 114 greatly influences luminescence properties.

Incidentally, a luminescent material used for the luminescent layer 112, in particular, a polymer film is constituted with a coated film by a spin coating method, for example, thereby where the film is formed on the pixel restricting layer 114, it is excellent in coverage and relatively high in short-circuit preventive function.

On the other hand, where the luminescent layer 112 is formed by using a small-molecular film, the film is often prepared by a deposition method. Therefore, the film is poor in coverage as compared with a polymer film and tends to form pin holes on film formation and causes short circuit. Therefore, the film quality and the film thickness of the pixel restricting layer 114 will greatly influence the characteristics.

Therefore, a great film thickness of the pixel restricting layer 114 causes the thickness distribution of the luminescent layer 112, thereby posing such a problem that light emission is not uniform. Since the problem may lead to a reduction in life, the pixel restricting layer 114 must be formed to be as thin as possible.

For example, according to Japanese Published Unexamined Patent Application No. 9-63771, although a pixel restricting layer is not used, various improvements are made for the surface of an underlying layer which constitutes a luminescent layer 112, thereby proposing an organic electroluminescent element in which an oxide thin film made with vanadium (V), molybdenum (Mo), ruthenium (Ru) or the like is laminated in place of an ITO electrode as a positive electrode 111 or on the ITO electrode.

Incidentally, where the luminescent layer 112 is not uniform in thickness, an electric field concentrates at a region lower in thickness, from which deterioration starts. This contributes to an unstable light emission. Furthermore, a great film thickness of the pixel restricting layer 114 results in thickness distribution, thus causing non-uniformity of the light emission. Therefore, it is necessary to form the pixel restricting layer 114 in a thickness of 100 nm or lower.

As described above, where the luminescent layer 112 is formed by using a small-molecular layer or a polymer layer, a uniform film formed on a pixel restricting layer 114 is a condition necessary for providing an organic electroluminescent element long in life, stable in operation and high in reliability.

The following approach for the pixel restricting layer 114 has been made in view of the above-described situation.

As illustrated in FIG. 15, the electroluminescent element concerned is provided with a positive electrode 111 as a first electrode, a negative electrode 113 as a second electrode, and a layer having the luminescence function composed of at least one type of organic semiconductor formed between the electrodes, that is, a luminescent layer 112, or it is an organic electroluminescent element which is provided with a pixel restricting layer 114 composed of a 50 nm-thick silicon nitride film for restricting a light emitting region, wherein the pixel restricting layer 114 is constituted so that the surface average roughness of Ra is made to be 5.0 nm or lower.

An elaborately formed film is used so that the surface mean roughness Ra of the pixel restricting layer 114 is made to be 5.0 nm or lower, by which the luminescent layer 112 formed on the upper layer thereof is formed uniformly without the thickness distribution. Therefore, even where the pixel restricting layer 114 is made thin, or 100 nm or lower in film thickness, it is possible to form a layer having a uniform luminescence function. The pixel restricting layer 114 in itself is also excellent in insulation property, thereby causing no leakage of emitted light. It is, thus possible to provide a favorable rectangular-shaped light emitting profile.

Furthermore, irregularities of the pixel restricting layer 114 are decreased, and short circuiting does not occur between both electrodes due to an elaborate film structure.

Still furthermore, since irregularities of the pixel restricting layer 114 are decreased, no emergent projections of the film develop, by which the occurrence of a so-called dark spot, which is a non-light emitting portion, can be suppressed. As a result, an electric current running through the organic electroluminescent element is distributed uniformly, thereby making it possible to provide a uniform light emission for a prolonged period of time.

In addition, since no portion is needed at which an excessively bright light is emitted for obtaining a desired light quantity, it is possible to prolong the life of the organic electroluminescent element.

It is noted that where the surface mean roughness of Ra exceeds 5.0 nm, no insulative property needed as a pixel restricting layer is secured to result in leakage of emitted light.

In the fifth embodiment, the pixel restricting layer 114 is formed by using silicon nitride in a low-temperature CVD method in which high density plasma is used so as to provide a film thickness of approximately 50 nm. Then, photolithography is used to form a resist pattern, and an etching is performed to form an aperture. First, after anisotropic etching is conducted, isotropic etching is conducted, thereby forming a pattern having a smooth edge. At this time, an angle with the underlying layer at a pattern edge is made to be approximately 3 to 10 degrees.

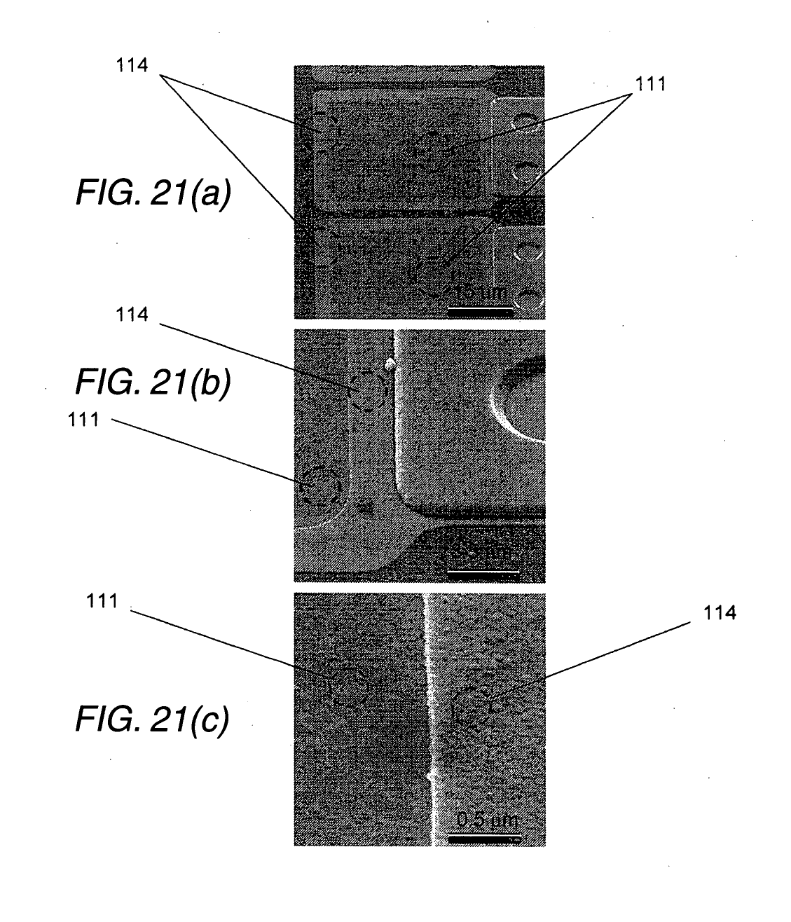

FIG. 21 is a photo showing physical properties of the surface of the pixel restricting layer 114 of the electroluminescent element according to the fifth embodiment of the present invention.

FIG. 21(a) to FIG. 21(c) are electron micrographs of major parts on the surface of the pixel restricting layer 114, which are magnified for the pixel restricting layer 114 at 1.5k times, 7k times and 50k times respectively.

That found on the underlying layer of a pattern on the pixel restricting layer 114 is the surface of the positive electrode 111 composed of ITO. According to this constitution, the luminescent layer 112 is formed uniform in thickness on the positive electrode 111 restricted by the pixel restricting layer 114.

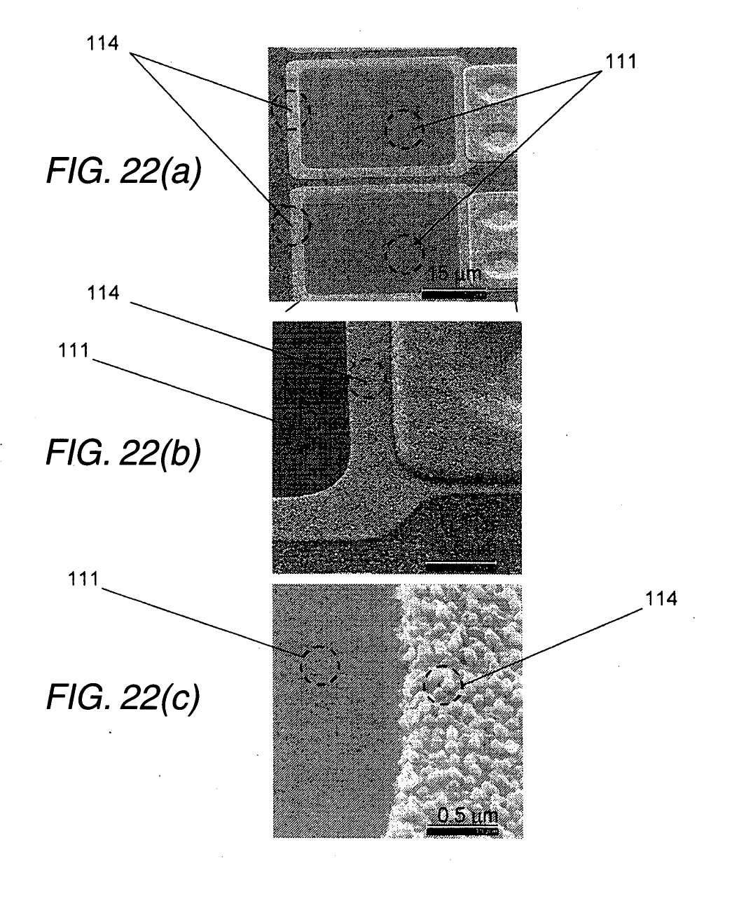

FIG. 22 is a photo showing physical properties of the surface of the pixel restricting layer 114 of a conventional electroluminescent element.

FIG. 22(a) to FIG. 22(c) are magnified electron micrographs of major parts on the surface of the pixel restricting layer 114 of a conventional example shown for comparison. FIG. 22(a) to FIG. 22(c) are the photos which are magnified respectively corresponding to FIG. 21(a) to FIG. 21(c). As apparent from the comparison of these photos, the surface of the pixel restricting layer 114 of the fifth embodiment is excellent in smoothness.

The surface of the pixel restricting layer 114 of the organic electroluminescent element shown in FIG. 21 and FIG. 22 is measured for the surface mean roughness by using a stylus-based profilometer. As a result, the surface mean roughness of the conventional pixel restricting layer 114 shown in FIG. 22 is 5.5 nm, whereas that of the pixel restricting layer 114 shown in FIG. 21 is 1.0 nm. Furthermore, a sum of an absolute value of a maximum ridge height Rp and that of a maximum valley depth Rv on the surface of the pixel restricting layer 114 is 20.8 nm on the conventional pixel restricting layer 114 and 7.2 nm on the surface of the pixel restricting layer 114 of the fifth embodiment.

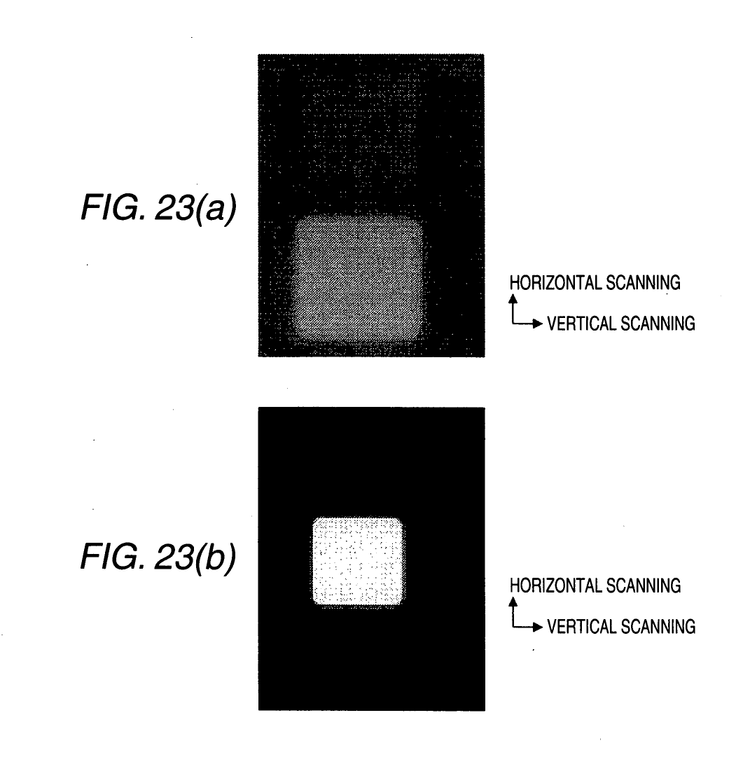

FIG. 23 is a photo showing a light emitting state of an electroluminescent element used in an exposure apparatus of the fifth embodiment of the present invention.

In this instance, FIG. 23(a) and FIG. 23(b) are photomacrographs showing a light emitting state of the electroluminescent element of this embodiment. FIG. 23(a) and FIG. 23(b) are photos showing a light emitting state of the organic electroluminescent element of the fifth embodiment. FIG. 23(a) and FIG. 23(b) are different in photographic conditions each other. FIG. 23(a) is a photo taken by an ordinary digital camera, with a predetermined adaptor attached on the eye piece of the microscope, whereas FIG. 23(b) is a photo taken by a CCD camera having a predetermined magnifying optical system.

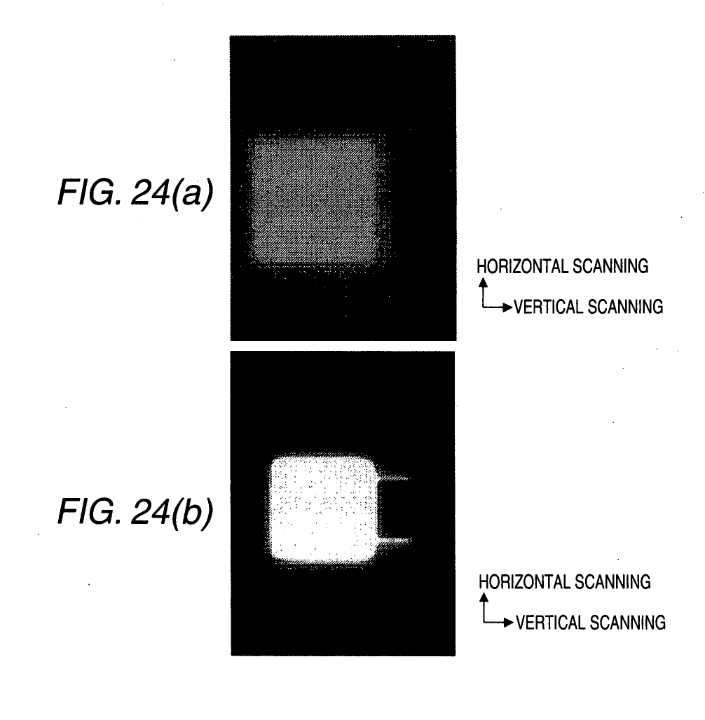

FIG. 24 is a photo showing a light emitting state of an electroluminescent element used in a conventional exposure apparatus.

FIG. 24(a) and FIG. 24(b) are photomacrographs showing a light emitting state of a conventional electroluminescent element for comparison. The photos shown in FIG. 24(a) and FIG. 24(b) were taken under conditions the same as those under which the photos shown in FIG. 23(a) and FIG. 23(b) were taken.

Furthermore, FIG. 23(a), FIG. 23(b), FIG. 24(a) and FIG. 24(b) are all photos obtained by observing a light emitting state of an organic electroluminescent element having a light emitting region formed so as to be approximately a rectangular shape and also the same in size by a 50 nm-thick pixel restricting layer 114.

It is apparent from FIG. 24(a) and FIG. 24(b) that light is emitted from a portion at which an electric charge should be prevented from being injected by the pixel restricting layer 114 (that is, a portion at which light should not be emitted in principle). This abnormal luminescent portion is immediately above the pixel restricting layer 114 (apparent with reference to FIG. 23(a) and FIG. 23(b) or in comparison with FIG. 24(a) and FIG. 24(b)), which means that a leak electric current runs through the pixel restricting layer 114. By comparison thereof, in FIG. 23(a) and FIG. 23(b), a light emitting region completely coincides with an aperture formed by the pixel restricting layer 114.

The electroluminescent element of the fifth embodiment in which the surface of the pixel restricting layer 114 is smoothened can provide a light emitting state great in light-dark ratio, without leakage of emitted light.

Furthermore, as have been so far described, the pixel restricting layer 114 of a conventional organic electroluminescent element shown in FIG. 24(a) and FIG. 24(b) is 5.5 nm in surface mean roughness and a sum of an absolute value of a maximum ridge height and that of a maximum valley depth on the surface of the pixel restricting layer 114 is 20.8 nm. It is difficult to use an organic electroluminescent element prepared under these conditions in precision instruments such as an exposure apparatus which will be described later.

Individual pixels formed by exposure apparatuses are required to have an extremely high uniformity. Therefore, a light emitting region must be formed constant in configuration. Where unstable conditions such as leakage occur, the above requirement is not met. With the above matter taken into account, in an application, for example, an exposure apparatus, such an accuracy is required so that the surface mean roughness Ra of the pixel restricting layer 114 is equal to or less than 1.0 nm and a sum of an absolute value of a maximum ridge height Rp and that of a maximum valley depth Rv on the pixel restricting layer 114 is equal to or less than 10 nm, corresponding to FIG. 23(a) and FIG. 23(b).

However, in an application such as a lighting device where individual light emitting regions are not required to be formed accurate in configuration, a light emitting state as shown in FIG. 24(a) or FIG. 24(b) will not pose a particular problem. In this instance, although leakage is found in a pixel restricting layer, the light emission brightness at a leakage portion is negligible so that it will not impart any influence on the application purposes or will not lead to the breakage of an organic electroluminescent element. With the above matter taken into account, an electroluminescent element can be actually used in an application such as a lighting device, if such an accuracy is met that the surface mean roughness Ra of the pixel restricting layer 114 is equal to or less than 5.0 nm and a sum of an absolute value of a maximum ridge height Rp and that of a maximum valley depth Rv on the pixel restricting layer is equal to or less than 20 nm, corresponding to FIG. 23(a) and FIG. 23(b).

Then, an application such as a display device represented by a display screen lies midway between the above two applications. Regarding a display device, the reproducibility of a halftone (gradation) is important. In a narrow sense, the light emission brightness of each pixel will change, depending on whether light emission resulting from the above-described leakage of the pixel restricting layer 114 is found. However, no particular problem should be found, if the light emission brightness changes to an extent less than one gradation step within a range of brightness which is reproducible by a display device (that is, dynamic range). In an ordinary display device, the number of gradient steps is set to be approximately 64. With this matter taken into account, an electroluminescent element can actually be used in an application such as a display device, if such an accuracy is met that is midway between the above-described accuracy required for an exposure apparatus and that for a lighting device, that is, the surface mean roughness Ra of the pixel restricting layer is equal to or less than 2.0 nm and a sum of an absolute value of a maximum ridge height Rp and that of a maximum valley depth Rv on the pixel restricting layer is equal to or less than 15 nm.

Furthermore, a desired surface state can be given to the pixel restricting layer 114 by using a plasma CVD system in which a silicon nitride film is formed, with film forming conditions adjusted, for example, the film is formed at a low temperature, a film-forming speed is decreased by keeping the power low, or a mixture ratio of SiH₄ to NH₃ introduced during film formation is changed, that is, the ratio of SiH₄ is increased. The desired surface state can also be easily obtained by the procedures in which the pixel restricting layer 114 is film-formed, after patterning or concurrently with patterning, the surface is processed by plasma processing or the like to adjust the surface roughness. The film forming conditions are given various film-forming characteristics different in each system and not necessarily observed completely, because a smoother surface state may be obtained at a higher temperature and at a greater film-forming speed. It is also possible to smoothen the surface by plasma processing or the like after film formation. Still furthermore, as shown in FIG. 15, where an inorganic oxide layer (transition metal oxide layer 115) such as molybdenum oxide is formed between a positive electrode 111 and a pixel restricting layer 114, plasma processing conducted during surface treatment can smoothen the surface without deterioration of the surface, by which the end surface of the pixel restricting layer 114 is smoothened favorably, together with the exposed surface of the inorganic oxide layer (transition metal oxide layer 115). In contrast, where the lower layer of the pixel restricting layer 114 is a polymer layer, plasma processing may cause deterioration.

In the fifth embodiment, a method is employed in which an insulative film such as a silicon nitride film is interposed as the pixel restricting layer 114. A metal film having a light-blocking effect such as tungsten or a product laminated with a light protection film may be used. Where a metal film having a light-blocking effect is used, a light outgoing region is optically specified, with a light emitting region kept as it is.

The fifth embodiment includes the following inventions.

An organic electroluminescent element of the fifth embodiment contains a transition metal oxide layer 115 having a functional layer formed on a positive electrode 111, an electron blocking layer 117 formed on the transition metal oxide layer 115 higher in LUMO (lowest unoccupied molecular orbital) level than a luminescent layer 112 and the luminescent layer 112 formed on the electron blocking layer 117. This constitution can provide an effect that holes are injected effectively without a substantial energy barrier, thereby attaining an improved luminous efficiency. In this instance, the LUMO is an unoccupied orbital which is immediately above a molecular orbital, or HOMO (highest occupied molecular orbital) at which electrons having the highest energy are accommodated.

Furthermore, in the organic electroluminescent element of the fifth embodiment, a difference in ionization potential between the transition metal oxide layer 115 and the electron blocking layer 117 is preferably made to be 0.2 eV or lower. This constitution can improve an injection efficiency for hole injection effectively.

Furthermore, in the organic electroluminescent element of the fifth embodiment, a transition metal oxide layer 115 is preferably made to be 5.6 or more in ionization potential. This constitution can improve an injection efficiency for hole injection effectively.

Furthermore, a transition metal oxide used in the fifth embodiment is preferably made to be from IMΩcm to 1 GΩcm in specific resistance. An ordinary four-terminal method was employed to measure the molybdenum oxide thin film used in the fifth embodiment, finding that the specific resistance was 12 MΩcm. In particular, that having the specific resistance from 10 MΩcm to 100 MΩcm is preferably used. The resistance value can be controlled by adjusting compositions of the thus obtained film, the surface oxidation degree, the defective state and the crystallization degree thereof, or a substrate temperature during thin film formation and an annealing temperature after the formation. A transition metal oxide assumes a non-crystalline state at temperatures near an ordinary temperature and tends to assume a crystalline state more easily with an increase in temperature. As the transition metal oxide layer 115 used in the fifth embodiment, that which is in a non-crystalline state is preferably used because of the specific resistance falling under the above-described range.

Furthermore, the organic electroluminescent element of the fifth embodiment includes that in which a transition metal oxide layer 115 is formed so that the specific resistance along a laminated direction is smaller than the specific resistance along a planar direction. This constitution can provide the specific resistance greater in a transverse direction or in a planar direction, thereby making it possible to prevent a cross-talk. The thus constituted organic electroluminescent element can, therefore, prevent a cross-talk, even if formed integrally without patterning, resulting in an easy manufacturing. Furthermore, at least an underlying layer, which is a region of forming the organic electroluminescent element, is entirely covered by the transition metal oxide layer 115, thus making it possible to provide a stable and highly-reliable structure. A voltage drop is decreased due to a small specific resistance along a vertical direction, that is, in a laminated direction.

Furthermore, in the fifth embodiment, an electron blocking layer 117 may be constituted with a small-molecular compound.

Still furthermore, in the fifth embodiment, the electron blocking layer 117 may be constituted with an oligomer.

In addition, in the fifth embodiment, the electron blocking layer 117 may be constituted with a polymer compound.

Furthermore, in the fifth embodiment, a luminescent layer 112 may be constituted with a phosphorescent dendrimer having a luminescent structural unit at the center. Still furthermore, in the fifth embodiment, the luminescent layer 112 may be constituted with a dendritic multi-branched polymer structure having a luminescent structural unit at the center.

Furthermore, in the fifth embodiment, the luminescent layer 112 may be constituted with a dendritic multi-branched small-molecular structure having a luminescent structural unit at the center.

Furthermore, the fifth embodiment includes a process of forming a transition metal oxide layer 115 on the surface of a substrate 100 in which a positive electrode 111 is formed and a process of forming a luminescent layer 112 thereon inside the same chamber, without breakage of vacuum, and in the process of forming a transition metal oxide layer 115 and in the process of forming the luminescent layer 112, the films are formed in such a way that the ionization potential of the transition metal oxide layer 115 is equal to or greater in absolute value than that of the luminescent layer 112 on the transition metal oxide layer 115 side. This method can manufacture an organic electroluminescent element excellent in luminous efficiency.

Furthermore, the fifth embodiment is a method for manufacturing an organic electroluminescent element which may include a process of forming a pixel restricting layer 114 after a process of forming a transition metal oxide layer 115, and a process of forming a luminescent layer 112 by an ink jet method on the transition metal oxide layer 115 exposed from an aperture of the pixel restricting layer 114. According to the above manufacturing method, there is no chance of causing decomposition to break the luminescent layer 112, as found in PEDT. Furthermore, since the transition metal oxide layer 115 is hydrophilic on the surface, a film such as the luminescent layer 112 formed by an ink jet method is made uniform, thereby making it possible to form a luminescent layer 112 more uniform in thickness distribution.

Furthermore, the fifth embodiment is an organic electroluminescent element which is provided with at least one hole injection electrode and a plurality of functional layers formed on an electrode, including a transition metal oxide layer (MxOy:M denotes a transition metal) arranged between the electrode and a functional layer, also including an organic electroluminescent element which is constituted in such a way that the ionization potential of the transition metal oxide layer is greater in absolute value than that of the functional layer on the transition metal oxide layer side.

This constitution can remove an energy barrier and also improve an injection efficiency.

The fifth embodiment includes the following inventions as well.

An organic electroluminescent element of the fifth embodiment is constituted more preferably in such a way that the surface mean roughness (Ra) of a pixel restricting layer 114 is made to be 2.0 nm or lower. An elaborately formed layer is used so that the surface mean roughness (Ra) of the pixel restricting layer 114 is 2.0 nm or lower, by which a layer having the luminescence function formed on the upper layer thereof is free of any thickness distribution and formed more uniformly. Therefore, in addition to the effect provided from the above constitution, a more uniform luminescent profile can be obtained. Furthermore, irregularities of the pixel restricting layer 114 are decreased, and no short circuit between the electrodes due to the elaborately structured film develops. Where the surface mean roughness (Ra) of the pixel restricting layer 114 exceeds 2.0 nm, a projection which is one of the causes of a dark spot, that is, a non-light emitting portion, is developed at an increased probability. The pixel restricting layer 114 having the surface mean roughness of 2.0 nm or lower is more effective in suppressing the occurrence of the dark spot or leakage of emitted light.

Furthermore, the organic electroluminescent element of the fifth embodiment is constituted more preferably in such a way that the surface mean roughness (Ra) of the pixel restricting layer 114 is made to be 1.0 nm or lower. An elaborately formed layer is used so that the surface mean roughness (Ra) of the pixel restricting layer 114 is 1.0 nm or lower, by which a luminescent layer 112 formed on the upper layer thereof is free of any thickness distribution and formed uniformly. Therefore, if the pixel restricting layer 114 is made thin, or 100 nm or lower in thickness, it is possible to form a layer having a uniform luminescence function. Furthermore, since the pixel restricting layer 114 in itself is excellent in insulation property, there is no chance of causing the leakage of emitted light to provide a favorable rectangular-shaped luminescent profile. Furthermore, irregularities of the pixel restricting layer are decreased, and no short circuit between the electrodes due to the elaborately structured film develops. Irregularities of the pixel restricting layer are decreased, by which no emergent projections and the occurrence of a so-called dark spot develop, that is, a non-light emitting portion, can be suppressed.

Furthermore, the organic electroluminescent element of the fifth embodiment includes that in which a sum of an absolute value of a maximum ridge height Rp and that of a maximum valley depth Rv on the pixel restricting layer 114 is from 1 nm to 20 nm. According to this constitution, an elaborately formed film is used in such a way that a sum of an absolute value of a maximum ridge height Rp and that of a maximum valley depth Rv on the pixel restricting layer 114 is set from 1 nm to 20 nm, by which a luminescent layer 112 formed on the upper layer thereof can be formed more uniformly without thickness distribution.

Furthermore, the organic electroluminescent element of the fifth embodiment includes that in which a sum of an absolute value of a maximum ridge height Rp and that of a maximum valley depth Rv on the pixel restricting layer 114 is set from 1 nm to 10 nm. An elaborately formed film is used in such a way that a sum of an absolute value of a maximum ridge height Rp and that of a maximum valley depth Rv on the pixel restricting layer 114 is set from 1 nm to 10 nm, by which the luminescent layer 112 formed on the upper layer thereof can be formed more uniformly without thickness distribution. Therefore, if the pixel restricting layer 114 is made thin, that is, 100 nm or lower in film thickness, it is possible to form a layer having a uniform luminescence function. Furthermore, since the pixel restricting layer 114 in itself is excellent in insulation property, there is no chance of causing the leakage of emitted light, thereby a favorable rectangular-shaped luminescent profile can be obtained. Furthermore, irregularities of the pixel restricting layer are decreased, and no short circuit between the electrodes due to the elaborately structured film develops. Irregularities of the pixel restricting layer are decreased, by which no emergent projections on a film and the occurrence of a so-called dark spot develop, that is, a non-light emitting portion, can be suppressed.

Furthermore, in the organic electroluminescent element of the fifth embodiment, it is preferable that a thin film constituting the pixel restricting layer 114 is made from 5 nm to 100 nm in grain size. An elaborately formed film is used in such a way that a thin film constituting the pixel restricting layer 114 is made from 5 nm to 100 nm in grain size, by which a layer having a luminescence function formed on the upper layer thereof is formed uniformly without thickness distribution. Where the grain size exceeds 40 nm, there develop irregularities resulting from a grain aggregate to result in a decreased uniformity.

Furthermore, in the organic electroluminescent element of the fifth embodiment, it is more preferable that a thin film constituting the pixel restricting layer 114 is made from 5 nm to 40 nm in grain size. An elaborately formed film is used in such a way that a thin film constituting the pixel restricting layer 114 is made from 5 nm to 40 nm in grain size, by which a layer having the luminescence function formed on the upper layer thereof is formed uniformly without thickness distribution.

Furthermore, in the organic electroluminescent element of the fifth embodiment, the film density of a thin film constituting the pixel restricting layer 114 is preferably to be 2.0 g/cm² to 3.5 g/cm². Such an elaborate film is used, by which a luminescent layer 112 formed on the upper layer thereof can be formed uniformly without thickness distribution. Therefore, if the pixel restricting layer 114 is made thin, that is, 100 nm or lower in film thickness, it is formed as a layer having a uniform luminescence function. Furthermore, since the pixel restricting layer 114 in itself is excellent in insulation property, no leakage of emitted light to provide a favorable rectangular-shaped luminescent profile develops.

Furthermore, in the organic electroluminescent element of the fifth embodiment, it is preferable that an angle between the circumference of an aperture on the pixel restricting layer 114 and the lower structure thereof (positive electrode 111 or substrate 100) is set from 3 to 45 degrees. This constitution can decrease a step at the inner edge of the pixel restricting layer 114, by which the luminescent layer 112 is prevented from becoming thick at the edge portion of the pixel restricting layer 114. The luminescent layer 112 is free of thickness distribution at an aperture portion on the pixel restricting layer 114 and can be formed uniformly. Therefore, it is formed as a layer having a uniform luminescence function and able to provide a favorable rectangular-shaped luminescent profile. There is also a problem that a step at an edge portion may result in a fact that dust or particles due to a poor washing which will develop as cores of dark spots may easily remain at an edge portion. Since there is no large step at the edge portion due to the above-described constitution, dust or particles which become causes of the dark spots are less likely to remain.

Furthermore, in the organic electroluminescent element of the fifth embodiment, it is more preferable that an angle between the circumference of an aperture on the pixel restricting layer 114 and the lower structure is set to be 3 to 10 degrees. This constitution can decrease a step at the inner edge of the pixel restricting layer 114, by which the luminescent layer 112 is prevented from becoming thick at the edge portion of the pixel restricting layer 114. The luminescent layer 112 is free of thickness distribution at an aperture portion on the pixel restricting layer 114 and can be formed uniformly. Therefore, it is formed as a layer having a uniform luminescence function and able to provide an excellent rectangular-shaped luminescent profile. There is also a problem that a step at an edge portion may result in a fact that dust or particles due to a poor washing which will develop as cores of dark spots may easily remain at an edge portion. Since there is no large step at the edge portion due to the above-described constitution, dust or particles which become causes of the dark spots are less likely to remain, and consequently, an excellent rectangular-shaped luminescent profile can be obtained.

Furthermore, in the organic electroluminescent element of the fifth embodiment, the pixel restricting layer 114 is preferably from 20 nm to 100 nm in thickness. According to this constitution, the luminescent layer 112 can be formed uniformly without undergoing a change in thickness at an aperture portion on the pixel restricting layer 114. Therefore, it is formed as a layer having a uniform luminescence function and able to provide a favorable rectangular-shaped luminescent profile.

Furthermore, the organic electroluminescent element of the fifth embodiment includes that in which the surface of the pixel restricting layer 114 is entirely covered with an inorganic oxide layer (transition metal oxide layer 115), and a layer having the luminescence function is formed on the upper layer thereof (for example, a structure shown in FIG. 3). According to this constitution, a step formed at the inner edge of the pixel restricting layer 114 and irregularities of the pixel restricting layer 114 are moderated by the inorganic oxide layer, by which a luminescent layer formed on the upper layer thereof is made more uniform in film thickness. The inorganic oxide layer is preferably a charge-injection layer.

Still furthermore, in the organic electroluminescent element of the fifth embodiment, it is preferable that a pixel restricting layer 114 is constituted with an oxide silicon film, silicon nitride or silicon oxynitride. This constitution can form a film high in accuracy and also high in insulation property, thereby making it possible to form the pixel restricting layer 114 more thinly. As a result, a luminescent layer 112 formed on the upper layer thereof is formed uniformly without thickness distribution. Therefore, even if the pixel restricting layer 114 is made thin, that is, 100 nm or lower in thickness, it is formed as a layer having a uniform luminescence function and able to provide a favorable rectangular-shaped luminescent profile.

In addition, in the organic electroluminescent element of the fifth embodiment, the pixel restricting layer 114 may be constituted by laminating a plurality of layers appropriately selected from oxide silicon film, silicon nitride and silicon oxynitride.

As a plurality of embodiments have been so far described, these embodiments are combined with each other, for example, the buffer layer described in detail in the first embodiment is combined with other embodiments, and, for example the specified physical property of the pixel restricting layer described in detail in the fifth embodiment is combined with other embodiments, which are all intended by the present inventor and, as a matter of course, included in the scope to be protected.

An electroluminescent element of the present invention is applicable, as an exposure apparatus and an image forming device, to a copier, a printer, a multifunction printer, a facsimile machine and others.

This application is based upon and claims the benefit of priority of Japanese Patent Application No 2006-110117 filed on Jun. 4, 1912, Japanese Patent Application No 2006-116183 filed on Jun. 4, 1919, Japanese Patent Application No 2006-116193 filed on Jun. 4, 1919, Japanese Patent Application No 2006-116184 filed on Jun. 4, 1919, Japanese Patent Application No 2006-116194 filed on Jun.4, 1919, the contents of which are incorporated herein by reference in its entirety.

1. An organic electroluminescent element which is provided with a positive electrode, a negative electrode and a luminescent layer between the positive electrode and the negative electrode, wherein a transition metal oxide layer is formed between the negative electrode and the luminescent layer.

2. The organic electroluminescent element according to claim 1, wherein the transition metal oxide layer is from 1 nm to 1 μm in thickness.

3. The organic electroluminescent element according to claim 1, wherein the transition metal oxide layer is 70% or more in transmittance.

4. The organic electroluminescent element according to claim 1, wherein the transition metal oxide layer is from 4 to 6 eV in work function.

5. The organic electroluminescent element according to claim 1, wherein the transition metal oxide layer is from 1 MΩcm to 1 GΩcm in specific resistance.

6. The organic electroluminescent element according to claim 1, wherein the transition metal oxide layer contains molybdenum oxide.

7. The organic electroluminescent element according to claim 1, wherein the transition metal oxide layer contains vanadium oxide.

8. The organic electroluminescent element according to claim 1, wherein the transition metal oxide layer contains tungsten oxide.

9. The organic electroluminescent element according to claim 1, wherein the luminescent layer contains a polymer compound.

10. The organic electroluminescent element according to claim 1, wherein the luminescent layer contains a polymer compound having a fluorene ring.

11. The organic electroluminescent element according to claim 1, wherein an intermediate layer is additionally formed between the transition metal oxide layer and the negative electrode.

12. The organic electroluminescent element according to claim 11, wherein the intermediate layer contains at least any one of barium, calcium, lithium, cesium, the oxide thereof or halogenide.

13. The organic electroluminescent element according to claim 11, wherein the intermediate layer is constituted with a polymer layer.

14. The organic electroluminescent element according to claim 1, wherein the positive electrode is formed on a translucent substrate, a functional layer containing a hole injection layer and a luminescent layer is formed on the positive electrode, and the transition metal oxide layer and the negative electrode are formed so as to oppose the hole injection layer via the luminescent layer.

15. The organic electroluminescent element according to claim 1, wherein the positive electrode is formed on a substrate, a functional layer containing a hole injection layer and a luminescent layer is formed on the positive electrode, the transition metal oxide layer and the negative electrode are formed so as to oppose the hole injection layer via the luminescent layer, and the negative electrode is constituted with a transparent material.

16. The organic electroluminescent element according to claim 1, wherein a transition metal oxide layer is additionally formed between the positive electrode and the luminescent layer.

17. A method for manufacturing an organic electroluminescent element, wherein a positive electrode is formed on a substrate, a luminescent layer is formed as the upper layer of the positive electrode, a transition metal oxide layer is formed as the upper layer of the luminescent layer, and a negative electrode is formed as the upper layer of the transition metal oxide layer.

18. The method for manufacturing an organic electroluminescent element according to claim 17, wherein a process of forming the negative electrode is a film forming process by a sputtering method.

19. A display device in which an organic electroluminescent element described in claim 1 is arranged two-dimensionally.

20. An exposure apparatus in which an organic electroluminescent element described in claim 1 is arranged in a row.
